(19) United States
(12) Patent Application Publication
(10) Pub. No.: US 2026/0293092 A1
(43) Pub. Date: Sep. 24, 2026

(54) SEMICONDUCTOR DEVICE AND METHOD FOR MANUFACTURING SEMICONDUCTOR DEVICE

(71) Applicant: Semiconductor Energy Laboratory Co., Ltd., Atsugi-shi, Kanagawa-ken (JP)

(72) Inventors: Hideomi SUZAWA, Atsugi (JP); Kensuke YOSHIZUMI, Atsugi (JP); Akihiro KIKUCHI, Isehara (JP)

(21) Appl. No.: 19/473,832

(22) PCT Filed: May 2, 2024
(86) PCT No.: PCT/IB2024/054222

§ 371 Date: Oct. 9, 2025

(30) Foreign Application Priority Data
May 11, 2023 (JP) 2023-078257
Feb. 27, 2024 (JP) 2024-027454

(51) Int. Cl. H10B 12/00

(52) U.S. Cl. CPC H10B 12/31; H10B 12/05

(57) ABSTRACT

A semiconductor device with favorable electrical characteristics is provided. Alternatively, a transistor in which the breakdown voltage of a gate insulating layer is high is provided. In the semiconductor device, a first conductive layer and a second conductive layer positioned at different levels with a first insulating layer therebetween are one and the other of a source electrode and a drain electrode of a first transistor. The first insulating layer has a first opening reaching the first conductive layer. The second conductive layer is provided over the first insulating layer. A semiconductor layer includes a first region covering the top surface of the first conductive layer, a second region covering a side surface of the first opening, and a third region covering the top surface of the second conductive layer and overlapping with a gate electrode. A gate insulating layer includes a fourth region provided to face a sidewall of the first opening, a fifth region covering the top surface of the third region, and a sixth region covering the top surface of the second conductive layer and being positioned outward from an end portion of the gate electrode in a top view. The thickness of the fifth region is larger than the thickness of the fourth region and the thickness of the sixth region.

### TECHNICAL FIELD

One embodiment of the present invention relates to a semiconductor device, a memory device, a display apparatus, and an electronic appliance. Another embodiment of the present invention relates to a method for manufacturing a semiconductor device.

One embodiment of the present invention is not limited to the above technical field. Examples of the technical field of one embodiment of the present invention can include a semiconductor device, a display apparatus, a light-emitting apparatus, a power storage device, a memory device, an electronic appliance, a lighting device, an input device (e.g., a touch sensor), an input/output device (e.g., a touch panel) a method for driving any of them, and a method for manufacturing any of them.

In this specification and the like, a semiconductor device is a device that utilizes semiconductor characteristics, and refers to a circuit including a semiconductor element (e.g., a transistor, a diode, or a photodiode), a device including the circuit, or the like. The semiconductor device also refers to any device that can function by utilizing semiconductor characteristics. For example, an integrated circuit, a chip including an integrated circuit, and an electronic component including a chip in a package are examples of the semiconductor device. Moreover, a memory device, a display apparatus, a light-emitting apparatus, a lighting device, and an electronic appliance themselves are semiconductor devices and each of them includes a semiconductor device in some cases.

### BACKGROUND ART

In recent years, semiconductor devices have been developed, and LSIs, CPUs, memories, and the like are mainly used as semiconductor devices. A CPU is an assembly of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit (IC) and a display apparatus. A silicon-based semiconductor material is widely known as a semiconductor thin film that can be used for a transistor, and an oxide semiconductor has been attracting attention as another material.

It is known that a transistor including an oxide semiconductor has an extremely low leakage current in an off state. For example, Patent Document 1 discloses a low-power-consumption CPU utilizing a feature of a low leakage current of the transistor including an oxide semiconductor. Furthermore, for example, Patent Document 2 discloses a memory device that can retain stored contents for a long period of time by utilizing a feature of a low leakage current of the transistor including an oxide semiconductor.

In recent years, demand for an integrated circuit with higher density has risen with reductions in size and weight of electronic appliances. Furthermore, the productivity of a semiconductor device including an integrated circuit is desired to be improved. For example, Patent Document 3 and Non-Patent Document 1 each disclose a technique to achieve an integrated circuit with higher density by making a plurality of memory cells overlap with each other by stacking a first transistor including an oxide semiconductor film and a second transistor including an oxide semiconductor film. Patent Document 4 discloses a technique to achieve an integrated circuit with higher density by placing a channel of a transistor including an oxide semiconductor film in the vertical direction.

### REFERENCE

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] M. Oota et. al, “3D-Stacked CAAC—In—Ga—Zn Oxide FETs with Gate Length of 72 nm”, IEDM Tech. Dig., 2019, pp. 50-53

### SUMMARY OF THE INVENTION

### Problems to be Solved by the Invention

One object of one embodiment of the present invention is to provide a transistor with favorable electrical characteristics. Another object of one embodiment of the present invention is to provide a transistor in which the breakdown voltage of a gate insulating layer is high. Another object of one embodiment of the present invention is to provide a transistor with small parasitic capacitance. Another object of one embodiment of the present invention is to provide a transistor with a high on-state current. Another object of one embodiment of the present invention is to provide a transistor, a semiconductor device, or a memory device that can be miniaturized or highly integrated. Another object of one embodiment of the present invention is to provide a display apparatus with high resolution or a high aperture ratio. Another object of one embodiment of the present invention is to provide a transistor, a semiconductor device, a display apparatus, or a memory device with high reliability. Another object of one embodiment of the present invention is to provide a semiconductor device, a display apparatus, or a memory device with low power consumption. Another object of one embodiment of the present invention is to provide a memory device that operates at high speed. Another object of one embodiment of the present invention is to provide a method for manufacturing the above transistor, semiconductor device, display apparatus, or memory device.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device including a first transistor and a first insulating layer. The first transistor includes a first conductive layer, a second conductive layer, a semiconductor layer, a gate insulating layer, and a gate electrode. The first conductive layer is one of a source electrode and a drain electrode of the first transistor, and the second conductive layer is the other of the source electrode and the drain electrode of the first transistor. The first conductive layer and the second conductive layer are positioned at different levels. The first insulating layer is provided between the first conductive layer and the second conductive layer. The gate electrode overlaps with the semiconductor layer with the gate insulating layer therebetween. A first opening reaching the first conductive layer is included. The second conductive layer is provided over the first insulating layer. The semiconductor layer includes a first region covering a top surface of the first conductive layer in the first opening, a second region covering a side surface of the first insulating layer in the first opening, and a third region covering a top surface of the second conductive layer and overlapping with the gate electrode. The gate insulating layer includes a fourth region provided to face a sidewall of the first opening provided in the first insulating layer with the second region therebetween, a fifth region covering a top surface of the third region, and a sixth region covering the top surface of the second conductive layer and being positioned outward from an end portion of the gate electrode in a top view. A thickness of the fifth region is larger than a thickness of the fourth region. The thickness of the fifth region is larger than a thickness of the sixth region.

In the above embodiment, the thickness of the fifth region is preferably larger than the thickness of the sixth region by 2 nm or more.

In the above embodiment, the thickness of the sixth region is preferably greater than or equal to 1.0 nm and less than or equal to 100 nm.

In the above embodiment, the thickness of the fourth region is preferably greater than or equal to 0.1 nm and less than or equal to 7.0 nm.

In the above embodiment, the semiconductor layer preferably includes a region covering the top surface of the second conductive layer and being covered with the sixth region.

In the above embodiment, it is preferable that the second conductive layer be provided with a second opening overlapping with the first opening, the semiconductor layer include a region covering a side surface of the second conductive layer in the second opening, and the first insulating layer include a region covering the second opening with the semiconductor layer therebetween.

Another embodiment of the present invention is a method for manufacturing a semiconductor device, including: forming a first insulating layer over a first conductive layer; forming a second conductive layer over the first insulating layer; removing part of the second conductive layer and part of the first insulating layer to form a first opening reaching the first conductive layer and to expose a top surface of the first conductive layer; forming a first semiconductor layer in contact with the top surface of the first conductive layer, a side surface of the first insulating layer in the first opening, a side surface of the second conductive layer in the first opening, and a top surface of the second conductive layer; forming a second insulating layer in contact with a top surface of the first semiconductor layer and a top surface of the first insulating layer by a method with deposition rate anisotropy such that a thickness of the second insulating layer in a region covering a side surface of the first opening with the first semiconductor layer therebetween becomes smaller than a thickness of the second insulating layer in a region covering a top surface of the first conductive layer; forming a third conductive layer over the second insulating layer; forming a first mask by a photolithography method; performing dry etching using the first mask; and removing part of the third conductive layer by the dry etching to form a fourth conductive layer. In the region covering the top surface of the first conductive layer in the second insulating layer, a thickness of a part not covered with the first mask is reduced by the dry etching.

In the above embodiment, the second insulating layer is preferably formed by an ionization sputtering method.

In the above embodiment, the second insulating layer is preferably formed by a long throw sputtering method.

In the above embodiment, the second insulating layer is preferably formed by a plasma-enhanced chemical vapor deposition method.

### Effect of the Invention

One embodiment of the present invention can provide a transistor with favorable electrical characteristics. Another embodiment of the present invention can provide a transistor in which the breakdown voltage of a gate insulating layer is high. Another embodiment of the present invention can provide a transistor with small parasitic capacitance. Another embodiment of the present invention can provide a transistor with a high on-state current. Another embodiment of the present invention can provide a transistor, a semiconductor device, or a memory device that can be miniaturized or highly integrated. Another embodiment of the present invention can provide a display apparatus with high resolution or a high aperture ratio. Another embodiment of the present invention can provide a transistor, a semiconductor device, a display apparatus, or a memory device with high reliability. Another embodiment of the present invention can provide a semiconductor device, a display apparatus, or a memory device with low power consumption. Another embodiment of the present invention can provide a memory device that operates at high speed. Another embodiment of the present invention can provide a method for manufacturing the above transistor, semiconductor device, display apparatus, or memory device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a plan view illustrating an example of a semiconductor device. FIG. 1B and FIG. 1C are cross-sectional views illustrating the example of the semiconductor device.

FIG. 2A is a cross-sectional view illustrating an example of a semiconductor device. FIG. 2B is a plan view illustrating the example of the semiconductor device.

FIG. 3A and FIG. 3B are cross-sectional views illustrating examples of a semiconductor device.

FIG. 4 is a cross-sectional view illustrating an example of a semiconductor device.

FIG. 5A and FIG. 5B are cross-sectional views illustrating examples of a method for manufacturing a semiconductor device.

FIG. 6A and FIG. 6B are cross-sectional views illustrating an example of a method for manufacturing a semiconductor device.

FIG. 7A and FIG. 7B are cross-sectional views illustrating examples of a method for manufacturing a semiconductor device.

FIG. 8A is a plan view illustrating an example of a semiconductor device. FIG. 8B and FIG. 8C are cross-sectional views illustrating the example of the semiconductor device.

FIG. 9A and FIG. 9B are cross-sectional views illustrating an example of a method for manufacturing a semiconductor device.

FIG. 10A to FIG. 10C are cross-sectional views illustrating an example of a method for manufacturing a semiconductor device.

FIG. 11A and FIG. 11B are cross-sectional views illustrating an example of a method for manufacturing a semiconductor device.

FIG. 12A to FIG. 12C are cross-sectional views illustrating an example of a method for manufacturing a semiconductor device.

FIG. 13 is a cross-sectional view illustrating an example of a semiconductor device.

FIG. 14A to FIG. 14C are cross-sectional views illustrating an example of a method for manufacturing a semiconductor device.

FIG. 15A to FIG. 15C are cross-sectional views illustrating an example of a method for manufacturing a semiconductor device.

FIG. 16A is a plan view illustrating an example of a memory device. FIG. 16B and FIG. 16C are cross-sectional views illustrating the example of the memory device.

FIG. 17A is a plan view illustrating an example of a memory device. FIG. 17B is a cross-sectional view illustrating the example of the memory device.

FIG. 18 is a cross-sectional view illustrating an example of a memory device.

FIG. 19 is a cross-sectional view illustrating an example of a memory device.

FIG. 20 is a block diagram for illustrating a structure example of a semiconductor device.

FIG. 21A to FIG. 21H are diagrams for illustrating circuit configuration examples of memory cells.

FIG. 22A and FIG. 22B are perspective views for illustrating structure examples of a semiconductor device.

FIG. 23 is a block diagram for illustrating a CPU.

FIG. 24A and FIG. 24B are perspective views of a semiconductor device.

FIG. 25A and FIG. 25B are perspective views of semiconductor devices.

FIG. 26A and FIG. 26B are diagrams illustrating hierarchies of a variety of memory devices.

FIG. 27A and FIG. 27B are perspective views illustrating an example of a display apparatus.

FIG. 28 is a cross-sectional view illustrating an example of a display apparatus.

FIG. 29 is a cross-sectional view illustrating an example of a display apparatus.

FIG. 30A to FIG. 30C are diagrams illustrating structure examples of a display apparatus.

FIG. 31A and FIG. 31B are diagrams illustrating examples of electronic components.

FIG. 32A to FIG. 32C are diagrams illustrating an example of a large computer. FIG. 32D is a diagram illustrating an example of space equipment. FIG. 32E is a diagram illustrating an example of a storage system that can be used in a data center.

FIG. 33A to FIG. 33F are diagrams illustrating examples of electronic appliances.

FIG. 34A to FIG. 34G are diagrams illustrating examples of electronic appliances.

FIG. 35A to FIG. 35F are diagrams illustrating examples of electronic appliances.

FIG. 36 is a cross-sectional view illustrating an example of a display apparatus.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

In structures of the invention described below, the same portions or portions having similar functions are denoted by the same reference numerals in different drawings, and a repeated description thereof is omitted. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Thus, the disclosed invention is not necessarily limited to the position, size, range, and the like disclosed in the drawings.

In this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

A transistor is a kind of semiconductor element and can achieve a function of amplifying current or voltage, switching operation for controlling conduction or non-conduction, and the like. A transistor in this specification includes an IGFET (Insulated Gate Field Effect Transistor) and a thin film transistor (TFT).

In this specification and the like, a transistor including an oxide semiconductor or a metal oxide in its semiconductor layer and a transistor including an oxide semiconductor or a metal oxide in its channel formation region are each referred to as an OS transistor in some cases. A transistor including silicon in its channel formation region is referred to as a Si transistor in some cases.

In this specification and the like, a transistor is an element having at least three terminals including a gate, a drain, and a source. In addition, the transistor includes a region where a channel is formed (also referred to as a channel formation region) between the drain (a drain terminal, a drain region, or a drain electrode) and the source (a source terminal, a source region, or a source electrode), and current can flow between the source and the drain through the channel formation region. In this specification and the like, a channel formation region refers to a region through which current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also functions as an impurity in some cases. Oxygen vacancies (also referred to as Vo) are formed in an oxide semiconductor in some cases by entry of impurities, for example.

In this specification and the like, an oxynitride refers to a material that includes more oxygen than nitrogen in its composition. A nitride oxide refers to a material that includes more nitrogen than oxygen in its composition.

The contents of elements such as hydrogen, oxygen, carbon, and nitrogen in a film can be analyzed by secondary ion mass spectrometry (SIMS) or X-ray photoelectron spectroscopy (XPS), for example. XPS is suitable when the content percentage of a target element is high (e.g., higher than or equal to 0.5 atomic %, or higher than or equal to 1 atomic %). By contrast, SIMS is suitable when the content percentage of a target element is low (e.g., lower than or equal to 0.5 atomic %, or lower than or equal to 1 atomic %). To compare the contents of elements, a combined analysis using both SIMS and XPS is further preferably performed.

The term “film” and the term “layer” can be used interchangeably depending on the case or the circumstances. For example, the term “conductive layer” can be replaced with the term “conductive film”. For another example, the term “insulating film” can be replaced with the term “insulating layer”.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, “electrically connected” includes the case where components are connected to each other through an “object having any electric action”. There is no particular limitation on an “object having any electric function” as long as electric signals can be transmitted and received between components that are connected through the object. Examples of the “object having any electric function” include a switching element such as a transistor, a resistor, a coil, and other elements with a variety of functions as well as an electrode or a wiring.

Unless otherwise specified, off-state current in this specification and the like refers to leakage current between a source and a drain generated when a transistor is in an off state (also referred to as a non-conducting state or a cutoff state). Unless otherwise specified, an off state in an n-channel transistor refers to a state where a voltage Vgs between its gate and source is lower than a threshold voltage Vth (in a p-channel transistor, higher than Vth).

In this specification and the like, “normally-on characteristics” mean a state where a channel exists and current flows through a transistor even when no voltage is applied to a gate. Furthermore, “normally-off characteristics” mean a state where current does not flow through a transistor when no potential or a ground potential is applied to a gate.

In this specification and the like, a top surface shape of a component means the contour shape of the component in a plan view. A plan view means that the component is observed from a normal direction of a formation surface of the component or a surface of a support (e.g., a substrate) where the component is formed.

In this specification and the like, the expression “having substantially the same top-view shapes” means that at least outlines of stacked layers partly overlap with each other. For example, the case of processing an upper layer and a lower layer with the use of the same mask pattern or mask patterns that are partly the same is included. However, in some cases, the outlines do not strictly overlap with each other and the upper layer is positioned inward from the lower layer or the upper layer is positioned outward from the lower layer; such a case is also represented by the expression “having substantially the same top-view shapes”. In the case where the top-view shapes are the same or substantially the same, it can be said that the end portions are aligned or substantially aligned with each other or the side end portions are aligned or substantially aligned with each other.

In this specification and the like, a tapered shape refers to such a shape that at least part of a side surface of a component is inclined with respect to a substrate surface or a formation surface. For example, a tapered shape preferably includes a region where the angle between the inclined side surface and the substrate surface or the formation surface (also referred to as a taper angle) is greater than 0° and less than 90°. Note that the side surface of the component, the substrate surface, and the formation surface are not necessarily completely flat, and may have a substantially planar shape with a small curvature or a substantially planar shape with slight unevenness.

In this specification and the like, when the expression “A is in contact with B” is used, at least part of A is in contact with B. In other words, A includes a region in contact with B, for example.

In this specification and the like, when the expression “A is positioned over B” is used, at least part of A is positioned over B. In other words, A includes a region positioned over B, for example.

In this specification and the like, when the expression “A covers B” is used, at least part of A covers B. In other words, A includes a region covering B, for example.

In this specification and the like, when the expression “A overlaps with B” is used, at least part of A overlaps with B. In other words, A includes a region overlapping with B, for example.

In this specification and the like, a device manufactured using a metal mask or an FMM (a fine metal mask, a high-resolution metal mask) may be referred to as a device having an MM (metal mask) structure. In this specification and the like, a device manufactured without using a metal mask or an FMM may be referred to as a device having an MML (metal maskless) structure.

In this specification and the like, a structure in which light-emitting layers of light-emitting elements (also referred to as light-emitting devices) having different emission wavelengths are separately formed is sometimes referred to as an SBS (Side By Side) structure. The SBS structure can optimize materials and structures of light-emitting elements and thus can extend freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other in some cases. One layer may have two or three functions of the carrier-injection layer, the carrier-transport layer, and the carrier-blocking layer in some cases.

In this specification and the like, a light-emitting element includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (which may be referred to as a mask layer) is positioned above at least a light-emitting layer (more specifically, a layer processed into an island shape among layers included in an EL layer) and has a function of protecting the light-emitting layer in the manufacturing process.

In this specification and the like, the term “island shape” refers to a state where two or more layers formed using the same material in the same step are physically separated from each other. For example, the term “island-shaped EL layer” refers to a state where the EL layer and its adjacent EL layer are physically separated from each other.

In this specification and the like, step disconnection refers to a phenomenon in which a layer, a film, or an electrode is split because of the shape of the formation surface (e.g., a step).

Note that in the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

### Embodiment 1

In this embodiment, a semiconductor device of one embodiment of the present invention is described.

The semiconductor device of one embodiment of the present invention includes a first conductive layer, a second conductive layer, a third conductive layer, an oxide semiconductor layer, a first insulating layer, and a second insulating layer.

The first insulating layer is positioned over the first conductive layer, and the second conductive layer is positioned over the first insulating layer. The first insulating layer and the second conductive layer have an opening reaching the first conductive layer. In the opening, the oxide semiconductor layer is in contact with at least the top surface of the first conductive layer, a side surface of the first insulating layer, and a side surface of the second conductive layer. The second insulating layer is positioned over the oxide semiconductor layer in the opening. The third conductive layer overlaps with the oxide semiconductor layer with the second insulating layer therebetween in the opening. Note that the opening is also referred to as an opening portion.

The first conductive layer functions as one of a source electrode and a drain electrode of a transistor. The second conductive layer functions as the other of the source electrode and the drain electrode of the transistor. The third conductive layer functions as a gate electrode of the transistor, and the second insulating layer functions as a gate insulating layer.

Although “in a cross-sectional view” is simply used in this specification and the like, it is rephrased as, specifically, “in a cross-sectional view from the same direction” in some cases. For example, in the case where the relation between a plurality of components is described, a relation in a cross-sectional view from the same direction is described. In that case, the relation between the plurality of components can be described using one cross-sectional view.

In the transistor of one embodiment of the present invention, the source electrode and the drain electrode are positioned at different levels, and current flowing in the semiconductor layer flows in the height direction. In other words, the channel length direction includes a component of the height direction (vertical direction); accordingly, the transistor of one embodiment of the present invention can also be referred to as a VFET (Vertical Field Effect Transistor), a vertical transistor, a vertical-channel transistor, a vertical-channel-type transistor, or the like.

In the transistor of one embodiment of the present invention, the source electrode, the semiconductor layer, and the drain electrode can be provided to overlap with each other; thus, the area occupied by the transistor can be significantly smaller than the area occupied by what is called a planar transistor in which a semiconductor layer is provided in a planar shape.

In this specification and the like, the expression “end portions are aligned” means that outlines of stacked layers at least partly overlap with each other in a plan view. For example, the case of processing an upper layer and a lower layer with the use of the same mask pattern or mask patterns that are partly the same is included. Note that, in some cases, the outlines do not strictly overlap with each other and the outline of the upper layer is positioned inward from the outline of the lower layer or the outline of the upper layer is positioned outward from the outline of the lower layer; such a case is also represented by the expression “end portions are aligned”.

In general, it is sometimes difficult to clearly differentiate “completely aligned” from “substantially aligned”. Thus, in this specification and the like, the expression “aligned” includes both “completely aligned” and “substantially aligned”, in some cases.

### Structure Example 1 of Semiconductor Device

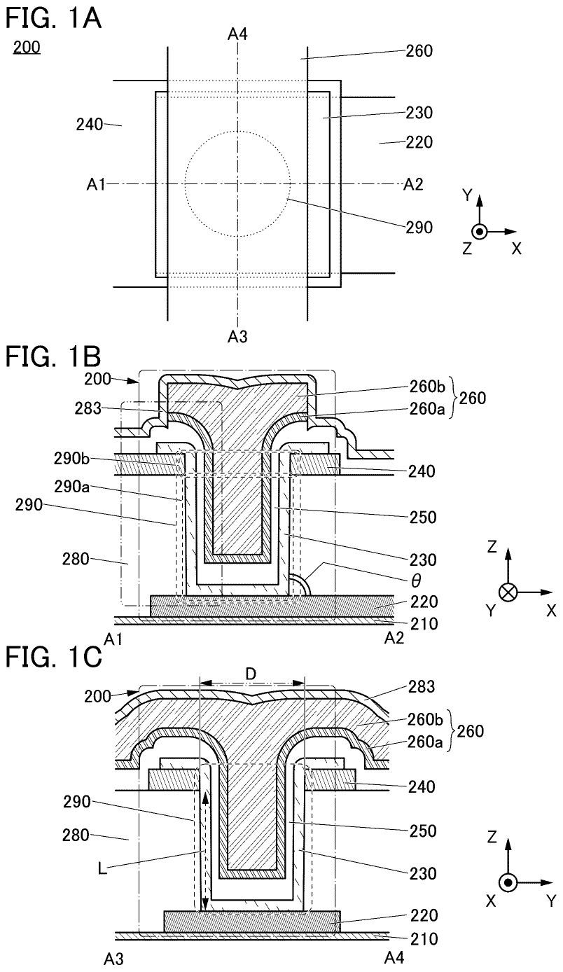

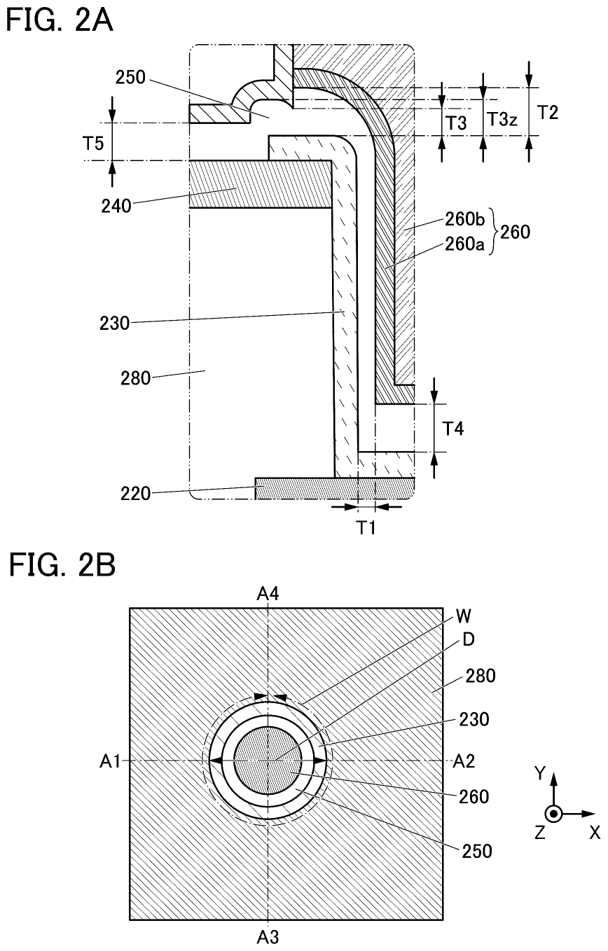

Structures of the semiconductor device of one embodiment of the present invention will be described with reference to FIG. 1A to FIG. 3B. FIG. 1A is a plan view of a semiconductor device including a transistor 200. FIG. 1B is a cross-sectional view taken along dashed-dotted line A1-A2 in FIG. 1A. FIG. 1C is a cross-sectional view taken along dashed-dotted line A3-A4 in FIG. 1A. FIG. 2A is an enlarged view of a region surrounded by a dashed double-dotted line in FIG. 1B. FIG. 2B is a cross-sectional view along the XY plane including an insulating layer 280. Note that some components are omitted in the plan view in FIG. 1A for the sake of clarity of the drawing. Some components are omitted also in the following plan views in some cases.

The semiconductor device illustrated in FIG. 1A to FIG. 1C, FIG. 2A, and FIG. 2B includes an insulating layer 210 over a substrate (not illustrated), the transistor 200 over the insulating layer 210, the insulating layer 280 over the insulating layer 210, and an insulating layer 283 over the transistor 200. The insulating layer 210, the insulating layer 280, and the insulating layer 283 function as interlayer films.

The transistor 200 includes a conductive layer 220, a conductive layer 240 over the insulating layer 280, an oxide semiconductor layer 230, an insulating layer 250 over the oxide semiconductor layer 230, and a conductive layer 260 over the insulating layer 250. The conductive layer 220 and the conductive layer 240 are positioned at different levels. The insulating layer 283 covers the top surface and a side surface of the conductive layer 260. Although FIG. 1B, FIG. 1C, and the like illustrate an example in which the conductive layer 260 has a two-layer stacked structure of a conductive layer 260a and a conductive layer 260b over the conductive layer 260a, the conductive layer 260 may include three or more layers or may be a single layer.

As illustrated in FIG. 1B and FIG. 1C, an opening 290 reaching the conductive layer 220 is provided in the insulating layer 280 and the conductive layer 240. Here, the top surface of the conductive layer 220 corresponds to a bottom portion of the opening 290, and a side surface of the insulating layer 280 and a side surface of the conductive layer 240 correspond to a sidewall of the opening 290. The opening 290 includes an opening provided in the insulating layer 280 and an opening provided in the conductive layer 240. In other words, the opening provided in a region where the insulating layer 280 overlaps with the conductive layer 220 is part of the opening 290, and the opening provided in a region where the conductive layer 240 overlaps with the conductive layer 220 is another part of the opening 290. Note that the opening 290 provided in the insulating layer 280 is referred to as an opening 290a, and the opening 290 provided in the conductive layer 240 is referred to as an opening 290b.

At least part of the components of the transistor 200 are placed inside the opening 290. Specifically, each of the oxide semiconductor layer 230, the insulating layer 250, and the conductive layer 260 is placed such that at least part thereof is positioned inside the opening 290. The oxide semiconductor layer 230 is in contact with the top surface of the conductive layer 220, the side surface of the insulating layer 280, and the side surface of the conductive layer 240 in the opening 290.

The part of the oxide semiconductor layer 230 and the insulating layer 250 that are placed inside the opening 290 reflect the shape of the opening 290. Specifically, the oxide semiconductor layer 230 is provided to cover the bottom portion and the sidewall of the opening 290, and the insulating layer 250 is provided to cover the oxide semiconductor layer 230. The conductive layer 260 is provided to fill a depressed portion of the insulating layer 250 that reflects the shape of the opening 290. The oxide semiconductor layer 230 is preferably provided in contact with a sidewall of the insulating layer 280 in the opening 290a. The insulating layer 250 is placed to face the sidewall of the insulating layer 280 in the opening 290a with the oxide semiconductor layer 230 therebetween.

The width of the opening 290 is referred to as a width D. The width D varies in the depth direction, in some cases. The width D can be the width of an upper end of the opening 290 in the insulating layer 280, for example. Alternatively, the width D can be the width of a lower end of the opening 290. Alternatively, the width D can be the width at half of the depth of the opening 290 in the insulating layer 280. Alternatively, the width of the opening 290 in the conductive layer 240 can be used.

A region of the oxide semiconductor layer 230 that is in contact with the conductive layer 240 functions as a low-resistance region in some cases.

In the transistor 200, the oxide semiconductor layer 230 functions as a semiconductor layer, the conductive layer 260 functions as a gate electrode, the insulating layer 250 functions as a gate insulating layer, the conductive layer 220 functions as one of a source electrode and a drain electrode, and the conductive layer 240 functions as the other of the source electrode and the drain electrode.

As described above, the oxide semiconductor layer 230 is provided inside the opening 290 provided in the insulating layer 280. The transistor 200 has a structure in which current flows in the vertical direction since one of the source electrode and the drain electrode (here, the conductive layer 220) is positioned on the lower side and the other of the source electrode and the drain electrode (here, the conductive layer 240) is positioned on the upper side. That is, a channel is formed along the sidewall of the opening provided in the insulating layer 280.

The oxide semiconductor layer 230 is in contact with the top surface of the conductive layer 220 and the side surface of the conductive layer 240 inside the opening 290. The oxide semiconductor layer 230 is also in contact with part of the top surface of the conductive layer 240. When the oxide semiconductor layer 230 is in contact with not only the side surface of the conductive layer 240 but also the top surface of the conductive layer 240 as described above, the area where the oxide semiconductor layer 230 and the conductive layer 240 are in contact with each other can be increased as compared with the case where the oxide semiconductor layer 230 is not in contact with the top surface of the conductive layer 240 but in contact with the side surface of the conductive layer 240, for example. Thus, the contact resistance between the oxide semiconductor layer 230 and the conductive layer 240 can be reduced.

The conductive layer 240 has the opening 290b in a region overlapping with the conductive layer 220. It is preferable that the conductive layer 240 not be provided inside the opening 290a provided in the insulating layer 280. That is, it is preferable that the conductive layer 240 not include a region in contact with the side surface of the insulating layer 280 in the opening 290a. With such a structure, the opening 290b provided in the conductive layer 240 and the opening 290a provided in the insulating layer 280 can be collectively formed. When the side surface of the conductive layer 240 in the opening 290b is aligned or substantially aligned with the side surface of the insulating layer 280 in the opening 290a, the thickness distribution of the oxide semiconductor layer 230 provided inside the opening 290 can be uniform. In addition, the oxide semiconductor layer 230 can be inhibited from being divided by a step between the conductive layer 240 and the insulating layer 280.

The conductive layer 260 includes a region positioned over the insulating layer 280. In FIG. 1B and FIG. 1C, the conductive layer 260 includes, over the insulating layer 280, a region that covers each of the conductive layer 240, the oxide semiconductor layer 230, and the insulating layer 250.

The conductive layer 240 preferably includes a region not covered with the conductive layer 260. In the region not overlapping with the conductive layer 260, an end portion of the conductive layer 240 is positioned outward from an end portion of the conductive layer 260. In the region not overlapping with the conductive layer 260, a conductive layer can be provided over the conductive layer 240, and the conductive layer and the conductive layer 240 can be electrically connected to each other.

FIG. 1B illustrates a structure in which the end portion of the conductive layer 240 is positioned outward from the end portion of the conductive layer 260 on the outside of the opening 290. With such a structure, a plug or the like can be provided over a region of the conductive layer 240 that extends outward from the conductive layer 260, so as to electrically connect the conductive layer 240 and a conductive layer such as a wiring, an electrode, or the like positioned above the conductive layer 260 to each other.

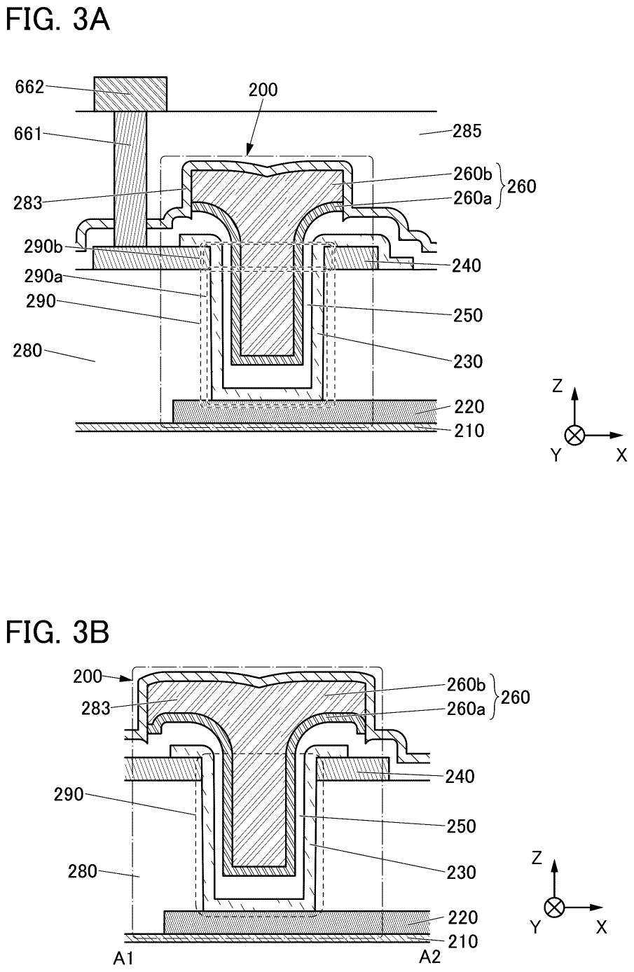

FIG. 3A illustrates an example of a semiconductor device including, over the transistor 200, the insulating layer 283; an insulating layer 285 over the insulating layer 283; a conductive layer 661 provided to penetrate the insulating layer 250, the insulating layer 283, and the insulating layer 285; and a conductive layer 662 over the conductive layer 661 and the insulating layer 285. The conductive layer 661 is preferably provided in contact with the top surface of the conductive layer 240. The conductive layer 240 is electrically connected to the conductive layer 662 through the conductive layer 661.

The insulating layer 250 is provided in contact with the top surface of the oxide semiconductor layer 230. The insulating layer 250 preferably includes a region in contact with the top surface of the conductive layer 240, a region in contact with the side surface of the conductive layer 240, and a region in contact with the top surface of the insulating layer 280.

The sidewall of the opening 290 is preferably perpendicular to the top surface of the insulating layer 210. With such a structure, the semiconductor device can be miniaturized or highly integrated. In that case, films provided inside the opening 290 are each preferably formed by an atomic layer deposition (ALD) method. An ALD method, which enables atomic layers to be deposited one by one, has effects such as enabling formation of an extremely thin film, enabling film formation on a component with a high aspect ratio, enabling formation of a film with a small number of defects such as pinholes, enabling film formation with excellent coverage, and enabling low-temperature film formation. Thus, the films can be formed on the sidewall of the opening 290 with favorable coverage. For example, the oxide semiconductor layer 230 and the conductive layer 260 can each be formed by an ALD method. In the case where the oxide semiconductor layer 230 and the conductive layer 260 each have a stacked-layer structure, for example, one or more of the stacked layers are preferably formed by an ALD method. It is particularly preferable that, between the conductive layer 260a and the conductive layer 260b, the conductive layer 260a be formed by an ALD method, for example. The conductive layer 260 filling the opening 290 can increase the cross-sectional area of the conductive layer 260 and reduce the resistance. Accordingly, for example, the conductive layer 260b is formed by a sputtering method, a PECVD method, or the like so that the conductive layer 260 can be formed to fill the opening 290.

It is preferable that the insulating layer 250 favorably cover the sidewall of the opening 290 and inhibit a short circuit between the conductive layer 240 and the conductive layer 260.

As illustrated in FIG. 1B and FIG. 1C, part of the insulating layer 250 is positioned outside the opening 290, that is, over the conductive layer 240 and the insulating layer 280. In that case, the insulating layer 250 preferably covers the end portion of the oxide semiconductor layer 230. This can prevent a short circuit between the conductive layer 260 and the oxide semiconductor layer 230. The insulating layer 250 preferably covers the end portion of the conductive layer 240. This can prevent a short circuit between the conductive layer 260 and the conductive layer 240.

The insulating layer 250 functions as the gate insulating layer of the transistor 200. When the gate insulating layer is thin, a gate potential applied during the operation of the transistor 200 can be reduced. In addition, the transistor 200 can operate at high speed.

Meanwhile, there is a concern that making the gate insulating layer thin may increase leakage current through the gate insulating layer of the transistor. There is also a concern that the gate-drain breakdown voltage or the like of the transistor is reduced. Such a concern is more noticeable particularly when the gate insulating layer is overetched or the gate insulating layer is damaged in the processing for the transistor.

The insulating layer 250 is exposed to an etching atmosphere in a region outward from the end portion of the conductive layer 260 at the time of forming the conductive layer 260 and thus might be damaged by the etching. The damage due to the etching might reduce the breakdown voltage of the insulating layer 250. In particular, when dry etching is used in the step of forming the conductive layer 260, the damage due to the etching is sometimes more noticeable.

The insulating layer 250 is not covered with the conductive layer 260 in the region outward from the end portion of the conductive layer 260. Thus, the thickness of the insulating layer 250 sometimes becomes smaller in the region outward from the end portion of the conductive layer 260 than in a region overlapping with the conductive layer 260 because of overetching in the step of forming the conductive layer 260. The reduction in thickness of the insulating layer 250 due to the overetching is sometimes more noticeable particularly when dry etching is used in the step of forming the conductive layer 260. In the region of the insulating layer 250 where the thickness is reduced, the breakdown voltage might be reduced. Here, overetching refers to, for example, etching of the insulating layer 250 in a region where the insulating layer 250 is exposed after removal of part of the conductive layer 260, by dry etching treatment performed for the purpose of etching of the conductive layer 260.

In the region of the insulating layer 250 where the breakdown voltage is reduced, for example, gate leakage current that flows because of the electric field between the conductive layer 260 and the conductive layer 240 might increase. In the case where the damage to the insulating layer 250 or the reduction in the thickness of the insulating layer 250 is noticeable, a short circuit between the conductive layer 260 and the conductive layer 240 might occur, for example.

In the transistor of one embodiment of the present invention, the thickness of the insulating layer 250 in a region sandwiched between the top surface of the conductive layer 240 and the conductive layer 260 (a thickness T2 described later) is preferably larger than the thickness in a region provided to face the sidewall of the insulating layer 280 in the opening 290a (a thickness T1 described later). With such a structure, the thickness of the insulating layer 250 in a region that covers the top surface of the conductive layer 240 and is not covered with the conductive layer 260 (a thickness T3 described later) can be sufficient to inhibit gate leakage current and a short circuit even in the case where the thickness of the insulating layer 250 is reduced by the overetching in the formation of the conductive layer 260.

FIG. 2A illustrates the thicknesses of five regions (thicknesses T1, T2, T3, T4, and T5) in the insulating layer 250.

The thickness T1 is the thickness of the insulating layer 250 in the region provided to face the sidewall of the insulating layer 280 in the opening 290a. In the region, the insulating layer 250 faces the sidewall of the opening 290a with the oxide semiconductor layer 230 therebetween.

The thickness T2 is the thickness of the insulating layer 250 in the region sandwiched between the top surface of the conductive layer 240 and the conductive layer 260. In the region, the insulating layer 250 covers the top surface of the conductive layer 240 with the oxide semiconductor layer 230 therebetween.

The thickness T3 is the thickness of the insulating layer 250 in the region that covers the top surface of the conductive layer 240 with the oxide semiconductor layer 230 therebetween and is not covered with the conductive layer 260. FIG. 2A illustrates the thickness of the insulating layer 250 in a region that is outside the end portion of the conductive layer 260 and is extremely close to the end portion as the thickness T3; however, in the case where there is a region having a different thickness like a thickness T3z in FIG. 2A (a thick region in the case of FIG. 2A), for example, the thickness of the thinnest region can be regarded as the thickness T3. Alternatively, in observation of the cross-sectional view, the average thickness of the corresponding region may be regarded as the thickness T3.

The thickness T1, the thickness T2, and the thickness T5 that is described later each have a thickness distribution in the corresponding region in some cases. In such a case, the thickness of the thinnest region can be regarded as the thickness of the region, for example. Alternatively, the thickness of the thickest region can be regarded as the thickness of the region, for example. Alternatively, the average thickness of the region can be regarded as the thickness of the region, for example.

The thickness T4 is the thickness of the insulating layer 250 in a region sandwiched between the top surface of the conductive layer 220 and the conductive layer 260. In the region, the insulating layer 250 covers the top surface of the conductive layer 220 with the oxide semiconductor layer 230 therebetween.

The thickness T5 is the thickness of the insulating layer 250 in a region that covers the top surface of the conductive layer 240 and does not overlap with the oxide semiconductor layer 230. The thickness T5 can also be expressed as the thickness in a region that covers the top surface of the conductive layer 240 and is positioned outward from the end portion of the oxide semiconductor layer 230 in a top view.

The thickness T2 and the thickness T4 are substantially the same, for example. The thickness T4 is, for example, greater than or equal to 0.8 times and less than or equal to 1.2 times the thickness T2. A portion of the insulating layer 250 that is positioned at the bottom portion of the opening 290 does not have a uniform thickness and has a larger thickness in the middle portion, for example, in some cases. In that case, the thickness T4 can be the thickness of the thickest part of the insulating layer 250, for example.

The thickness T2 is larger than the thickness T1. Since the thickness T2 and the thickness T4 are substantially the same, the thickness T4 is larger than the thickness T1. When the thickness T2 is made large, parasitic capacitance between the conductive layer 240 and the conductive layer 260 can be reduced. Furthermore, when the thickness T4 is made large, parasitic capacitance between the conductive layer 220 and the conductive layer 260 can be reduced.

In the case where the insulating layer 250 is etched because of the overetching at the time of the processing for the conductive layer 260, the thickness T3 is smaller than the thickness T2. In that case, in order that the thickness T3 can be sufficient to inhibit a short circuit between the conductive layer 260 and the conductive layer 240 or gate leakage through the insulating layer 250, the thickness T2 needs to take a thickness to be reduced by the overetching into account.

In the case where the thickness T2 is too large, on the other hand, the aspect ratio of an opening to be filled with the conductive layer 260 is high, which sometimes makes it difficult to improve the coverage of the insulating layer 250 with the conductive layer 260. Thus, the thickness T2 is less than or equal to 100 nm, for example.

The thickness T1 is the thickness of the insulating layer 250 in a region that can function as the gate insulating layer in a channel formation region of the transistor 200. The thickness T1 is preferably greater than or equal to 0.1 nm and less than or equal to 30 nm, preferably greater than or equal to 0.1 nm and less than or equal to 20 nm, preferably greater than or equal to 0.1 nm and less than or equal to 10 nm, preferably greater than or equal to 0.1 nm and less than or equal to 8.0 nm, further preferably greater than or equal to 0.1 nm and less than or equal to 7.0 nm.

The thickness T3 is preferably greater than or equal to 1.0 nm and less than or equal to 100 nm, preferably greater than or equal to 2.0 nm and less than or equal to 100 nm, further preferably greater than or equal to 3.0 nm and less than or equal to 100 nm, still further preferably greater than or equal to 4.0 nm and less than or equal to 100 nm, yet still further preferably greater than or equal to 5.0 nm and less than or equal to 100 nm, for example.

The thickness T2 and the thickness T4 are each larger than or equal to the thickness T3, for example. The thickness T2 and the thickness T4 are sometimes larger than the thickness T3 by 2 nm or more, for example.

The thickness T5 is substantially the same as the thickness T3, for example. The thickness T5 is preferably greater than or equal to 1.0 nm and less than or equal to 50 nm, preferably greater than or equal to 2.0 nm and less than or equal to 50 nm, further preferably greater than or equal to 3.0 nm and less than or equal to 50 nm, still further preferably greater than or equal to 4.0 nm and less than or equal to 50 nm, yet still further preferably greater than or equal to 5.0 nm and less than or equal to 50 nm, for example.

The thickness T2 and the thickness T4 are each larger than or equal to the thickness T5, for example. The thickness T2 and the thickness T4 are sometimes larger than the thickness T5 by 2 nm, for example.

As a film formation method of the insulating layer 250, for example, a method is preferably used in which the film formation rate is lower on a plane where a formation surface is perpendicular to a substrate surface than on a plane where the formation surface is parallel to the substrate surface. Such a film formation method can also be expressed as a film formation method with deposition rate anisotropy.

The use of such a method can make the thickness of the insulating layer 250 small in the region that can function as the gate insulating layer in the channel formation region of the transistor. Accordingly, the driving voltage of the transistor 200 can be reduced and the operation speed can be increased. Furthermore, the thickness of the insulating layer 250 can be large in a region that covers the top surface of the conductive layer 240. Accordingly, a reduction in thickness of the insulating layer 250 in the transistor 200 can be inhibited, leading to a reduction in gate leakage current in the transistor 200 and inhibition of a reduction in breakdown voltage of the transistor 200.

As a method for forming the insulating layer 250 illustrated in FIG. 1B, FIG. 1C, FIG. 2A, and the like, a sputtering method, a CVD method, or the like can be used.

As a sputtering method, for example, an ionization sputtering method, a long throw sputtering method, or the like can be used. The ionization sputtering method is a method in which a sputtering particle generated from a target is ionized by RF or the like and film formation is performed with anisotropy by a self bias or the like. In the long throw sputtering method, the distance between a sputtering target and a substrate is made long to enable anisotropic film formation; the distance between the sputtering target and the substrate is preferably greater than or equal to 60 mm, further preferably greater than or equal to 100 mm.

As a CVD method, for example, a plasma-enhanced chemical vapor deposition (PECVD) method can be used. Here, a PECVD method using RF is preferably used. In the case of forming an insulating layer, in particular, the use of RF enables discharge of plasma to be more stable.

Here, FIG. 1B and FIG. 1C illustrate a structure in which the end portion of the oxide semiconductor layer 230 is positioned inward from the end portion of the conductive layer 240 on the outside of the opening 290. Note that the present invention is not limited thereto. For example, in the X direction, the end portion of the oxide semiconductor layer 230 and the end portion of the conductive layer 240 are aligned with or substantially aligned with each other in some cases. Alternatively, the end portion of the oxide semiconductor layer 230 is positioned outward from the end portion of the conductive layer 240 in some cases. In FIG. 3A, for example, in the X direction, an end portion of the conductive layer 240 on the side where the conductive layer 661 is provided on the top surface (in the negative direction of X) is positioned outward from the end portion of the oxide semiconductor layer 230, and as for an end portion on the other side (in the positive direction of X), the end portion of the oxide semiconductor layer 230 is positioned outward from the end portion of the conductive layer 240 and the oxide semiconductor layer 230 covers the end portion of the conductive layer 240. When the oxide semiconductor layer 230 covers the end portion of the conductive layer 240, the breakdown voltage between the conductive layer 240 and the conductive layer 260 can be further increased, and leakage current through the insulating layer 250 positioned between the conductive layer 240 and the conductive layer 260 can be further reduced in some cases.

As illustrated in FIG. 3B, the end portion of the conductive layer 260 in the X direction is positioned outward from the end portion of the oxide semiconductor layer 230 in some cases. In the case where the conductive layer 260 includes a light-blocking material, current induced by light in the oxide semiconductor layer 230 is inhibited in a region covered with the conductive layer 260, so that the characteristics and reliability of the transistor are improved in some cases. When a region functioning as the low-resistance region in the oxide semiconductor layer 230 overlaps with the conductive layer 260, the resistance can be further reduced and the on-state current of the transistor can be further improved in some cases.

The sidewall of the opening 290 is preferably provided so as to be perpendicular to the top surface of the insulating layer 210, for example. An angle θ formed between the side surface of the insulating layer 280 in the opening 290 and the top surface of the insulating layer 210 is illustrated in FIG. 1B. The angle θ is preferably greater than 60° and less than or equal to 90°, further preferably greater than or equal to 70° and less than or equal to 90°, still further preferably greater than or equal to 80° and less than or equal to 90°. The angle θ preferably has such a value, in which case the insulating layer 250 can have anisotropy and the insulating layer 250 can be thin in a region that covers the sidewall of the opening 290. Furthermore, the semiconductor device can be miniaturized or highly integrated, which is preferable.

Alternatively, for example, the sidewall of the opening 290 may have an inverse tapered shape in some cases. In other words, the angle formed between the side surface of the insulating layer 280 in the opening 290 and the top surface of the insulating layer 210 may be greater than 90° in some cases.

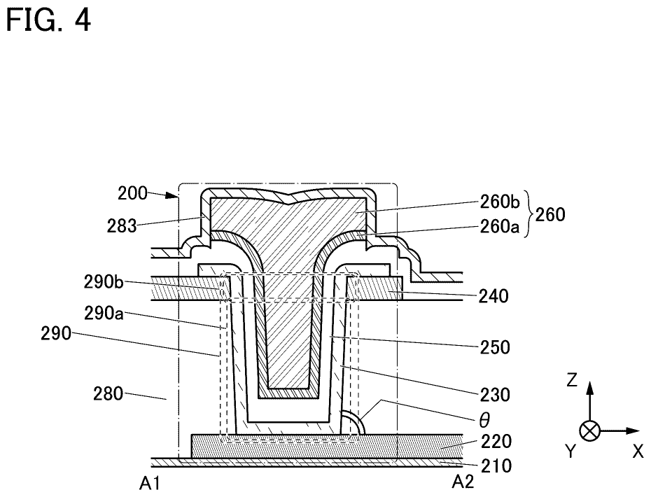

FIG. 4 illustrates an example in which the angle θ is less than 90°.

Although FIG. 1B and FIG. 1C illustrate the structure in which the side surface of the conductive layer 240 in the opening 290b and the side surface of the insulating layer 280 in the opening 290a are aligned with or substantially aligned with each other, the present invention is not limited thereto. For example, the side surface of the conductive layer 240 in the opening 290b and the side surface of the insulating layer 280 in the opening 290a may be discontinuous. The inclination of the side surface of the conductive layer 240 in the opening 290b and the inclination of the side surface of the insulating layer 280 in the opening 290a may be different from each other. In that case, for example, the angle formed between the side surface of the conductive layer 240 in the opening 290b and the top surface of the insulating layer 210 is preferably smaller than the angle formed between the side surface of the insulating layer 280 in the opening 290a and the top surface of the insulating layer 210. With such a structure, the coverage of the side surface of the conductive layer 240 in the opening 290b with the oxide semiconductor layer 230 is improved, so that defects such as voids can be reduced. In the case of employing such a structure, the thickness of the insulating layer 250 in a portion that covers the side surface of the conductive layer 240 is sometimes larger than the thickness of the insulating layer 250 in a portion that covers the sidewall of the insulating layer 280 in the opening 290a.

The insulating layer 250 may consist of two or more stacked layers. In that case, one or more layers of the plurality of layers are preferably formed with anisotropy, for example.

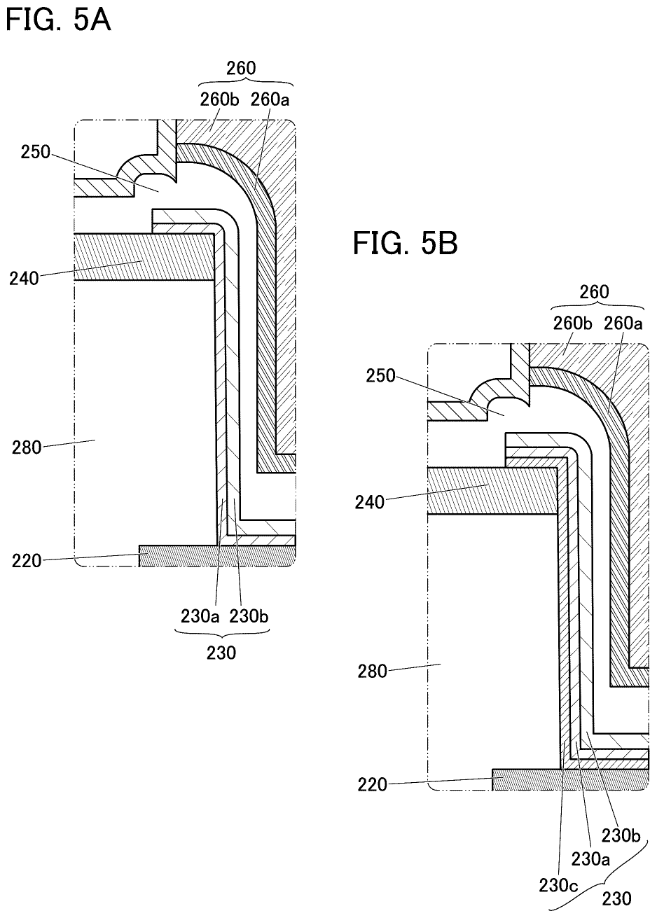

The oxide semiconductor layer 230 may have a stacked-layer structure of two or more layers. FIG. 5A illustrates an example in which the oxide semiconductor layer 230 has a two-layer structure of an oxide layer 230a and an oxide layer 230b over the oxide layer 230a. FIG. 5B illustrates an example in which the oxide semiconductor layer 230 has a three-layer structure of an oxide layer 230c, the oxide layer 230a over the oxide layer 230c, and the oxide layer 230b over the oxide layer 230a.

### Structure Example 2 of Semiconductor Device

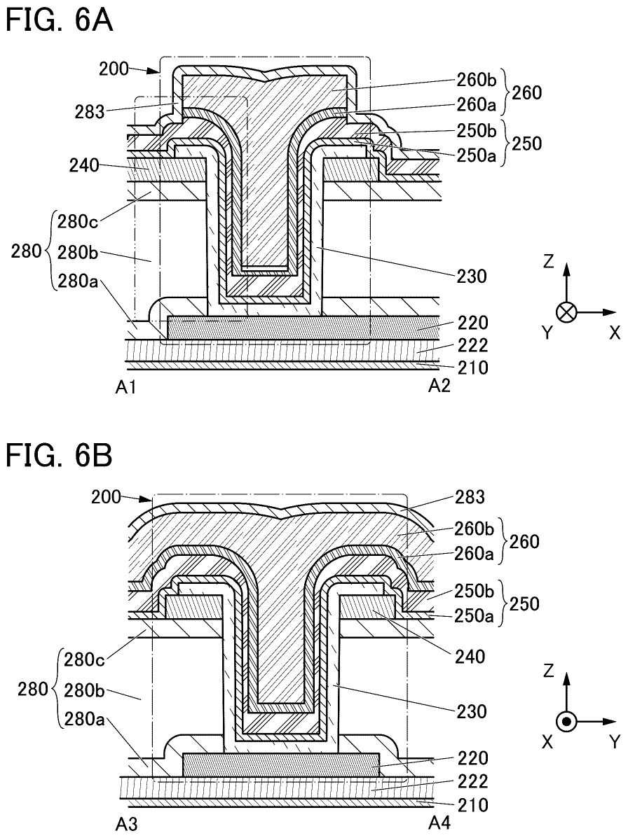

Another structure example of the semiconductor device illustrated in FIG. 1A will be described with reference to FIG. 6A and FIG. 6B.

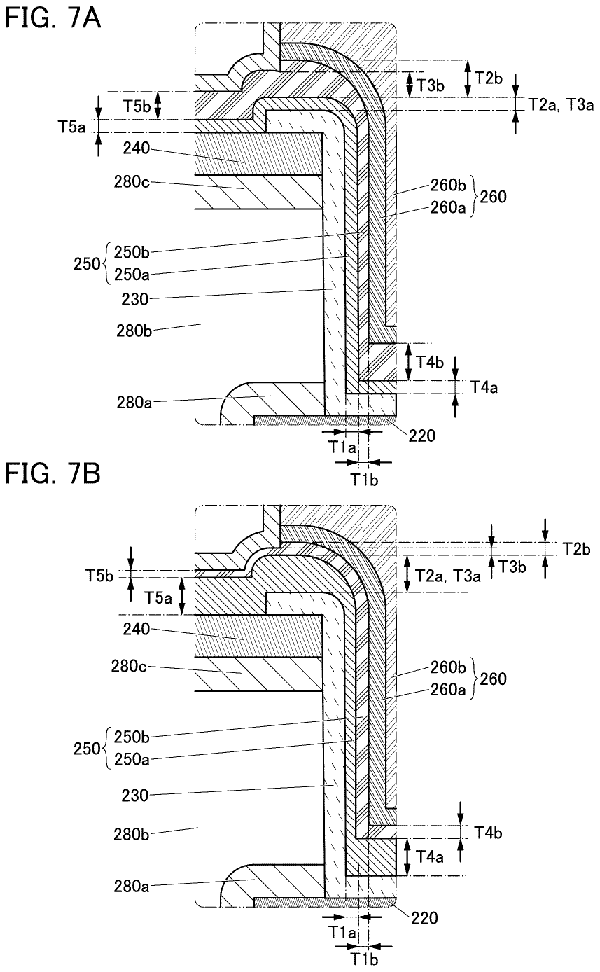

FIG. 6A and FIG. 6B are cross-sectional views taken along dashed-dotted line A1-A2 and dashed-dotted line A3-A4 in FIG. 1A, respectively, and are different from FIG. 1B and FIG. 1C in that the insulating layer 250 consists of a stack of an insulating layer 250a and an insulating layer 250b over the insulating layer 250a. FIG. 7A is an enlarged view of a region surrounded by a dashed double-dotted line in FIG. 6A.

In FIG. 6A and FIG. 6B, an insulating layer 222 is provided over the insulating layer 210, and the conductive layer 220 and the insulating layer 280 are provided over the insulating layer 222.

In FIG. 6A and FIG. 6B, the insulating layer 280 includes an insulating layer 280a, an insulating layer 280b over the insulating layer 280a, and an insulating layer 280c over the insulating layer 280b. The insulating layer 280a includes a region in contact with the top surface of the insulating layer 222, a region in contact with a side surface of the conductive layer 220, and a region in contact with the top surface of the conductive layer 220. The insulating layer 280c includes a region in contact with the bottom surface of the conductive layer 240.

The insulating layer 250a is preferably formed by a method that provides high coverage. Increasing the coverage with the insulating layer 250a enables formation of the insulating layer 250a suitably even in an opening with a high aspect ratio.

When the coverage with the insulating layer 250a is increased in a region that covers the sidewall of the insulating layer 280 in the opening 290a, i.e., a region that can function as the gate insulating layer in the channel formation region of the transistor, a gate insulating layer with a small and uniform thickness can be formed, for example.

It is particularly preferable to use an ALD method as a film formation method of the insulating layer 250a.

A film formation method that provides high coverage has low deposition rate anisotropy in some cases. The insulating layer 250a is formed by, for example, a film formation method with low deposition rate anisotropy. The thickness of the insulating layer 250a in a region sandwiched between the top surface of the conductive layer 240 and the conductive layer 260 (a thickness T2a described later) is substantially the same as the thickness in a region provided to face the sidewall of the insulating layer 280 in the opening 290a (a thickness T1a described later), for example. The insulating layer 250a is formed by a film formation method with low deposition rate anisotropy as compared with the insulating layer 250b. In other words, the insulating layer 250a is formed by a film formation method with isotropy. As a film formation method with isotropy, an ALD method can be used, for example.

The insulating layer 250b is preferably formed by a method with high deposition rate anisotropy. The thickness of the insulating layer 250b in a region sandwiched between the top surface of the conductive layer 240 and the conductive layer 260 (a thickness T2b described later) is preferably larger than the thickness in a region provided to face the sidewall of the insulating layer 280 in the opening 290a (a thickness T1b described later).

When the insulating layer 250 is obtained by combining the insulating layer 250a formed by a film formation method that provides high coverage and the insulating layer 250b formed by a method with high deposition rate anisotropy, the thickness in the region that can function as the gate insulating layer in the channel formation region of the transistor can be small and uniform, gate leakage current through the insulating layer 250 can be inhibited, and a short circuit between the conductive layer 240 and the conductive layer 260 can be inhibited. With the use of an ALD method for the insulating layer 250a, a thin, uniform, and dense gate insulating layer can be formed. FIG. 7A illustrates the thicknesses of five regions (thicknesses T1a, T2a, T3a, T4a, and T5a) in the insulating layer 250a and the thicknesses of five regions (thicknesses T1b, T2b, T3b, T4b, and T5b) in the insulating layer 250b.

The thickness T1a is the thickness of the insulating layer 250a in the region provided to face the sidewall of the insulating layer 280 in the opening 290a. In the region, the insulating layer 250a faces a sidewall of the opening 290a with the oxide semiconductor layer 230 therebetween.

The thickness T2a is the thickness of the insulating layer 250a in the region sandwiched between the top surface of the conductive layer 240 and the conductive layer 260. In the region, the insulating layer 250a covers the top surface of the conductive layer 240 with the oxide semiconductor layer 230 therebetween.

The thickness T3a is the thickness of the insulating layer 250a in the region that covers the top surface of the conductive layer 240 with the oxide semiconductor layer 230 therebetween and is not covered with the conductive layer 260.

The thickness T4a is the thickness of the insulating layer 250a in a region sandwiched between the top surface of the conductive layer 220 and the conductive layer 260. In the region, the insulating layer 250a covers the top surface of the conductive layer 220 with the oxide semiconductor layer 230 therebetween.

The thickness T5a is the thickness of the insulating layer 250a in a region that covers the top surface of the conductive layer 240 and does not overlap with the oxide semiconductor layer 230.

The thickness T1b is the thickness of the insulating layer 250b in the region provided to face the sidewall of the insulating layer 280 in the opening 290a. In the region, the insulating layer 250b faces the sidewall of the opening 290a with the oxide semiconductor layer 230 and the insulating layer 250a therebetween.

The thickness T2b is the thickness of the insulating layer 250b in the region sandwiched between the top surface of the conductive layer 240 and the conductive layer 260. In the region, the insulating layer 250b covers the top surface of the conductive layer 240 with the oxide semiconductor layer 230 and the insulating layer 250a therebetween.

The thickness T3b is the thickness of the insulating layer 250b in the region that covers the top surface of the conductive layer 240 with the oxide semiconductor layer 230 and the insulating layer 250a therebetween and is not covered with the conductive layer 260.

The thickness T4b is the thickness of the insulating layer 250b in a region sandwiched between the top surface of the conductive layer 220 and the conductive layer 260. In the region, the insulating layer 250b covers the top surface of the conductive layer 220 with the oxide semiconductor layer 230 and the insulating layer 250a therebetween.

The thickness T5b is the thickness of the insulating layer 250b in a region that covers the top surface of the conductive layer 240 and does not overlap with the oxide semiconductor layer 230.

The sum of the thickness T2a and the thickness T2b is less than or equal to 100 nm, for example.

In FIG. 7A, the thickness T2b and the thickness T4b are substantially the same, for example. The thickness T4b is, for example, greater than or equal to 0.8 times and less than or equal to 1.2 times the thickness T2b.

The thickness T2b is larger than the thickness T1b. Since the thickness T2b and the thickness T4b are substantially the same, the thickness T4b is larger than the thickness T1b.

In FIG. 7A, the thickness T2a, the thickness T3a, the thickness T4a, and the thickness T5a are each substantially the same as the thickness T1a, for example, and are each greater than or equal to 0.8 times and less than or equal to 1.2 times the thickness T1a, for example.

The sum of the thickness T1a and the thickness T1b is preferably greater than or equal to 0.2 nm and less than or equal to 30 nm, preferably greater than or equal to 0.2 nm and less than or equal to 20 nm, preferably greater than or equal to 0.2 nm and less than or equal to 10 nm, preferably greater than or equal to 0.2 nm and less than or equal to 8.0 nm, further preferably greater than or equal to 0.2 nm and less than or equal to 7.0 nm.

In FIG. 7A, the thickness T1a is greater than or equal to 0.1 nm, greater than or equal to 0.2 nm, greater than or equal to 0.5 nm, or greater than or equal to 1 nm, for example.

In FIG. 7A, the thickness T1b may be extremely small. For example, the thickness T1b may be greater than or equal to 0.1 nm and less than or equal to 1 nm, greater than or equal to 0.1 nm and less than or equal to 0.5 nm, or greater than or equal to 0.1 nm and less than or equal to 0.2 nm.

The sum of the thickness T3a and the thickness T3b is preferably greater than or equal to 1.0 nm and less than or equal to 100 nm, preferably greater than or equal to 2.0 nm and less than or equal to 100 nm, further preferably greater than or equal to 3.0 nm and less than or equal to 100 nm, preferably greater than or equal to 4.0 nm and less than or equal to 100 nm, preferably greater than or equal to 5.0 nm and less than or equal to 100 nm, for example.

The thickness T2b and the thickness T4b are each larger than or equal to the thickness T3b, for example. The thickness T2b and the thickness T4b are sometimes larger than the thickness T3b by 2 nm or more, for example.

The thickness T5b is substantially the same as the thickness T3b, for example.

Although FIG. 7A illustrates an example in which a film formed by a film formation method that provides high coverage is used as the insulating layer 250a and a film formed by a method with high deposition rate anisotropy is used as the insulating layer 250b, as illustrated in FIG. 7B, a film formed by a method with high deposition rate anisotropy may be used as the insulating layer 250a and a film formed by a film formation method that provides high coverage may be used as the insulating layer 250b.

In the structure illustrated in FIG. 7B, for example, the insulating layer 250b can be formed by an ALD method. In that case, the insulating layer 250a is formed entirely as the formation surface. In an ALD method, different materials or the like of the formation surface result in different film formation starting time in some cases. When the insulating layer 250b is formed in a state where the insulating layer 250a is formed entirely, for example, the insulating layer 250b can have its thickness and film quality more uniform.

In FIG. 7B, the thickness T2a and the thickness T4a are substantially the same, for example. The thickness T4a is, for example, greater than or equal to 0.8 times and less than or equal to 1.2 times the thickness T2a.

In FIG. 7B, the thickness T2b and the thickness T4b are each substantially the same as the thickness T1b, for example, and are each greater than or equal to 0.8 times and less than or equal to 1.2 times the thickness T1b, for example.

In FIG. 7B, the thickness T1b is greater than or equal to 0.1 nm, greater than or equal to 0.2 nm, greater than or equal to 0.5 nm, or greater than or equal to 1 nm, for example.

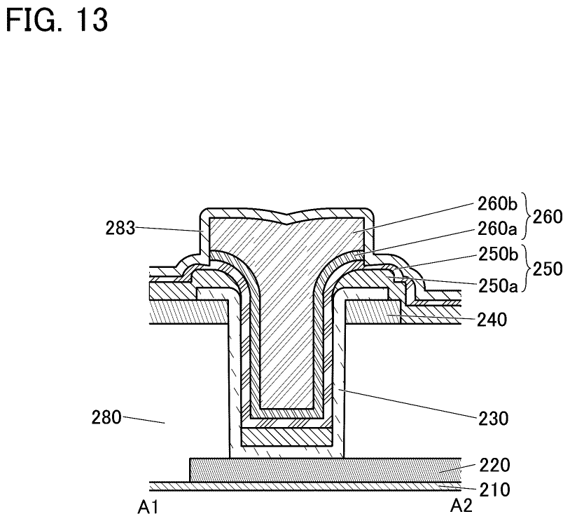

In FIG. 7B, the thickness T1a may be extremely small. For example, the thickness T1a may be greater than or equal to 0.1 nm and less than or equal to 1 nm, greater than or equal to 0.1 nm and less than or equal to 0.5 nm, or greater than or equal to 0.1 nm and less than or equal to 0.2 nm. The thickness T1a may be 0 nm as illustrated in FIG. 13 to be described later. In other words, the insulating layer 250 may consist only of the insulating layer 250a without providing the insulating layer 250b in the region provided to face the sidewall of the insulating layer 280 in the opening 290a.

The thickness of the thinnest region in the corresponding region is regarded as the thickness T3b, for example.

The thickness of the thickest region in each of the corresponding regions is regarded as the thickness T4a or the thickness T4b, for example.

The thicknesses T1a, T1b, T2a, T2b, T3a, T5a, and T5b each have a thickness distribution in the corresponding region in some cases. In such a case, the thickness of the thinnest region can be regarded as the thickness of the region, for example. Alternatively, the thickness of the thickest region can be regarded as the thickness of the region, for example. Alternatively, the average thickness of the region can be regarded as the thickness of the region, for example.

### Structure Example 3 of Semiconductor Device

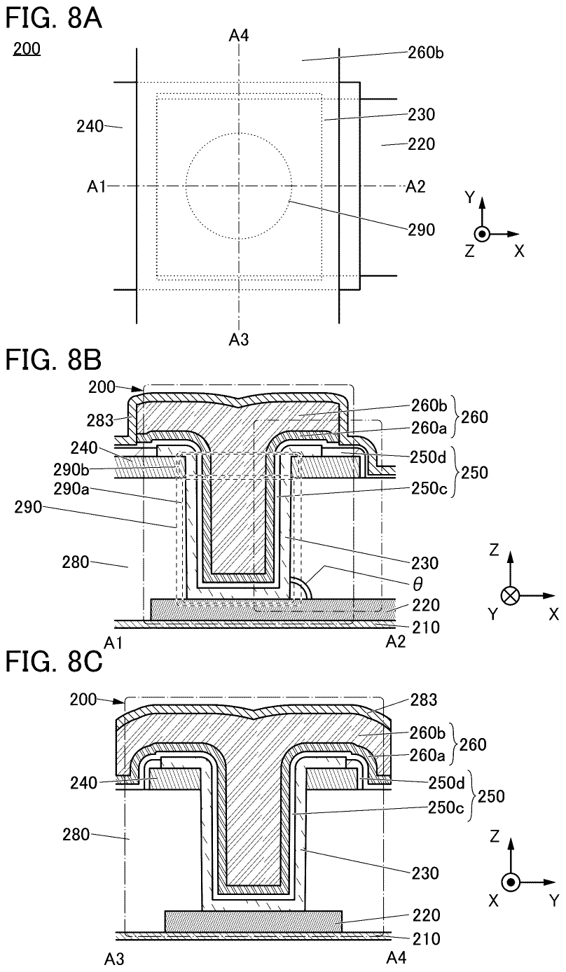

Another structure example of the semiconductor device will be described with reference to FIG. 8A to FIG. 8C.

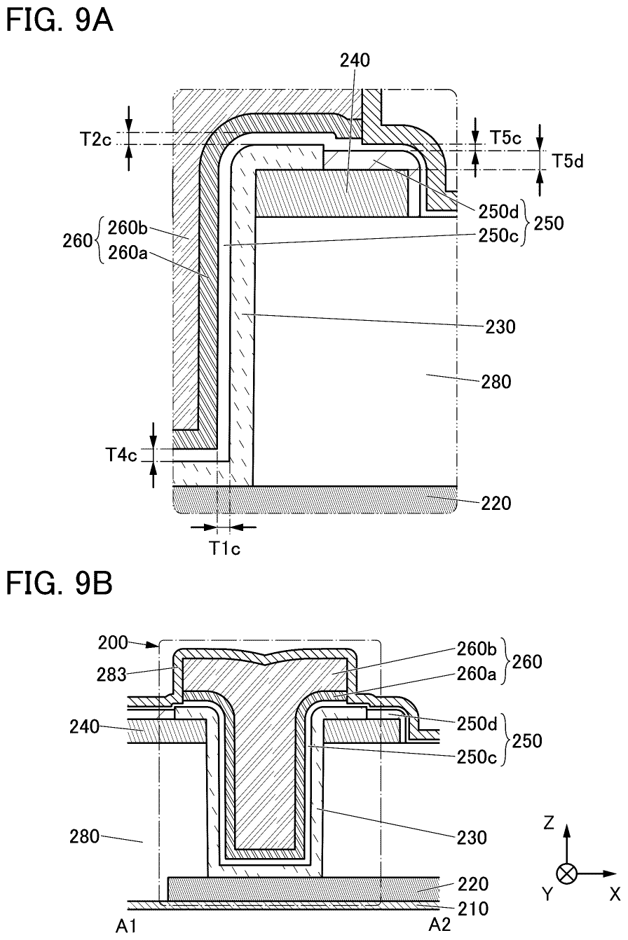

FIG. 8A is a plan view of a semiconductor device including the transistor 200. FIG. 8B is a cross-sectional view taken along dashed-dotted line A1-A2 in FIG. 8A. FIG. 8C is a cross-sectional view taken along dashed-dotted line A3-A4 in FIG. 8A. FIG. 9A is an enlarged view of a region surrounded by a dashed double-dotted line in FIG. 8B.

The semiconductor device illustrated in FIG. 8A to FIG. 8C is different from the semiconductor device illustrated in FIG. 1A to FIG. 1C in that the insulating layer 250 consists of an insulating layer 250c and an insulating layer 250d, for example.

The insulating layer 250d is placed in a region that is not covered with the oxide semiconductor layer 230 on the top surface of the conductive layer 240. In FIG. 8B and FIG. 8C, the insulating layer 250d is in contact with each of the top surface of the conductive layer 240 and the side surface of the conductive layer 240. The insulating layer 250c is placed over the oxide semiconductor layer 230, the insulating layer 250d, and the insulating layer 280. The insulating layer 250d is sandwiched between the conductive layer 240 and the insulating layer 250c.

The insulating layer 250d can be formed using, for example, a film that is selectively formed in a region where the surface of the conductive layer 240 is exposed. The insulating layer 250d is not formed in a region where the conductive layer 240 is covered with the oxide semiconductor layer 230 at the time of formation of the insulating layer 250d, for example. The conductive layer 240 preferably includes a metal layer. In the case where the conductive layer 240 has a stacked-layer structure, the uppermost layer is preferably a metal layer. For the insulating layer 250d, a film that selectively grows over a metal can be used.

Since the insulating layer 250d is selectively formed in the region where the surface of the conductive layer 240 is exposed, the thickness of the insulating layer 250 in the region where the oxide semiconductor layer 230 is not placed between the conductive layer 240 and the conductive layer 260 can be large. Consequently, leakage current through the insulating layer 250 can be reduced and the breakdown voltage can be improved. Even when the thickness of the insulating layer 250 is not large in the region where the oxide semiconductor layer 230 is placed, the leakage current through the insulating layer 250 can be reduced and the breakdown voltage can be improved because the oxide semiconductor layer 230 is placed between the conductive layer 240 and the conductive layer 260.

It can be expressed that the insulating layer 250 has a large thickness in a region that does not overlap with the oxide semiconductor layer 230 and overlaps with the conductive layer 240.

The insulating layer 250c is preferably provided in contact with the top surface of the oxide semiconductor layer 230. In FIG. 8B, FIG. 8C, and the like, the insulating layer 250c includes a region that covers the top surface of the conductive layer 240 with the insulating layer 250d therebetween and a region that covers the side surface of the conductive layer 240 with the insulating layer 250d therebetween. The insulating layer 250c is preferably provided in contact with the insulating layer 250d. The insulating layer 250c preferably includes a region in contact with the top surface of the insulating layer 280.

The insulating layer 250c can be formed by an ALD method, a CVD method, an MBE method, a PLD method, a sputtering method, or the like as appropriate.

With the use of a method that provides high coverage for the insulating layer 250c, a thin and uniform gate insulating layer can be formed.

For the insulating layer 250c, one or more materials that can be used for the insulating layer 250 can be used in combination.

In the structure illustrated in FIG. 8B and FIG. 8C, the insulating layer 250c and the insulating layer 250d are not necessarily formed by an anisotropic film formation method. Accordingly, a smaller angle may be included within the preferable range of the angle θ in the structure illustrated in FIG. 8B and FIG. 8C, for example. In the structure illustrated in FIG. 8B and FIG. 8C, the angle θ can be greater than or equal to 45° and less than or equal to 90°, for example.

When the angle θ has a small value, e.g., greater than or equal to 45° and less than or equal to 60°, the coverage with the oxide semiconductor layer 230, the insulating layer 250, or the like can be further improved.

FIG. 9A illustrates the thicknesses of four regions (thicknesses T1c, T2c, T4c, and T5c) in the insulating layer 250c and the thickness of one region (a thickness T5d) in the insulating layer 250d.

The thickness T1c is the thickness of the insulating layer 250c in a region provided to face the sidewall of the insulating layer 280 in the opening 290a. In the region, the insulating layer 250c faces the sidewall of the opening 290a with the oxide semiconductor layer 230 therebetween.

The thickness T2c is the thickness of the insulating layer 250c in a region sandwiched between the top surface of the conductive layer 240 and the conductive layer 260. In the region, the insulating layer 250c covers the top surface of the conductive layer 240 with the oxide semiconductor layer 230 therebetween.

The thickness T5c is the thickness of the insulating layer 250c in a region that covers the top surface of the conductive layer 240 with the insulating layer 250d therebetween and is not covered with the conductive layer 260.

The thickness T4c is the thickness of the insulating layer 250c in a region sandwiched between the top surface of the conductive layer 220 and the conductive layer 260. In the region, the insulating layer 250c covers the top surface of the conductive layer 220 with the oxide semiconductor layer 230 therebetween.

The thickness T5d is the thickness of the insulating layer 250d in a region that covers the top surface of the conductive layer 240.

The thickness T2c and the thickness T4c are each substantially the same as the thickness T1c, for example, and are each greater than or equal to 0.8 times and less than or equal to 1.2 times the thickness T1c, for example. The thickness T5c is smaller than the thickness T1c.

The thickness T1c is preferably greater than or equal to 0.2 nm and less than or equal to 30 nm, preferably greater than or equal to 0.2 nm and less than or equal to 20 nm, preferably greater than or equal to 0.2 nm and less than or equal to 10 nm, preferably greater than or equal to 0.2 nm and less than or equal to 8.0 nm, further preferably greater than or equal to 0.2 nm and less than or equal to 7.0 nm.

The sum of the thicknesses T1c and T5d is preferably greater than or equal to 1.0 nm and less than or equal to 50 nm, preferably greater than or equal to 2.0 nm and less than or equal to 50 nm, further preferably greater than or equal to 3.0 nm and less than or equal to 50 nm, preferably greater than or equal to 4.0 nm and less than or equal to 50 nm, preferably greater than or equal to 5.0 nm and less than or equal to 50 nm, for example.

The thicknesses T1c, T2c, T4c, T5c, and T5d each have a thickness distribution in the corresponding region in some cases. In such a case, the thickness of the thinnest region can be regarded as the thickness of the region, for example. Alternatively, the thickness of the thickest region can be regarded as the thickness of the region, for example. Alternatively, the average thickness of the region can be regarded as the thickness of the region, for example.

As illustrated in FIG. 9B, the end portion of the oxide semiconductor layer 230 may be placed outward from the end portion of the conductive layer 260. When the oxide semiconductor layer 230 is placed between the end portion of the conductive layer 260 and the top surface of the conductive layer 240, leakage current through the insulating layer 250 between the conductive layer 260 and the conductive layer 240 can be reduced in some cases. The pattern width of the conductive layer 260 (here, the width in the X direction) can be small without consideration of an arrangement margin between the pattern of the conductive layer 260 and the pattern of the oxide semiconductor layer 230; thus, the wiring width of the conductive layer 260 functioning as the gate electrode of the transistor can be narrowed, resulting in further miniaturization of the transistor, for example.

The transistor 200 includes a metal oxide (also referred to as an oxide semiconductor) functioning as a semiconductor in the oxide semiconductor layer 230 including a channel formation region. That is, the transistor 200 can be regarded as an OS transistor.

When oxygen vacancies (Vo) and impurities are present in a channel formation region of an oxide semiconductor in an OS transistor, the electrical characteristics easily vary and the reliability thereof might worsen. In some cases, hydrogen in the vicinity of an oxygen vacancy forms a defect that is an oxygen vacancy which hydrogen enters (hereinafter also referred to as VoH in some cases), which generates an electron serving as a carrier. Thus, when the channel formation region of the oxide semiconductor includes oxygen vacancies, the OS transistor is likely to have normally-on characteristics. Therefore, the oxygen vacancies and the impurities are preferably reduced as much as possible in the channel formation region of the oxide semiconductor. In other words, the oxide semiconductor preferably includes an i-type (intrinsic) or substantially i-type channel formation region with a reduced carrier concentration.

Meanwhile, preferably, a source region and a drain region of the OS transistor include more oxygen vacancies, include more VoH, or have a higher concentration of an impurity such as hydrogen, nitrogen, or a metal element than the channel formation region, and thus are low-resistance regions with increased carrier concentrations. In other words, the source region and the drain region of the OS transistor are preferably n-type regions having higher carrier concentrations and lower resistances than the channel formation region.

A region of the oxide semiconductor layer 230 that is in contact with the insulating layer 280 and the vicinity thereof function as the channel formation region of the transistor 200. One of a region of the oxide semiconductor layer 230 that is in contact with the conductive layer 220 and a region of the oxide semiconductor layer 230 that is in contact with the conductive layer 240 functions as a source region, and the other functions as a drain region. That is, the channel formation region is sandwiched between the source region and the drain region.

When the oxide semiconductor layer 230 and the conductive layer 220 are in contact with each other, a metal compound is formed or oxygen vacancies are formed, so that the resistance of the region of the oxide semiconductor layer 230 that is in contact with the conductive layer 220 is reduced. Accordingly, the contact resistance between the oxide semiconductor layer 230 and the conductive layer 220 can be reduced. Similarly, when the oxide semiconductor layer 230 and the conductive layer 240 are in contact with each other, the resistance of the region of the oxide semiconductor layer 230 that is in contact with the conductive layer 240 is reduced. Accordingly, the contact resistance between the oxide semiconductor layer 230 and the conductive layer 240 can be reduced.

As illustrated in FIG. 2B, the insulating layer 280 is in contact with all the perimeter of the oxide semiconductor layer 230. Thus, the channel formation region of the transistor 200 can be formed in all the perimeter of the oxide semiconductor layer 230 (the entire region in contact with the insulating layer 280) in the opening 290. Note that FIG. 2B can be regarded as a cross-sectional view along the XY plane including the channel formation region of the oxide semiconductor layer 230.

The channel length of the transistor 200 is a distance between the source region and the drain region. That is, it can be said that the channel length of the transistor 200 is determined by the thickness of the insulating layer 280 over the conductive layer 220. In FIG. 1C, a channel length L of the transistor 200 is indicated by a dashed double-headed arrow. In a cross-sectional view, the channel length L is a distance between an end portion of a region where the oxide semiconductor layer 230 is in contact with the conductive layer 220 and an end portion of a region where the oxide semiconductor layer 230 is in contact with the conductive layer 240. That is, the channel length L corresponds to the length of the side surface of the insulating layer 280 on the opening 290 side in a cross-sectional view.

Further miniaturization of a conventional transistor, e.g., a planar transistor, has been difficult since the channel length thereof is restricted by the light exposure limit of photolithography; however, in the present invention, the channel length can be determined by the thickness of the insulating layer 280. Thus, the transistor 200 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 0.1 nm, greater than or equal to 1 nm, or greater than or equal to 5 nm). Accordingly, the transistor 200 can have a higher on-state current and improved frequency characteristics.

Furthermore, as described above, the channel formation region, the source region, and the drain region can be formed in the opening 290. Thus, the area occupied by the transistor 200 can be reduced as compared with a lateral transistor, e.g., a planar transistor, in which a channel formation region, a source region, and a drain region are provided separately on the XY plane. Accordingly, high integration of the semiconductor device can be achieved. In the case where the semiconductor device of one embodiment of the present invention is used for a memory device, the memory capacity per unit area can be increased.

As illustrated in FIG. 2B, the oxide semiconductor layer 230, the insulating layer 250, and the conductive layer 260 are provided concentrically. Thus, a side surface of the conductive layer 260 provided at the center faces a side surface of the oxide semiconductor layer 230 with the insulating layer 250 therebetween. That is, in a plan view, the entire outer circumference of the oxide semiconductor layer 230 serves as the channel formation region. In that case, for example, the channel width of the transistor 200 is determined by the length of the perimeter of the oxide semiconductor layer 230. That is, it can be said that the channel width of the transistor 200 is determined by the width of the opening 290 (the diameter in the case where the opening 290 is circular in a plan view). In FIG. 1C and FIG. 2B, the width D of the opening 290 is indicated by a dashed double-dotted double-headed arrow. In FIG. 2B, a channel width W of the transistor 200 is indicated by a dashed-dotted double-headed arrow. By increasing the width D of the opening 290, the channel width per unit area can be increased and the on-state current can be increased.

In the case where the opening 290 is formed by a photolithography method, the width D of the opening 290 is limited by the light exposure limit of photolithography. In addition, the width D of the opening 290 is determined by the thicknesses of the oxide semiconductor layer 230, the insulating layer 250, and the conductive layer 260 provided in the opening 290. The width D of the opening 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening 290 is circular in a plan view, the width D of the opening 290 corresponds to the diameter of the opening 290, and the channel width W can be calculated by “D×π”.

The channel length L of the transistor 200 is preferably smaller than at least the channel width W of the transistor 200. The channel length L of the transistor 200 is preferably greater than or equal to 0.1 times and less than or equal to 0.99 times, further preferably greater than or equal to 0.5 times and less than or equal to 0.8 times the channel width W of the transistor 200. This structure enables the transistor to have excellent electrical characteristics and high reliability. In the case where the opening 290 is formed to be circular in a plan view, the oxide semiconductor layer 230, the insulating layer 250, and the conductive layer 260 are provided concentrically. This makes the distance between the conductive layer 260 and the oxide semiconductor layer 230 substantially uniform, so that a gate electric field can be substantially uniformly applied to the oxide semiconductor layer 230.

Although this embodiment describes an example in which the opening 290 is circular in a plan view, the present invention is not limited thereto. For example, the opening 290 in a plan view may have an almost circular shape such as an elliptical shape, a polygonal shape such as a quadrangular shape, or a polygonal shape such as a quadrangular shape with rounded corners.

### <Component Materials for Semiconductor Device>

Materials that can be used for the semiconductor device of this embodiment are described below. Note that each layer included in the semiconductor device of this embodiment may have a single-layer structure or a stacked-layer structure. FIG. 1B, FIG. 1C, and FIG. 2A illustrate an example in which the conductive layer 220, the oxide semiconductor layer 230, and the conductive layer 240 each have a single-layer structure. FIG. 2A illustrates an example in which the oxide semiconductor layer 230 has a single-layer structure; meanwhile, FIG. 5A illustrates an example in which the oxide semiconductor layer 230 has a stacked-layer structure of two layers and FIG. 5B illustrates an example in which the oxide semiconductor layer 230 has a stacked-layer structure of three layers.

### [Insulating Layer]

An inorganic insulating film is preferably used for each of the insulating layers included in the semiconductor device (e.g., the insulating layer 210, the insulating layer 222, the insulating layer 250, the insulating layer 280, the insulating layer 283, and the like). Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

When a transistor including a metal oxide is surrounded by an insulating layer having a function of inhibiting passage of impurities and oxygen, the transistor can have stable electrical characteristics. As the insulating layer having a function of inhibiting passage of impurities and oxygen, a single layer or stacked layers including an insulating layer including one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum can be used, for example. Specifically, as a material of the insulating layer having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

Specifically, it is preferable to use a barrier insulating layer against impurities such as water and hydrogen and oxygen.

In this specification and the like, a barrier insulating layer refers to an insulating layer having a barrier property. In addition, the barrier property refers to a property that does not easily allow diffusion of a target substance, a property that does not easily allow passage of a target substance, a property with low permeability to a target substance, a function of inhibiting diffusion of a target substance, or a function of inhibiting passage of a target substance. Hydrogen described as a target substance refers to, for example, at least one of a hydrogen atom, a hydrogen molecule, a substance bonded to hydrogen, such as a water molecule or OH, and the like. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), a copper atom, and the like. Oxygen described as a target substance refers to, for example, at least one of an oxygen atom, an oxygen molecule, and the like.

Examples of the insulating layer having a function of inhibiting passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples include an oxide containing aluminum and hafnium (hafnium aluminate). Other examples include metal nitrides such as aluminum nitride, silicon nitride oxide, and silicon nitride.

An insulating layer in contact with an oxide semiconductor layer, such as a gate insulating layer, or an insulating layer provided in the vicinity of the oxide semiconductor layer preferably includes a region containing oxygen (hereinafter, sometimes referred to as excess oxygen) that is released by heating. For example, when an insulating layer including a region containing excess oxygen is in contact with an oxide semiconductor layer or positioned in the vicinity of the oxide semiconductor layer, oxygen vacancies in the oxide semiconductor layer can be reduced. An insulating layer in which a region containing excess oxygen is easily formed can be silicon oxide, silicon oxynitride, porous silicon oxide, or the like.

As miniaturization and high integration of transistors progress, for example, a problem such as leakage current may arise because of a thinner gate insulating layer. When a material with a high relative permittivity (high-k) is used for the gate insulating layer, the voltage at the time of operation of the transistor can be lowered while the physical thickness is maintained. In addition, the equivalent oxide thickness (EOT) of the gate insulating layer can be reduced. When a material with a high dielectric constant is used for a dielectric layer of a capacitor, the element can have a larger capacitance value. By contrast, when a material with a low relative permittivity is used for the insulating layer functioning as an interlayer film, parasitic capacitance generated between wirings can be reduced. Thus, a material is preferably selected depending on the function of an insulating layer. Note that the material with a low relative permittivity is a material with high dielectric strength.

Examples of the material with a high relative permittivity include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with a low relative permittivity include resins such as polyester, polyolefin, polyamide (e.g., nylon and aramid), polyimide, polycarbonate, and an acrylic resin. Other examples of the inorganic insulating material with a low relative permittivity include silicon oxide to which fluorine is added, silicon oxide to which carbon is added, and silicon oxide to which carbon and nitrogen are added. Another example is porous silicon oxide. These silicon oxides may contain nitrogen.

An inorganic insulating material such as silicon oxide, silicon oxynitride, and silicon nitride oxide can be used for both a layer in which a material with a high dielectric constant is suitably used, such as a gate insulating layer, and a layer in which a material with a low dielectric constant is suitably used, such as an interlayer film, for example. These materials have relatively low dielectric constants as compared with a high-k material such as hafnium oxide, for example, and thus are each expressed as a material with a low dielectric constant in this specification and the like in some cases.

A material that can have ferroelectricity may be used for the insulating layer included in the semiconductor device. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the ratio of the number of hafnium atoms to the number of atoms of the element J1 can be set as appropriate; the ratio of the number of hafnium atoms to the number of atoms of the element J1 is, for example, 1:1 or the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The ratio of the number of zirconium atoms to the number of atoms of the element J2 can be set as appropriate; the ratio of the number of zirconium atoms to the number of atoms of the element J2 is, for example, 1:1 or the neighborhood thereof. As the material that can have ferroelectricity, piezoelectric ceramics having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more selected from aluminum, gallium, indium, and the like. The element M2 is one or more selected from boron, scandium, yttrium, lanthanum, cerium, neodymium, europium, titanium, zirconium, hafnium, vanadium, niobium, tantalum, chromium, and the like. The atomic ratio of the element M1 to the element M2 can be set as appropriate. A metal oxide containing the element M1 and nitrogen has ferroelectricity in some cases even though the element M2 is not contained. Examples of the material that can have ferroelectricity also include a material in which an element M3 is added to the above metal nitride. The element M3 is one or more selected from magnesium, calcium, strontium, zinc, cadmium, and the like. Here, the atomic ratio of the element M1 to the element M2 to the element M3 can be set as appropriate.

Examples of the material that can have ferroelectricity also include a perovskite-type oxynitride such as SrTaO₂N or BaTaO₂N, and GaFeO₃ with a K-alumina-type structure.

Although the metal oxides and the metal nitrides are given as examples of the material that can have ferroelectricity in the above description, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, an insulating layer 130 can have a stacked-layer structure of a plurality of materials selected from the above-listed materials. Note that the crystal structures (properties) of the above-listed materials and the like can be changed depending on the processes as well as the formation conditions; thus, a material that exhibits ferroelectricity is referred to not only as a ferroelectric but also as a material that can have ferroelectricity in this specification and the like.

A metal oxide containing one or both of hafnium and zirconium can have ferroelectricity even in a form of a thin film of several nanometers. A metal oxide containing one or both of hafnium and zirconium can have ferroelectricity even with a minute area. Accordingly, the use of a metal oxide containing one or both of hafnium and zirconium enables miniaturization of the semiconductor device.

In this specification and the like, the material that can have ferroelectricity processed into a layered shape is sometimes referred to as a ferroelectric layer. Furthermore, in this specification and the like, a device including such a ferroelectric layer, metal oxide film, or metal nitride film is sometimes referred to as a ferroelectric device in this specification and the like.

It is considered that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulating layer can exhibit ferroelectricity, the insulating layer 130 needs to include a crystal. It is particularly preferable that the insulating layer include a crystal having an orthorhombic crystal structure to exhibit ferroelectricity. Note that a crystal included in the insulating layer may have one or more selected from cubic, tetragonal, orthorhombic, monoclinic, and hexagonal crystal structures. The insulating layer may include an amorphous structure. In that case, the insulating layer may have a composite structure including an amorphous structure and a crystal structure.

The insulating layer 250 functions as the gate insulating layer of the transistor 200. For the insulating layer 250, a material with a high relative permittivity is preferably used.

The insulating layer 250 preferably has a function of capturing hydrogen and fixing hydrogen. In that case, the hydrogen concentration in the oxide semiconductor layer 230 (in particular, the hydrogen concentration in the channel formation region of the transistor) can be reduced. Accordingly, VoH in the channel formation region can be reduced, so that the channel formation region can be an i-type or substantially i-type region.

Examples of a material for the insulating layer having a function of capturing or fixing hydrogen include metal oxides such as an oxide containing hafnium, an oxide containing aluminum, an oxide containing aluminum and hafnium (hafnium aluminate), and an oxide containing magnesium. These metal oxides may further contain zirconium, and examples of such a metal oxide include an oxide containing hafnium and zirconium. In a metal oxide having an amorphous structure, some oxygen atoms have a dangling bond, which allows the metal oxide to have a high capability of capturing or fixing hydrogen. Thus, these metal oxides preferably have an amorphous structure. For example, these oxides may have an amorphous structure by containing silicon. For example, an oxide containing hafnium and silicon (hafnium silicate) is preferably used. Note that the metal oxide partly has one or both of a crystal region and a crystal grain boundary in some cases.

A function of capturing or fixing a target substance can also be referred to as a property that does not easily allow diffusion of a target substance. Thus, a function of capturing or fixing a target substance can be rephrased as a barrier property.

In the case where the insulating layer 250 has a stacked-layer structure, it is preferable to use a layer having a function of capturing hydrogen and fixing hydrogen as any of the layers (hereinafter referred to as a first insulating layer of the insulating layer 250). When a layer having a function of capturing hydrogen and fixing hydrogen is used as a layer in contact with the oxide semiconductor layer 230 in the case where the insulating layer 250 has a stacked-layer structure of two layers and as a layer close to the oxide semiconductor layer 230 in the case where the insulating layer 250 has a stacked-layer structure of three or more layers, hydrogen contained in the oxide semiconductor layer 230 can be more effectively captured or fixed. Thus, the hydrogen concentration in the oxide semiconductor layer 230 can be reduced.

The insulating layer 250 preferably includes a barrier insulating layer against hydrogen as a second insulating layer in addition to the first insulating layer. Examples of a material for the barrier insulating layer against hydrogen include aluminum oxide, magnesium oxide, hafnium oxide, gallium oxide, an indium gallium zinc oxide, silicon nitride, and silicon nitride oxide.

For the first insulating layer of the insulating layer 250, for example, hafnium silicate or the like is preferably used. The first insulating layer of the insulating layer 250 preferably has an amorphous structure. An amorphous structure can inhibit formation of a crystal grain boundary. Inhibiting the formation of a crystal grain boundary can increase the planarity of the insulating layer. This makes the thickness distribution of the insulating layer uniform and the number of extremely thin portions to be reduced, so that the breakdown voltage of the insulating layer can be improved. In addition, the thickness distribution of a film provided over the insulating layer can be uniform.

Moreover, inhibiting the formation of a crystal grain boundary in the insulating layer can reduce leakage current due to a defect state in the crystal grain boundary. Thus, the insulating layer can function as an insulating film with a low leakage current.

Since hafnium oxide is a high relative permittivity material, hafnium silicate is a high relative permittivity material depending on the silicon content. Accordingly, in the case of using the insulating layer 250a as the gate insulating layer, a gate potential applied during the operation of the transistor can be reduced while the physical thickness of the gate insulating layer is maintained. In addition, the equivalent oxide thickness (EOT) of the gate insulating layer can be reduced.

As described above, for the first insulating layer of the insulating layer 250, an oxide containing one or both of aluminum and hafnium is preferably used, an oxide that has an amorphous structure and contains one or both of aluminum and hafnium is further preferably used, and aluminum oxide having an amorphous structure is still further preferably used.

When a barrier insulating layer against hydrogen is used as the second insulating layer of the insulating layer 250, diffusion of impurities contained in the conductive layer 260 into the oxide semiconductor layer 230 can be inhibited. Silicon nitride is suitably used for the insulating layer 250b because of its high barrier property against hydrogen. Here, the second insulating layer is preferably a layer above the first insulating layer.

With such a structure, a semiconductor device having favorable electrical characteristics can be provided. A highly reliable semiconductor device can be provided. A semiconductor device with a small variation in electrical characteristics of a transistor can be provided. A semiconductor device with a high on-state current can be provided.

Furthermore, the insulating layer 250 may include an insulating layer with a thermally stable structure, such as silicon oxide or silicon oxynitride.

Furthermore, the insulating layer 250 preferably includes a layer that can supply oxygen to the oxide semiconductor layer 230. An oxide can be used for the layer that can supply oxygen. When the insulating layer 250 includes silicon oxide or silicon oxynitride, oxygen can be adequately supplied from the insulating layer 250 to the oxide semiconductor layer 230.

The insulating layer 250 may include, between a pair of insulating layers having a function of capturing hydrogen and fixing hydrogen, an insulating layer with a thermally stable structure.

The insulating layer 250 preferably includes a barrier insulating layer against oxygen. This can inhibit oxidation of the conductive layer 240, the conductive layer 260, and the like. In the case where the insulating layer 250 has a stacked-layer structure, a layer in contact with the conductive layer 240 and a layer in contact with the conductive layer 260 are each preferably a barrier insulating layer against oxygen.

The layer that is included in the insulating layer 250 and is in contact with the conductive layer 240 is preferably less likely to transmit oxygen than at least the insulating layer 280. When the layer has a barrier property against oxygen, oxidation of the side surface of the conductive layer 240 and formation of an oxide film on the side surface can be inhibited. Accordingly, a decrease in the on-state current or field-effect mobility of the transistor 200 can be inhibited.

The use of a barrier insulating layer against hydrogen and oxygen as the above-described second insulating layer can inhibit the oxidation of the conductive layer 260, for example. Moreover, diffusion of oxygen contained in the oxide semiconductor layer 230 into the conductive layer 260 and formation of oxygen vacancies in the oxide semiconductor layer 230 can be inhibited.

Examples of the barrier insulating layer against oxygen include an oxide containing hafnium, an oxide containing aluminum, an oxide containing aluminum and hafnium (hafnium aluminate), magnesium oxide, gallium oxide, a gallium zinc oxide, an indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate).

An oxide containing hafnium and silicon (hafnium silicate) is an excellent insulating layer that functions as a barrier insulating layer against oxygen and moreover easily has an amorphous structure and thereby has a function of capturing or fixing hydrogen as described above.

Silicon nitride is an excellent insulating layer that functions as a barrier insulating layer against oxygen and moreover has a high barrier property against hydrogen as described above.

A two-layer structure in which a first insulating layer having a function of capturing or fixing hydrogen and a second insulating layer having a barrier property against hydrogen and oxygen are stacked in this order from the oxide semiconductor layer 230 side is preferably used for the insulating layer 250.

For example, an oxide containing one or both of aluminum and hafnium can be used for the first insulating layer, and silicon nitride can be used for the second insulating layer.

Here, in the case where the insulating layer 250 has a two-layer structure, the first insulating layer can be used as the insulating layer 250a illustrated in FIG. 6A, FIG. 6B, and the like, and the second insulating layer can be used as the insulating layer 250b.

In the case where the thickness T1b of the insulating layer 250b is extremely small, the insulating layer 250a may have a stacked-layer structure of the first insulating layer and the second insulating layer.

The insulating layer 250c illustrated in FIG. 8B, FIG. 8C, and the like can have the above-described stacked-layer structure of two layers.

A three-layer structure in which a third insulating layer including a material with a relatively low relative permittivity, a first insulating layer having a function of capturing or fixing hydrogen, and a second insulating layer having a barrier property against hydrogen and oxygen are stacked in this order from the oxide semiconductor layer 230 side is preferably used for the insulating layer 250. The material with a relatively low relative permittivity contained in the third insulating layer refers to, for example, a material with a lower relative permittivity than any one or more of the other layers in the stacked-layer structure. Here, for the third insulating layer, silicon oxide or silicon oxynitride can be suitably used. The third insulating layer is a layer in contact with the oxide semiconductor layer 230. When an oxide is used for the third insulating layer, oxygen can be supplied to the oxide semiconductor layer 230. Providing the second insulating layer can inhibit diffusion of oxygen included in the third insulating layer into the conductive layer 260 and inhibit oxidation of the conductive layer 260. Furthermore, a reduction in the amount of oxygen supplied from the third insulating layer to the oxide semiconductor layer 230 can be inhibited.

For example, silicon oxide or silicon oxynitride can be used for the third insulating layer, an oxide containing one or both of aluminum and hafnium can be used for the first insulating layer, and silicon nitride can be used for the second insulating layer.

Here, in the case where the insulating layer 250 has the above-described three-layer structure, the insulating layer 250a illustrated in FIG. 6A, FIG. 6B, and the like can have a two-layer stacked structure of the third insulating layer and the first insulating layer, and the second insulating layer can be used as the insulating layer 250b. Alternatively, the third insulating layer can be used as the insulating layer 250a, and the insulating layer 250b can have a two-layer stacked structure of the first insulating layer and the second insulating layer.

In the case where the thickness T1b of the insulating layer 250b is extremely small, the insulating layer 250a may have a stacked-layer structure of the third insulating layer, the first insulating layer, and the second insulating layer.

The insulating layer 250c illustrated in FIG. 8B, FIG. 8C, and the like can have the above-described stacked-layer structure of three layers.

A four-layer structure in which a fourth insulating layer having a barrier property against oxygen, the third insulating layer including a material with a relatively low relative permittivity, the first insulating layer having a function of capturing or fixing hydrogen, and the second insulating layer having a barrier property against hydrogen and oxygen are stacked in this order from the oxide semiconductor layer 230 side is preferably used for the insulating layer 250. For the first insulating layer to third insulating layer, structures similar to those of the layers used in the above-described three-layer structure can be used. The fourth insulating layer is a layer in contact with the oxide semiconductor layer 230. Since the fourth insulating layer has a barrier property against oxygen, release of oxygen from the oxide semiconductor layer 230 can be inhibited. For the fourth insulating layer, aluminum oxide is preferably used, for example. Aluminum oxide has a function of capturing or fixing hydrogen, and thus is suitably used for the fourth insulating layer in contact with the oxide semiconductor layer 230.

For example, aluminum oxide can be used for the fourth insulating layer, silicon oxide or silicon oxynitride can be used for the third insulating layer, an oxide containing one or both of aluminum and hafnium can be used for the first insulating layer, and silicon nitride can be used for the second insulating layer.

Here, in the case where the insulating layer 250 has the above-described four-layer structure, the insulating layer 250a illustrated in FIG. 6A, FIG. 6B, and the like can have a three-layer stacked structure of the fourth insulating layer, the third insulating layer, and the first insulating layer, and the second insulating layer can be used as the insulating layer 250b. Alternatively, the insulating layer 250a can have a two-layer stacked structure of the fourth insulating layer and the third insulating layer, and the insulating layer 250b can have a two-layer stacked structure of the first insulating layer and the second insulating layer. Alternatively, the fourth insulating layer can be used as the insulating layer 250a, and the insulating layer 250b can have a three-layer stacked structure of the third insulating layer, the first insulating layer, and the second insulating layer.

In the case where the thickness T1b of the insulating layer 250b is extremely small, the insulating layer 250a may have a four-layer stacked structure of the fourth insulating layer, the third insulating layer, the first insulating layer, and the second insulating layer.

The insulating layer 250c illustrated in FIG. 8B, FIG. 8C, and the like can have the above-described stacked-layer structure of four layers.

For the insulating layer 250d, one or more selected from the above-described materials that can be used for the insulating layer 250 can be used. The insulating layer 250d is preferably formed by a method that allows selective growth over a metal.

The thickness of the insulating layer 250 in a region overlapping with the channel formation region of the oxide semiconductor layer 230 in particular is preferably greater than or equal to 0.1 nm and less than or equal to 30 nm, preferably greater than or equal to 0.1 nm and less than or equal to 20 nm, preferably greater than or equal to 0.1 nm and less than or equal to 10 nm, further preferably greater than or equal to 0.1 nm and less than or equal to 8.0 nm, still further preferably greater than or equal to 0.5 nm and less than or equal to 7.0 nm.

The thickness of each of the layers constituting the insulating layer 250 is preferably small for miniaturization of the transistor. The thickness of each of the layers constituting the insulating layer 250 is, for example, greater than or equal to 0.1 nm and less than or equal to 10 nm, greater than or equal to 0.1 nm and less than or equal to 5 nm, greater than or equal to 0.5 nm and less than or equal to 5 nm, greater than or equal to 1 nm and less than 5 nm, or greater than or equal to 1 nm and less than or equal to 3 nm. Note that each of the layers constituting the insulating layer 250 at least partly includes a region with the above thickness.

The thicknesses of the fourth insulating layer, the third insulating layer, the first insulating layer, and the second insulating layer are, typically, 1 nm, 2 nm, 2 nm, and 1 nm, respectively. Such a structure enables the transistor to have favorable electrical characteristics even when the transistor is miniaturized or highly integrated.

The insulating layer 210 functions as an interlayer film and thus preferably has a low relative permittivity. When a material with a low relative permittivity is used for an interlayer film, parasitic capacitance generated between wirings can be reduced. Silicon oxide and silicon oxynitride are thermally stable, and thus are suitable for the insulating layer 210.

The concentration of impurities such as water and hydrogen in the insulating layer 210 is preferably reduced. This can inhibit entry of impurities such as water and hydrogen into the channel formation region of the oxide semiconductor layer 230.

As the insulating layer 210, a barrier insulating layer against hydrogen is preferably used. When the insulating layer 210 provided outside the oxide semiconductor layer 230 has a barrier property against hydrogen, diffusion of hydrogen into the oxide semiconductor layer 230 can be inhibited.

Examples of a material for the barrier insulating layer against hydrogen include aluminum oxide, magnesium oxide, hafnium oxide, gallium oxide, an indium gallium zinc oxide, silicon nitride, and silicon nitride oxide.

For example, a silicon nitride film is preferably used for the insulating layer 210.

An insulating layer having a function of capturing or fixing hydrogen is preferably used as the insulating layer 222. In that case, hydrogen in the oxide semiconductor layer 230 can be diffused into the insulating layer 222 through the conductive layer 220, and the hydrogen can be captured or fixed. Thus, the hydrogen concentration in the oxide semiconductor layer 230 can be reduced.

For example, a silicon nitride film is preferably used for the insulating layer 210 and an oxide film including hafnium and silicon (hafnium silicate film) is preferably used for the insulating layer 222.

As the insulating layer 283, a barrier insulating layer against hydrogen is preferably used. In that case, diffusion of hydrogen from above the insulating layer 283 into the oxide semiconductor layer 230 can be inhibited. A silicon nitride film and a silicon nitride oxide film can be suitably used for the insulating layer 283 because they release fewer impurities (e.g., water and hydrogen) and are less likely to transmit oxygen and hydrogen.

A film of silicon nitride formed by a sputtering method is particularly preferably used for the insulating layer 283. Since a sputtering method does not need to use a molecule containing hydrogen in a film formation gas, the hydrogen concentration in the insulating layer 283 can be reduced. When the insulating layer 283 is formed by a sputtering method, high-density silicon nitride can be formed.

As the insulating layer 283, an insulating layer having a function of capturing or fixing hydrogen may be used. With such a structure, diffusion of hydrogen from above the insulating layer 283 into the oxide semiconductor layer 230 can be inhibited, and hydrogen contained in the oxide semiconductor layer 230 can be captured or fixed. Thus, the hydrogen concentration in the oxide semiconductor layer 230 can be reduced. For the insulating layer 283, hafnium silicate or the like can be used.

The insulating layer 283 may have a stacked-layer structure of an insulating layer having a function of capturing or fixing hydrogen and a barrier insulating layer against hydrogen. For example, a stacked-layer film of aluminum oxide and silicon nitride over the aluminum oxide may be used for the insulating layer 283.

The insulating layer 280 preferably includes the above-described barrier insulating layer against hydrogen. The insulating layer 280 is provided to surround the oxide semiconductor layer 230. When the insulating layer 280 provided outside the oxide semiconductor layer 230 has a barrier property against hydrogen, diffusion of hydrogen into the oxide semiconductor layer 230 can be inhibited. For example, the insulating layer 280 preferably includes a silicon nitride film. Silicon nitride also has a barrier property against oxygen. Thus, using silicon nitride for the insulating layer 280 can inhibit extraction of oxygen from the oxide semiconductor layer 230 and accordingly can inhibit formation of an excess amount of oxygen vacancies in the oxide semiconductor layer 230.

Furthermore, using silicon nitride for the insulating layer 280 can prevent excess oxygen from being supplied to the oxide semiconductor layer 230. Thus, the channel formation region of the oxide semiconductor layer 230 can be prevented from containing excess oxygen, whereby the reliability of the transistor 200 can be improved.

The insulating layer 280 preferably includes any of an oxide insulating film, an oxynitride insulating film, and an insulating layer including a region containing excess oxygen, which are described above.

For example, the insulating layer including a region containing excess oxygen can be formed by a sputtering method in an oxygen-containing atmosphere. With the use of a sputtering method, which does not need to use a molecule containing hydrogen in a film formation gas, the hydrogen concentration in the insulating layer 280 can be reduced. When at least one layer included in the insulating layer 280 is formed in this manner, oxygen can be supplied from the insulating layer 280 to the channel formation region of the oxide semiconductor layer 230, so that oxygen vacancies and VoH can be reduced.

The concentration of impurities such as water and hydrogen in the insulating layer 280 is preferably reduced. This can inhibit entry of impurities such as water and hydrogen into the channel formation region of the oxide semiconductor layer 230.

Since the thickness of the insulating layer 280 over the conductive layer 220 corresponds to the channel length of the transistor 200, the thickness of the insulating layer 280 is set as appropriate depending on the design value of the channel length of the transistor 200.

The insulating layer 280 may have a stacked-layer structure, for example. The insulating layer 280 illustrated in FIG. 6A and FIG. 6B includes the insulating layer 280a, the insulating layer 280b over the insulating layer 280a, and the insulating layer 280c over the insulating layer 280b.

The insulating layer 280b is a layer in contact with the channel formation region of the oxide semiconductor layer 230. When an insulating layer including oxygen is used as the insulating layer 280b, oxygen can be supplied to the oxide semiconductor layer 230.

It is preferable that the insulating layer 280b include a region having a higher oxygen content than at least one of the insulating layer 280a and the insulating layer 280c. It is particularly preferable that the insulating layer 280b include a region having a higher oxygen content than each of the insulating layer 280a and the insulating layer 280c. When the insulating layer 280b has a high oxygen content, an i-type region can be easily formed in the oxide semiconductor layer 230 in the vicinity of the insulating layer 280b.

It is further preferable that a film from which oxygen is released by heating be used for the insulating layer 280b. When the insulating layer 280b releases oxygen by being heated during the manufacturing process of the transistor 200, the oxygen can be supplied to the oxide semiconductor layer 230. Supply of oxygen from the insulating layer 280b to the oxide semiconductor layer 230, particularly to the channel formation region in the semiconductor layer 230, can reduce oxygen vacancies and VoH in the oxide semiconductor layer 230, so that the transistor can have excellent electrical characteristics and high reliability.

In order to improve the electrical characteristics and reliability of an OS transistor, it is important to sufficiently reduce the hydrogen concentration in an oxide semiconductor and optimize the amount of oxygen supplied to the oxide semiconductor.

For example, the amount of oxygen molecules released from the insulating layer 280b is preferably greater than or equal to 1.0×10¹⁴ molecules/cm² and less than 1.0×10¹⁵ molecules/cm². Note that the amount of released oxygen molecules can be measured by thermal desorption spectrometry.

Particularly in the case where the channel length of the transistor 200 is small, oxygen vacancies and VoH in the channel formation region significantly affect the electrical characteristics and reliability. Accordingly, when the hydrogen concentration in the oxide semiconductor layer 230 is sufficiently reduced and the amount of oxygen supplied to the oxide semiconductor layer 230 is optimized, a transistor with a small channel length, excellent electrical characteristics, and high reliability can be provided.

The insulating layer 280b is preferably formed by a film formation method such as a sputtering method or a PECVD method. When a sputtering method is used, in particular, a hydrogen gas does not need to be used as a film formation gas, so that a film with an extremely low hydrogen content can be formed. Thus, supply of hydrogen to the oxide semiconductor layer 230 can be inhibited and the electrical characteristics of the transistor 200 can be stabilized.

In the case where the amount of oxygen supplied to the oxide semiconductor layer 230 is increased, heat treatment in an oxygen-containing atmosphere or plasma treatment in an oxygen-containing atmosphere is preferably performed after formation of the insulating layer 280b, for example. Alternatively, an oxide film may be formed over the top surface of the insulating layer 280b by a sputtering method in an oxygen atmosphere to supply oxygen. After that, the oxide film may be removed. Such treatment can supply oxygen to the insulating layer 280b and increase the amount of oxygen supplied to the oxide semiconductor layer 230.

In the oxide semiconductor layer 230, a region in contact with the insulating layer 280a and a region in contact with the insulating layer 280c are supplied with a smaller amount of oxygen than a region in contact with the insulating layer 280b. Thus, in the oxide semiconductor layer 230, the region in contact with the insulating layer 280a and the region in contact with the insulating layer 280c each have a low resistance in some cases. That is, by adjusting the thickness of the insulating layer 280a, the range of a region functioning as one of a source region and a drain region can be controlled. Similarly, by adjusting the thickness of the insulating layer 280c, the range of a region functioning as the other of the source region and the drain region can be controlled. In this manner, the thicknesses of the insulating layer 280a and the insulating layer 280c can be set as appropriate in accordance with the characteristics required for the transistor.

A material with a low relative permittivity is preferably used for the insulating layer 280b. In that case, parasitic capacitance generated between wirings can be reduced. For the insulating layer 280b, for example, silicon oxide or silicon oxynitride can be suitably used.

As each of the insulating layer 280a and the insulating layer 280c, a barrier insulating layer against oxygen is preferably used. The insulating layer 280a provided between the insulating layer 280b and the conductive layer 220 can inhibit oxidation of the conductive layer 220 and an increase in the resistance of the conductive layer 220. The insulating layer 280c provided between the insulating layer 280b and the conductive layer 240 can inhibit oxidation of the conductive layer 240 and an increase in the resistance of the conductive layer 240.

As the insulating layer 280a, an insulating layer having a function of capturing or fixing hydrogen may be used. With such a structure, diffusion of hydrogen from below the insulating layer 280a into the oxide semiconductor layer 230 can be inhibited, and hydrogen included in the oxide semiconductor layer 230 can be captured or fixed. Thus, the hydrogen concentration in the oxide semiconductor layer 230 can be reduced. For the insulating layer 280a, magnesium oxide, aluminum oxide, hafnium oxide, an oxide containing hafnium and silicon, or the like can be used. Alternatively, for example, a stacked-layer film of aluminum oxide and silicon nitride over the aluminum oxide may be used for the insulating layer 280a. Similarly, an insulating layer having a function of capturing or fixing hydrogen may be used as the insulating layer 280c.

For example, silicon nitride can be used for the insulating layer 280a and the insulating layer 280c, and silicon oxide can be used for the insulating layer 280b.

### [Conductive Layer]

For each of the conductive layers (the conductive layer 220, the conductive layer 240, the conductive layer 260, and the like) included in the semiconductor device, it is preferable to use a metal element selected from tungsten, copper, aluminum, chromium, silver, gold, platinum, zinc, tantalum, nickel, titanium, iron, cobalt, molybdenum, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride; titanium nitride; ruthenium nitride; a nitride containing molybdenum; a nitride containing tungsten, titanium, and aluminum; a nitride containing tantalum and aluminum; ruthenium oxide; an oxide containing strontium and ruthenium; an oxide containing lanthanum and nickel; or the like. A semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include an indium oxide containing tungsten oxide, an indium oxide containing titanium oxide, an indium tin oxide (also referred to as an ITO), an indium tin oxide containing titanium oxide, an indium tin oxide to which silicon is added (also referred to as an ITSO), an indium zinc oxide (also referred to as an IZO (registered trademark)), and an indium zinc oxide containing tungsten oxide. In this specification and the like, a conductive film formed using a conductive material containing oxygen may be referred to as an oxide conductive film.

A conductive material containing tungsten, copper, or aluminum as its main component is preferable because it has high conductivity.

A stack of a plurality of conductive layers formed of the above-described materials may be used. For example, a stacked-layer structure combining a material containing the above metal element and a conductive material containing oxygen may be employed. A stacked-layer structure combining a material containing the above metal element and a conductive material containing nitrogen may be employed. A stacked-layer structure combining a material containing the above metal element, a conductive material containing oxygen, and a conductive material containing nitrogen may be employed.

In the case where a metal oxide is used for the channel formation region of the transistor, a conductive layer functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

For the conductive layer 260, any of the above metal elements, an alloy containing any of the above metal elements as a component, an alloy containing a combination of the above metal elements, or the like can be used. For example, a material having high conductivity, such as tungsten, is preferably used. For the conductive layer 260, a conductive material that is not easily oxidized, a conductive material having a function of inhibiting diffusion of oxygen, or the like is preferably used. As described above, examples of the conductive material include a conductive material containing nitrogen and a conductive material containing oxygen. Thus, a decrease in conductivity of the conductive layer 260 can be inhibited.

It is preferable to use, for the conductive layer 260, a conductive material containing oxygen and a metal element contained in a metal oxide where the channel is formed. One or more of an indium tin oxide, an indium oxide containing tungsten oxide, an indium zinc oxide containing tungsten oxide, an indium oxide containing titanium oxide, an indium tin oxide containing titanium oxide, an indium zinc oxide, and an indium tin oxide to which silicon is added may be used. An indium gallium zinc oxide containing nitrogen may be used. With the use of such a material, hydrogen contained in the metal oxide where the channel is formed can be captured in some cases. Alternatively, hydrogen entering from an external insulating layer or the like can be captured in some cases.

The conductive layer 260 is greater than or equal to 3 nm and less than or equal to 500 nm, for example. The thickness of the conductive layer 260 is, for example, larger than or equal to the thickness of the insulating layer 250. When the conductive layer 260 has a large thickness, the resistance of the conductive layer 260 can be reduced.

The conductive layer 260 can have a two-layer structure of the conductive layer 260a and the conductive layer 260b over the conductive layer 260a.

When a conductive material having a function of inhibiting diffusion of oxygen is used for the conductive layer 260a, release of oxygen from the oxide semiconductor layer 230 can be inhibited and formation of oxygen vacancies in the oxide semiconductor layer 230 can be inhibited, for example.

Furthermore, the use of a conductive material that is not easily oxidized for the conductive layer 260a can inhibit the conductive layer 260a from being oxidized and having reduced conductivity owing to release of oxygen from the oxide semiconductor layer 230 or release of oxygen from the insulating layer 250, for example.

The material used for the conductive layer 260b preferably has higher conductivity than the material used for the conductive layer 260a, for example. When the conductive layer 260b has a large thickness, the amount of current flowing through the conductive layer 260b can be further increased.

When a film formation method achieving excellent coverage is used for the conductive layer 260a, the conductive layer 260a can be favorably formed along the sidewall of the opening 290.

For the conductive layer 260a, a conductive material containing nitrogen, a conductive material containing oxygen, or the like can be used, for example. For the conductive layer 260a, a conductive material containing oxygen and a metal element contained in a metal oxide where the channel is formed can be used, for example.

For the conductive layer 260a, for example, a conductive material containing the above metal element and nitrogen can be used; tantalum nitride, titanium nitride, ruthenium nitride, a nitride containing molybdenum, a nitride containing tungsten, titanium, and aluminum, a nitride containing tantalum and aluminum, or the like can be used, for example.

For the conductive layer 260a, for example, a conductive material containing the above metal element and oxygen can be used; ruthenium oxide, an oxide containing strontium and ruthenium, an oxide containing lanthanum and nickel, or the like can be used, for example.

One or more of an indium tin oxide, an indium oxide containing tungsten oxide, an indium zinc oxide containing tungsten oxide, an indium oxide containing titanium oxide, an indium tin oxide containing titanium oxide, an indium zinc oxide, and an indium tin oxide to which silicon is added may be used. An indium gallium zinc oxide containing nitrogen may be used.

For the conductive layer 260a, titanium, tantalum, ruthenium, or a material containing one or more selected from the metal elements is preferable because of being a conductive material that is not easily oxidized, a conductive material having a function of inhibiting diffusion of oxygen, or a material that maintains the conductivity even after absorbing oxygen.

For the conductive layer 260b, any of the above metal elements, an alloy containing any of the above metal elements as a component, an alloy containing a combination of the above metal elements, or the like can be used, for example. For example, tungsten can be used.

Furthermore, the conductive layer 260a may have a stacked-layer structure. Moreover, the conductive layer 260b may have a stacked-layer structure. In the case where the conductive layer 260a has a stacked-layer structure, a plurality of materials that can be used for the conductive layer 260a are stacked, for example. Alternatively, a plurality of materials selected from materials that can be used for the conductive layer of one embodiment of the present invention may be stacked. In the case where the conductive layer 260b has a stacked-layer structure, a plurality of materials that can be used for the conductive layer 260b are stacked, for example. Alternatively, a plurality of materials selected from materials that can be used for the conductive layer of one embodiment of the present invention may be stacked.

Each of the conductive layer 220 and the conductive layer 240 is a conductive layer in contact with the oxide semiconductor layer 230, and thus is preferably formed using a conductive material that is not easily oxidized, a conductive material that maintains its low electrical resistance even after oxidized, an oxide conductive material, or a conductive material having a function of inhibiting diffusion of oxygen. Examples of the conductive material include a conductive material containing nitrogen and a conductive material containing oxygen. Accordingly, a decrease in conductivity of the conductive layer 220 and the conductive layer 240 can be inhibited.

When a conductive material containing oxygen is used for the conductive layer 220 or the conductive layer 240, the conductive layer 220 or the conductive layer 240 can maintain its conductivity even after absorbing oxygen. This is suitable because the conductive layer 220 can maintain its conductivity also in the case where an insulating layer containing oxygen, e.g., hafnium oxide, is used for the insulating layer 210. For each of the conductive layer 220 and the conductive layer 240, an ITO, an ITSO, an IZO (registered trademark), or the like is preferably used, for example.

In the case where the conductive layer 220 has a three-layer structure of a first conductive layer, a second conductive layer, and a third conductive layer stacked in this order over the insulating layer 210, for example, a conductive material that is not easily oxidized or a conductive material having a function of inhibiting diffusion of oxygen is preferably used for the first conductive layer, a material having high conductivity is preferably used for the second conductive layer, and a conductive material containing oxygen is preferably used for the third conductive layer. Specifically, for example, titanium nitride is preferably used for the first conductive layer, tungsten is preferably used for the second conductive layer, and an ITO or an ITSO is preferably used for the third conductive layer. In that case, titanium nitride is in contact with the insulating layer 210, and an ITO or an ITSO is in contact with the oxide semiconductor layer 230. Such a structure enables the conductive layer 220 to maintain its conductivity even when being in contact with the oxide semiconductor layer 230. In the case of using an oxide insulating layer as the insulating layer 210, excessive oxidation of the conductive layer 220 due to the insulating layer 210 can be inhibited. When tungsten with high conductivity is used for the second conductive layer, the conductivity of the conductive layer 220 can be increased.

Although FIG. 1B and FIG. 1C illustrate a structure in which the top surface of the conductive layer 220 is flat, the present invention is not limited thereto. For example, a depressed portion overlapping with the opening 290 may be formed on the top surface of the conductive layer 220. When at least part of the oxide semiconductor layer 230, the insulating layer 250, and the conductive layer 260 are formed to fill the depressed portion, the gate electric field of the conductive layer 260 can be easily applied to a portion of the oxide semiconductor layer 230 close to the conductive layer 220.

In the case where the conductive layer 240 has a stacked-layer structure of two layers, for example, a material having higher conductivity than the upper layer is preferably used for the lower layer and a conductive material containing oxygen is preferably used for the upper layer. Specifically, for example, ruthenium, tungsten, titanium nitride, or tantalum nitride is preferably used for the lower layer, and an ITO or an ITSO is preferably used for the upper layer. In that case, an ITO or an ITSO is in contact with the oxide semiconductor layer 230. Such a structure enables the conductive layer 240 to maintain its conductivity even when being in contact with the oxide semiconductor layer 230. When a material having higher conductivity than the upper layer is used for the lower layer, the conductivity of the conductive layer 240 can be increased.

### [Oxide Semiconductor Layer 230]

As described above, the oxide semiconductor layer 230 includes a channel formation region. The channel formation region is an i-type (intrinsic) or substantially i-type region. The oxide semiconductor layer 230 further includes a source region and a drain region. The source region and the drain region are each an n-type region (low-resistance region) having a higher carrier concentration than the channel formation region.

There is no particular limitation on the crystallinity of a semiconductor material used for the oxide semiconductor layer 230, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used because degradation of the transistor characteristics can be inhibited.

A metal oxide functioning as a semiconductor preferably has a band gap larger than or equal to 2.0 eV, further preferably larger than or equal to 2.5 eV. With the use of a metal oxide having a large band gap, the off-state current of the transistor can be reduced. The off-state current of the OS transistor is low, so that power consumption of the semiconductor device can be adequately reduced. The OS transistor has excellent frequency characteristics, which enables the semiconductor device to operate at high speed.

Examples of the metal oxide that can be used for the oxide semiconductor layer 230 include an indium oxide, a gallium oxide, and a zinc oxide. The metal oxide preferably contains at least indium (In) or zinc (Zn). The metal oxide preferably contains two or three kinds selected from indium, an element M, and zinc. The element Mis a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably any one or more of the above elements, further preferably one or more selected from aluminum, gallium, tin, and yttrium, still further preferably gallium. In this specification and the like, a metal element and a metalloid element may be collectively referred to as a “metal element”, and a “metal element” in this specification and the like may refer to a metalloid element.

The oxide semiconductor layer 230 can be formed using, for example, an indium oxide (an In oxide) an indium zinc oxide (an In—Zn oxide, also referred to as an IZO (registered trademark)), an indium tin oxide (an In—Sn oxide), an indium titanium oxide (an In—Ti oxide), an indium gallium oxide (an In—Ga oxide), an indium gallium aluminum oxide (an In—Ga—Al oxide), an indium gallium tin oxide (an In—Ga—Sn oxide, also referred to as an IGTO), a gallium zinc oxide (a Ga—Zn oxide, also referred to as a GZO), an aluminum zinc oxide (an Al—Zn oxide, also referred to as an AZO), an indium aluminum zinc oxide (an In—Al—Zn oxide, also referred to as an IAZO), an indium tin zinc oxide (an In—Sn—Zn oxide, also referred to as an ITZO (registered trademark)), an indium titanium zinc oxide (an In—Ti—Zn oxide), an indium gallium zinc oxide (an In—Ga—Zn oxide, also referred to as an IGZO), an indium gallium tin zinc oxide (an In—Ga—Sn—Zn oxide, also referred to as an IGZTO), or an indium gallium aluminum zinc oxide (an In—Ga—Al—Zn oxide, also referred to as an IGAZO, an IGZAO, or an IAGZO). Alternatively, it is possible to use an indium tin oxide containing silicon, a gallium tin oxide (a Ga—Sn oxide), an aluminum tin oxide (an Al—Sn oxide), or the like. Alternatively, the above-described oxide having an amorphous structure can be used. For example, an indium oxide having an amorphous structure, an indium tin oxide having an amorphous structure, or the like can be used.

By increasing the proportion of the number of indium atoms in the total number of atoms of all the metal elements contained in the metal oxide, the field-effect mobility of the transistor can be increased. In addition, the transistor can have a high on-state current.

The metal oxide may contain, instead of indium or in addition to indium, one or more kinds of metal elements with large period numbers. The larger the overlap between orbits of metal elements is, the more likely it is that the metal oxide will have high carrier conductivity. Thus, when the transistor includes a metal element with a large period number, the field-effect mobility can be increased in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. By containing a nonmetallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements included in the metal oxide, the metal oxide has high crystallinity, so that diffusion of impurities in the metal oxide can be inhibited. Consequently, a change in electrical characteristics of the transistor can be inhibited, and the reliability can be increased.

By increasing the proportion of the number of element M atoms in the total number of atoms of all the metal elements included in the metal oxide, the metal oxide can have a large band gap. In addition, formation of oxygen vacancies in the metal oxide can be inhibited. Accordingly, generation of carriers due to oxygen vacancies is inhibited, which makes the off-state current of the transistor low. In addition, a shift in the threshold voltage of the transistor can be inhibited. Furthermore, a change in electrical characteristics of the transistor is inhibited, and the reliability can be increased.

The electrical characteristics and reliability of the transistor depend on the composition of the metal oxide used for the oxide semiconductor layer 230. Thus, by varying the composition of the metal oxide in accordance with the electrical characteristics and reliability required for the transistor, the semiconductor device can have both excellent electrical characteristics and high reliability.

When the metal oxide is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:0.5, In:M:Zn=1:1:1, In:M:Zn=1:1:1.2, In:M:Zn=1:1:2, In:M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=5:2:5, and a composition in the neighborhood of any of these atomic ratios. Note that a composition in the neighborhood includes the range of +30% of an intended atomic ratio. By increasing the atomic ratio of indium in the metal oxide, the on-state current, field-effect mobility, or the like of the transistor can be increased.

The atomic ratio of In may be less than the atomic ratio of M in the In-M-Zn oxide. Examples of the atomic ratio of the metal elements in such an In-M-Zn oxide include In:M:Zn=1:3:2, In:M:Zn=1:3:3, In:M:Zn=1:3:4, and a composition in the neighborhood of any of these atomic ratios. By increasing the proportion of the number of M atoms in the metal oxide, generation of oxygen vacancies can be inhibited.

In the case where a plurality of metal elements are contained as the element M, the sum of the proportions of the numbers of atoms of the metal elements can be the proportion of the number of the element M atoms.

In this specification and the like, the proportion of the number of indium atoms in the total number of atoms of all the metal elements contained is sometimes referred to as the content percentage of indium. The same applies to other metal elements.

In the case where the metal oxide is an In—Zn oxide, examples of the atomic ratio of the metal elements in the In—Zn oxide include In:Zn=1:1, In:Zn=2:1, In:Zn=4:1, and a composition in the neighborhood of any of these atomic ratios. In addition, the In—Zn oxide may contain a slight amount of the element M. In the case where Sn is contained as the element M, for example, examples of the atomic ratio of metal elements in the metal oxide include In:Sn:Zn=2:0.1:1, In:Sn:Zn=4:0.1:1, and a composition in the neighborhood of any of these atomic ratios.

For analysis of the composition of a metal oxide used for the oxide semiconductor layer 230, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, these methods may be combined for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an ALD method can be suitably used for forming the metal oxide. In the case where the metal oxide is formed by a sputtering method, the composition of the formed oxide film may be different from the composition of a target. In particular, the content percentage of zinc in the formed metal oxide film may be reduced to approximately 50% of that of the target. The metal oxide film may be formed by a chemical vapor deposition (CVD) method, a molecular beam epitaxy (MBE) method, a pulsed laser deposition (PLD) method, or the like.

The oxide semiconductor layer 230 may have a stacked-layer structure including two or more metal oxide layers. The two or more metal oxide layers included in the oxide semiconductor layer 230 may have the same composition or substantially the same compositions. Employing a stacked-layer structure of metal oxide layers having the same composition can reduce the manufacturing cost because the metal oxide layers can be formed using the same sputtering target, for example.

The two or more metal oxide layers included in the oxide semiconductor layer 230 may have different compositions.

The oxide semiconductor layer 230 can have a two-layer structure, for example. FIG. 5A illustrates an example in which the oxide semiconductor layer 230 has a two-layer structure of the oxide layer 230a and the oxide layer 230b over the oxide layer 230a in the structure illustrated in FIG. 2A.

For the oxide layer 230a, for example, a material having higher conductivity than the oxide layer 230b is preferably used. The use of the material having high conductivity for the oxide layer 230a in contact with the source electrode and the drain electrode (the conductive layer 220 and the conductive layer 240) can reduce the contact resistance between the oxide semiconductor layer 230 and the conductive layer 220 and the contact resistance between the oxide semiconductor layer 230 and the conductive layer 240, and thus the transistor can have a high on-state current.

Here, in the case where a material having high conductivity is used for the oxide layer 230b provided on the side of the conductive layer 260 functioning as the gate electrode, the threshold voltage of the transistor 200 shifts and drain current flowing when the gate voltage is 0 V (hereinafter also referred to as cutoff current) becomes large in some cases. Specifically, the threshold voltage may be low when the transistor 200 is an n-channel transistor. Thus, a material having lower conductivity than the oxide layer 230a is preferably used for the oxide layer 230b. Accordingly, the transistor 200 can have a high threshold voltage in the case where the transistor is an n-channel transistor, in which case the transistor 200 can have a low cutoff current. Note that characteristics with a low cutoff current are sometimes referred to as normally-off characteristics.

When the oxide semiconductor layer 230 has a stacked-layer structure and a material having higher conductivity than the oxide layer 230b is used for the oxide layer 230a as described above, the transistor can have normally-off characteristics and a high on-state current. Consequently, the semiconductor device can have both low power consumption and high performance.

The carrier concentration of the oxide layer 230a is preferably higher than the carrier concentration of the oxide layer 230b. Increasing the carrier concentration of the oxide layer 230a results in higher conductivity thereof, which can reduce the contact resistance between the oxide semiconductor layer 230 and the conductive layer 220 and the contact resistance between the oxide semiconductor layer 230 and the conductive layer 240, and thus the transistor can have a high on-state current. Reducing the carrier concentration of the oxide layer 230b results in lower conductivity thereof, which enables the transistor to be normally off.

The structure of the oxide semiconductor layer 230 is not limited to the above structure, and a material having lower conductivity than the oxide layer 230b may be used for the oxide layer 230a. In addition, the carrier concentration of the oxide layer 230a may be lower than the carrier concentration of the oxide layer 230b.

The band gap of a first metal oxide used for the oxide layer 230a is preferably different from the band gap of a second metal oxide used for the oxide layer 230b. For example, the difference between the band gap of the first metal oxide and the band gap of the second metal oxide is preferably larger than or equal to 0.1 eV, further preferably larger than or equal to 0.2 eV, still further preferably larger than or equal to 0.3 eV.

The band gap of the first metal oxide used for the oxide layer 230a is preferably smaller than the band gap of the second metal oxide used for the oxide layer 230b. Thus, the contact resistance between the oxide semiconductor layer 230 and the conductive layer 220 and the contact resistance between the oxide semiconductor layer 230 and the conductive layer 240 can be reduced, and thus the transistor can have a high on-state current. The transistor 200 can have a high threshold voltage in the case where the transistor is an n-channel transistor; accordingly, the transistor 200 can be a normally-off transistor. Since the second metal oxide has a large band gap, carriers can be inhibited from being generated and induced in the oxide layer 230b and at the interface between the oxide layer 230b and the insulating layer 250. Thus, the transistor can have higher reliability.

The content percentage of the element M in the first metal oxide is preferably lower than the content percentage of the element M in the second metal oxide, for example. More specifically, for example, it is preferable to use a metal oxide with a composition of In:M:Zn=1:1:1 [atomic ratio] or in the neighborhood thereof for the oxide layer 230a and a metal oxide with a composition of In:M:Zn=1:3:2 [atomic ratio] or in the neighborhood thereof for the oxide layer 230b. In that case, it is particularly preferable to use one or more of gallium, aluminum, and tin as the element M.

Note that the oxide semiconductor layer 230 is not limited to having the above structure, and the band gap of the first metal oxide may be larger than the band gap of the second metal oxide.

In addition, the content percentage of the element M in the first metal oxide is preferably lower than the content percentage of the element M in the second metal oxide. The first metal oxide may contain no or a slight amount of element M. It is preferable that the first metal oxide used for the oxide layer 230a be an In—Zn oxide, and the second metal oxide used for the oxide layer 230b be an In-M-Zn oxide, for example. Specifically, the first metal oxide can be an In—Zn oxide, and the second metal oxide can be an In—Ga—Zn oxide.

For the oxide layer 230a, it is preferable to use, for example, a metal oxide with a composition of In:Zn=1:1 [atomic ratio] or in the neighborhood thereof, a metal oxide with a composition of In:Zn=2:1 [atomic ratio] or in the neighborhood thereof, a metal oxide with a composition of In:Sn:Zn=2:0.1:1 [atomic ratio] or in the neighborhood thereof, a metal oxide with a composition of In:Zn=4:1 [atomic ratio] or in the neighborhood thereof, a metal oxide with a composition of In:Sn:Zn=4:0.1:1 [atomic ratio] or in the neighborhood thereof, or an indium oxide. For the oxide layer 230b, it is preferable to use a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof. In that case, the on-state current of the transistor 200 can be increased, and the transistor can have high reliability with small variations.

The structure of the oxide semiconductor layer 230 is not limited to the above structure, and the content percentage of the element M in the first metal oxide may be higher than the content percentage of the element M in the second metal oxide.

It is preferable that the oxide semiconductor layer 230 include a metal oxide layer having crystallinity. Examples of the structure of a metal oxide having crystallinity include a CAAC (c-axis aligned crystal) structure, a polycrystalline structure, and a nano-crystal (nc) structure. With the use of the metal oxide layer having crystallinity for the oxide semiconductor layer 230, the density of defect states in the oxide semiconductor layer 230 can be reduced, which enables the semiconductor device to have high reliability.

The higher the crystallinity of the metal oxide layer used for the oxide semiconductor layer 230 is, the lower the density of defect states in the oxide semiconductor layer 230 can be. By contrast, the use of a metal oxide layer having low crystallinity achieves a transistor through which a large amount of current can flow.

In the case where the metal oxide layer is formed by a sputtering method, the higher the substrate temperature (stage temperature) in the formation is, the higher the crystallinity of the formed metal oxide layer can be. The metal oxide layer with higher crystallinity can be formed as the proportion of a flow rate of an oxygen gas to the whole film formation gas (hereinafter, also referred to as oxygen flow rate ratio) used in film formation is increased.

The crystallinity of the oxide semiconductor layer 230 can be analyzed with X-ray diffraction (XRD), a transmission electron microscope (TEM), or electron diffraction (ED), for example. Alternatively, these methods may be combined for the analysis.

The oxide semiconductor layer 230 may have a stacked-layer structure of two or more metal oxide layers having different crystallinities. For example, a stacked-layer structure of a first metal oxide layer and a second metal oxide layer provided over the first metal oxide layer can be employed; the second metal oxide layer can include a region having higher crystallinity than the first metal oxide layer. Alternatively, the second metal oxide layer can include a region having lower crystallinity than the first metal oxide layer. In that case, the composition of the first metal oxide layer may be different from, the same as, or substantially the same as that of the second metal oxide layer.

It is preferable that a metal oxide with a composition of In:M:Zn=1:3:2 [atomic ratio] or in the neighborhood thereof or a metal oxide with a composition of In:M:Zn=1:3:4 [atomic ratio] or in the neighborhood thereof be used for the oxide layer 230a, and that a metal oxide with a composition of In:M:Zn=1:1:1 [atomic ratio] or in the neighborhood thereof be used for the oxide layer 230b, for example. The use of a metal oxide in which the ratio of Zn to In is high for the oxide layer 230a can increase the crystallinity of the oxide layer 230a. Furthermore, forming the oxide layer 230b over the oxide layer 230a with high crystallinity facilitates increasing the crystallinity of the oxide layer 230b. This is preferable because the crystallinity of the whole oxide semiconductor layer 230 can be increased. In that case, gallium, aluminum, or tin is particularly preferably used as the element M. For example, two IGZO layers having different compositions may be stacked. For another example, a stacked-layer structure of one selected from an indium oxide, an indium gallium oxide, and an IGZO, and one selected from an IAZO, an IAGZO, and an ITZO (registered trademark) may be employed.

As illustrated in FIG. 5B, the oxide semiconductor layer 230 can have a three-layer structure of the oxide layer 230c, the oxide layer 230a over the oxide layer 230c, and the oxide layer 230b over the oxide layer 230a.

The above-described structure can be applied to each of the oxide layer 230a and the oxide layer 230b. The structure of the oxide layer 230c can be similar to the structure that can be applied to the oxide layer 230b.

For the oxide layer 230a, it is preferable to use, for example, a metal oxide with a composition of In:Zn=1:1 [atomic ratio] or in the neighborhood thereof, a metal oxide with a composition of In:Zn=2:1 [atomic ratio] or in the neighborhood thereof, a metal oxide with a composition of In:Sn:Zn=2:0.1:1 [atomic ratio] or in the neighborhood thereof, a metal oxide with a composition of In:Zn=4:1 [atomic ratio] or in the neighborhood thereof, a metal oxide with a composition of In:Sn:Zn=4:0.1:1 [atomic ratio] or in the neighborhood thereof, or an indium oxide. For each of the oxide layer 230b and the oxide layer 230c, it is preferable to use a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof.

The oxide layer 230b and the oxide layer 230c each preferably have a larger band gap than the oxide layer 230a. In that case, the oxide layer 230a is sandwiched between the oxide layer 230b and the oxide layer 230c each having a large band gap, and the oxide layer 230a mainly functions as a current path (channel). When the oxide layer 230a is sandwiched between the oxide layer 230b and the oxide layer 230c, the trap states at the interfaces with the oxide layer 230a and the vicinity thereof can be reduced. Accordingly, a buried-channel transistor in which a channel is distanced from the interface with an insulating layer can be achieved, whereby the field-effect mobility can be increased. Furthermore, the influence of interface states that can be formed on the back channel side is reduced, so that light deterioration (e.g., light negative bias deterioration) of the transistor can be inhibited and the reliability of the transistor can be increased.

The thickness of the oxide semiconductor layer 230 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet still further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, yet still further preferably greater than or equal to 20 nm and less than or equal to 50 nm. In a transistor used for a further downsized semiconductor device, the thickness of the oxide semiconductor layer 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

Hydrogen contained in the oxide semiconductor reacts with oxygen bonded to a metal atom to be water, and thus forms an oxygen vacancy (Vo) in the oxide semiconductor, in some cases. A defect that is an oxygen vacancy which hydrogen enters (hereinafter referred to as VoH) functions as a donor and generates an electron serving as a carrier, in some cases. In some cases, bonding of part of hydrogen to oxygen bonded to a metal atom generates an electron serving as a carrier. Thus, a transistor including an oxide semiconductor that contains a large amount of hydrogen is likely to have normally-on characteristics (i.e., a negative threshold voltage value). Hydrogen in the oxide semiconductor is easily transferred by a stress such as heat or an electric field; thus, a large amount of hydrogen contained in the oxide semiconductor might reduce the reliability of the transistor.

The amount of VoH in the oxide semiconductor layer 230 is preferably reduced as much as possible so that the oxide semiconductor layer 230 becomes a highly purified intrinsic or substantially highly purified intrinsic oxide semiconductor layer. In order to obtain such an oxide semiconductor with sufficiently reduced VoH, it is important to remove impurities such as water and hydrogen in the oxide semiconductor (which is sometimes described as dehydration or dehydrogenation treatment) and to repair oxygen vacancies by supplying oxygen to the oxide semiconductor. When an oxide semiconductor with a sufficiently reduced impurities such as VoH is used for the channel formation region of the transistor, stable electrical characteristics can be given. Note that repairing oxygen vacancies by supplying oxygen to an oxide semiconductor is sometimes referred to as oxygen adding treatment.

The carrier concentration of the oxide semiconductor in the region functioning as the channel formation region is preferably lower than or equal to 1×10¹⁸ cm⁻³, further preferably lower than 1×10¹⁷ cm⁻³, still further preferably lower than 1× 1016 cm⁻³, yet further preferably lower than 1×10¹³ cm⁻³, yet still further preferably lower than 1×10¹² cm⁻³. The lower limit of the carrier concentration of the oxide semiconductor in the region functioning as the channel formation region is not particularly limited and can be, for example, 1× 10⁻⁹ cm⁻³.

Here, the influence of each impurity in the metal oxide (oxide semiconductor) is described.

When silicon or carbon, which is one of Group 14 elements, is contained in the oxide semiconductor, defect states are formed in the oxide semiconductor. Thus, the carbon concentration in the channel formation region of the oxide semiconductor, which is obtained by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³. The silicon concentration in the channel formation region of the oxide semiconductor, which is obtained by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³.

When the oxide semiconductor contains nitrogen, the oxide semiconductor easily becomes n-type by generation of electrons serving as carriers and an increase in carrier concentration. As a result, a transistor including an oxide semiconductor that contains nitrogen as a semiconductor is likely to have normally-on characteristics. Alternatively, when nitrogen is contained in the oxide semiconductor, trap states are sometimes formed. This might make the electrical characteristics of the transistor unstable. Therefore, the nitrogen concentration in the channel formation region of the oxide semiconductor, which is obtained by SIMS, is lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy causes generation of an electron serving as a carrier in some cases. Furthermore, bonding of part of hydrogen to oxygen bonded to a metal atom causes generation of an electron serving as a carrier in some cases. Thus, a transistor including an oxide semiconductor that contains hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor, which is obtained by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated in some cases. Thus, a transistor including an oxide semiconductor that contains an alkali metal or an alkaline earth metal is likely to have normally-on characteristics. Accordingly, the concentration of an alkali metal or an alkaline earth metal in the channel formation region of the oxide semiconductor, which is obtained by SIMS, is lower than or equal to 1×10¹⁸ atoms/cm³, preferably lower than or equal to 2× 1016 atoms/cm³.

When an oxide semiconductor with sufficiently reduced impurities is used for the channel formation region of the transistor, stable electrical characteristics can be given.

In the semiconductor device of this embodiment, a transistor including a different semiconductor material in its channel formation region may be used. Examples of the different semiconductor material include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also a kind of compound semiconductor. These semiconductor materials may contain an impurity as a dopant.

Examples of silicon that can be used for the semiconductor material for the transistor include single crystal silicon, polycrystalline silicon, microcrystalline silicon, and amorphous silicon. Examples of polycrystalline silicon include low-temperature polysilicon (LTPS).

The semiconductor layer of the transistor may include a layered substance that functions as a semiconductor. The layered substance is a general term of a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered substance include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typified by MoS₂), molybdenum selenide (typified by MoSe₂), molybdenum telluride (typified by MoTe₂), tungsten sulfide (typified by WS₂), tungsten selenide (typified by WSe₂), tungsten telluride (typified by WTe₂), hafnium sulfide (typified by HfS₂), hafnium selenide (typified by HfSe₂), zirconium sulfide (typified by ZrS₂), and zirconium selenide (typified by ZrSe₂).

### [Substrate]

As a substrate where the transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, any of these substrates provided with an element may be used. Examples of the element provided for the substrate include a capacitor, a resistor, a switching element, a light-emitting element, and a memory element.

### Example 1 of Method for Manufacturing Semiconductor Device

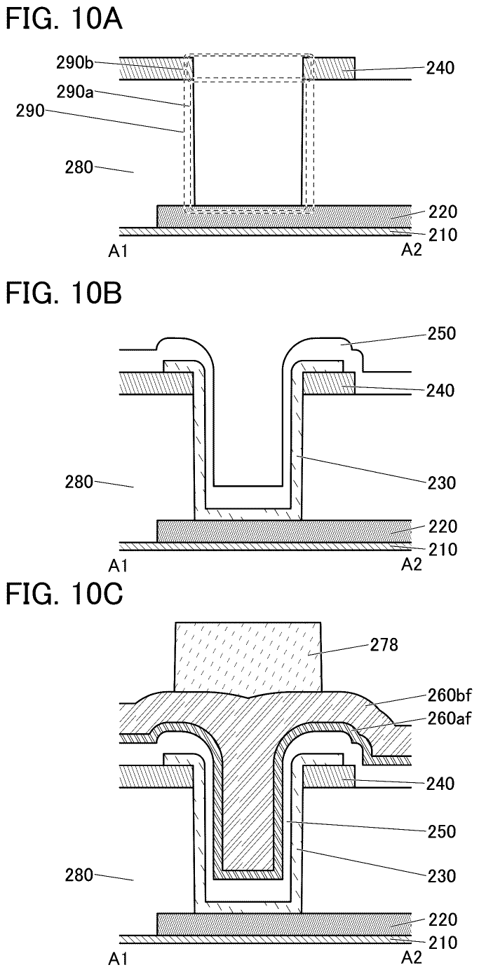

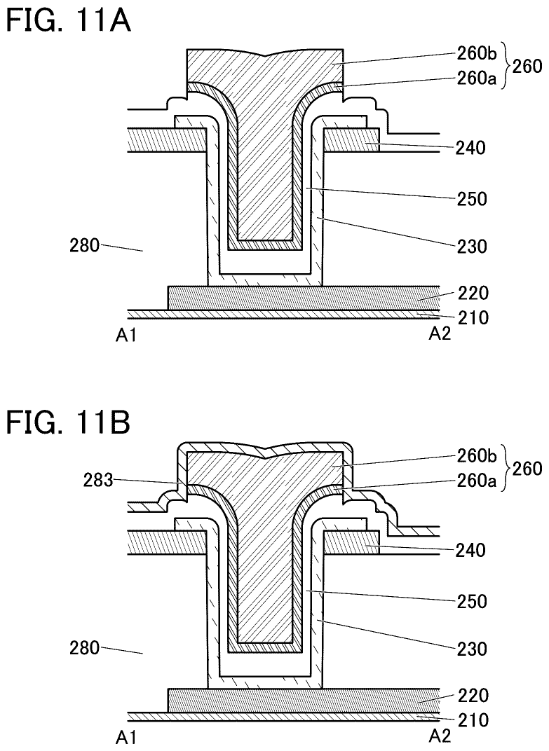

A method for manufacturing the semiconductor device illustrated in FIG. 1A to FIG. 1C and the like will be described with reference to FIG. 10A to FIG. 11B. Note that as for a material and a formation method of each component, portions similar to the portions described above are not described in some cases.

Thin films (an insulating film, a semiconductor film, a conductive film, and the like) included in the semiconductor device can be formed by a sputtering method, a CVD method, a vacuum evaporation method, a PLD method, an ALD method, or the like.

Examples of a sputtering method include an RF sputtering method in which a high-frequency power source is used as a sputtering power source, a DC sputtering method in which a direct-current power source is used, and a pulsed DC sputtering method in which voltage applied to an electrode is changed in a pulsed manner. Furthermore, an RF superimposed DC sputtering method can be given. For film formation using an insulating target, an RF sputtering method is preferably used. A DC sputtering method is used mainly in the case of film formation using a conductive target. In a DC sputtering method, not only formation of a conductive film but also formation of an insulating film is possible when reactive sputtering is performed. A pulsed DC sputtering method is mainly used in the case where a film of a compound such as an oxide, a nitride, or a carbide is formed by a reactive sputtering method. In an RF superimposed DC sputtering method, the ion energy and the potential on the target side can be controlled during film formation. Thus, damage due to film formation can be reduced as compared with that in the case of an RF sputtering method. Moreover, a high-quality film can be obtained.

As a sputtering method, for example, an ionization sputtering method, a long throw sputtering method, or the like can be used. The ionization sputtering method is a method in which a sputtering particle generated from a target is ionized by RF or the like and film formation is performed with anisotropy by a self bias or the like. In the long throw sputtering method, the distance between a sputtering target and a substrate is made long to enable anisotropic film formation.

Note that CVD methods can be classified into a PECVD method, a thermal CVD (TCVD) method using heat, a photo CVD method using light, and the like. Moreover, CVD methods can be classified into a metal CVD (MCVD) method and a metal organic CVD (MOCVD) method depending on a source gas to be used.

A high-quality film can be obtained at a relatively low temperature by a plasma CVD method. A thermal CVD method is a film formation method that does not use plasma and thus enables less plasma damage to an object. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, a thermal CVD method, which does not use plasma, does not cause such plasma damage, and thus can increase the yield of the semiconductor device. In addition, since a thermal CVD method does not cause plasma damage during film formation, a film with few defects can be obtained.

As an ALD method, a thermal ALD method, in which a precursor and a reactant react with each other only by a thermal energy, a PEALD (Plasma Enhanced ALD) method, in which a reactant excited by plasma is used, or the like can be used.

An ALD method, which enables atomic layers to be deposited one by one, has effects such as enabling formation of an extremely thin film, enabling film formation on a component with a high aspect ratio, enabling formation of a film with a small number of defects such as pinholes, enabling film formation with excellent coverage, and enabling low-temperature film formation. The use of plasma in a PEALD (Plasma Enhanced ALD) method is sometimes preferable because film formation at a lower temperature is possible. Note that a precursor used in an ALD method sometimes contains impurities such as carbon. Thus, in some cases, a film provided by an ALD method contains impurities such as carbon in a larger amount than a film provided by another film formation method. Note that impurities can be quantified by X-ray photoelectron spectroscopy (XPS).

Unlike a film formation method in which particles ejected from a target or the like are deposited, a CVD method and an ALD method are film formation methods in which a film is formed by reaction at a surface of an object. Thus, a CVD method and an ALD method are film formation methods that enable good step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low film formation rate, and thus is preferably used in combination with another film formation method with a high film formation rate, such as a CVD method, in some cases.

A CVD method and an ALD method enable control of the composition of a film to be obtained by using a flow rate ratio of source gases. For example, in a CVD method and an ALD method, a film with a certain composition can be formed depending on the flow rate ratio of the source gases. Moreover, for example, by a CVD method and an ALD method, a film whose composition is continuously changed can be formed by changing the flow rate ratio of the source gases during film formation. In the case where a film is formed while the flow rate ratio of the source gases is changed, as compared with the case where a film is formed using a plurality of film formation chambers, the time taken for the film formation can be shortened because the time taken for transfer and pressure adjustment is not required. Thus, the productivity of the semiconductor device can be increased in some cases.

By a CVD method, a film with a certain composition can be formed depending on the flow rate ratio of the source gases. For example, by a CVD method, a film whose composition is continuously changed can be formed by changing the flow rate ratio of the source gases during film formation. In the case where a film is formed while the flow rate ratio of the source gases is changed, as compared with the case where a film is formed using a plurality of film formation chambers, the time taken for the film formation can be shortened because the time taken for transfer or pressure adjustment is not required. Thus, the productivity of the semiconductor device can be increased in some cases.

By an ALD method, a film with a certain composition can be formed by concurrently introducing different kinds of precursors. In the case where different kinds of precursors are introduced, a film with a certain composition can be formed by controlling the number of cycles for each of the precursors.

Thin films (an insulating film, a semiconductor film, a conductive film, and the like) included in the semiconductor device can be formed by a wet film formation method such as a spin coating method, a dip coating method, a spray coating method, an inkjet method, dispensing, screen printing, offset printing, a doctor knife method, slit coating, roll coating, curtain coating, or knife coating.

In processing thin films included in the semiconductor device, a photolithography method or the like can be employed. Alternatively, the thin films may be processed by a nanoimprinting method, a sandblasting method, a lift-off method, or the like. Alternatively, island-shaped thin films may be directly formed by a film formation method using a shielding mask such as a metal mask.

There are the following two typical examples of photolithography methods. In one of the methods, a resist mask is formed over a thin film to be processed, the thin film is processed by etching or the like, and then the resist mask is removed. In the other method, a photosensitive thin film is formed and then the thin film is processed into a desired shape by light exposure and development.

As light used for light exposure in a photolithography method, for example, an i-line (wavelength: 365 nm), a g-line (wavelength: 436 nm), an h-line (wavelength: 405 nm), or combined light of any of them can be used. Alternatively, ultraviolet light, KrF laser light, ArF laser light, or the like can be used. The light exposure may be performed by a liquid immersion exposure technique. As the light used for the light exposure, extreme ultraviolet (EUV) light or X-rays may be used. Instead of the light used for the light exposure, an electron beam can be used. Extreme ultraviolet light, X-rays, or an electron beam is preferably used, in which case extremely minute processing can be performed. Note that a photomask is not needed when the light exposure is performed by scanning with a beam such as an electron beam.

For etching of thin films, a dry etching method, a wet etching method, a sandblasting method, or the like can be used.

First, the conductive layer 220 is formed over the insulating layer 210, the insulating layer 280 is formed over the conductive layer 220, and the conductive layer 240 is formed over the insulating layer 280.

Note that the top surface of the insulating layer 280 is preferably planarized by planarization treatment using a chemical mechanical polishing (CMP) method (also referred to as CMP treatment) after the formation of the insulating layer 280. By the planarization treatment of the insulating layer 280, the formation surface of the conductive layer 240 functioning as a wiring can be made flat, whereby disconnection of the conductive layer 240 can be inhibited. The planarization treatment is not necessarily performed, in which case the manufacturing cost can be reduced.

Next, the opening 290 is formed in the conductive layer 240 and the insulating layer 280 at a position overlapping with the conductive layer 220.

Since the opening 290 has a high aspect ratio, part of the conductive layer 240 and part of the insulating layer 280 are preferably processed by anisotropic etching. Processing by a dry etching method is particularly preferable because it is suitable for fine processing. The processing may be performed under different conditions depending on layers. The inclination of the side surface of the conductive layer 240 and the inclination of the side surface of the insulating layer 280 in the opening 290 are different from each other in some cases depending on the processing conditions of the conductive layer 240 and the insulating layer 280.

Next, heat treatment may be performed. The heat treatment is performed at, for example, higher than or equal to 250° C. and lower than or equal to 650° C., preferably higher than or equal to 300° C. and lower than or equal to 500° C., further preferably higher than or equal to 320° C. and lower than or equal to 450° C.

The heat treatment is performed in a nitrogen gas or inert gas atmosphere, or an atmosphere containing an oxidizing gas at higher than or equal to 10 ppm, higher than or equal to 1%, or higher than or equal to 10%. In the case where the heat treatment is performed in a mixed atmosphere of a nitrogen gas and an oxygen gas, for example, the proportion of the oxygen gas is preferably approximately 20%. The heat treatment may be performed under reduced pressure. Alternatively, heat treatment may be performed in a nitrogen gas or inert gas atmosphere, and then another heat treatment may be performed in an atmosphere containing an oxidizing gas at higher than or equal to 10 ppm, higher than or equal to 1%, or higher than or equal to 10% in order to compensate for released oxygen. By the above-described heat treatment, impurities such as water contained in the insulating layer 280, for example, can be reduced before formation of the oxide semiconductor layer 230.

The gas used in the above heat treatment is preferably highly purified. For example, the amount of moisture contained in the gas used in the above heat treatment is preferably lower than or equal to 1 ppb, further preferably lower than or equal to 0.1 ppb, still further preferably lower than or equal to 0.05 ppb. The heat treatment using a highly purified gas can prevent entry of moisture or the like into the insulating layer 280 and the like as much as possible.

Next, the conductive layer 240 is processed into an island shape (FIG. 10A). The step of processing the conductive layer 240 into an island shape and the step of providing the opening 290 in the conductive layer 240 can be performed independently, and there is no limitation on the order in that case. Alternatively, the processing into an island shape and the formation of the opening may be performed at a time in the following manner: light exposure using a mask for processing into a quadrangular island shape and light exposure using a mask for providing a circular opening are performed, and then, etching is performed. Light exposure using a multi-tone mask (typified by a half-tone mask or a gray-tone mask) may be used. An opening may be formed in the conductive layer 240 and the insulating layer 280 using the same mask or using different masks.

Next, the oxide semiconductor layer 230 is formed to cover the opening 290. Then, the insulating layer 250 is formed over the oxide semiconductor layer 230 (FIG. 10B). The oxide semiconductor layer 230 is formed in contact with the top surface of the conductive layer 220, the side surface of the insulating layer 280, and the top surface and the side surface of the conductive layer 240. The insulating layer 250 is formed in contact with the oxide semiconductor layer 230.

The oxide semiconductor layer 230 can be formed by a sputtering method, a CVD method, an MBE method, a PLD method, or an ALD method, for example.

The oxide semiconductor layer 230 is preferably formed as a film having as uniform a thickness as possible along the top surface of the conductive layer 220, the side surface of the insulating layer 280, and the side surface of the conductive layer 240, in the opening 290. By an ALD method, a thin film can be formed with good controllability. Thus, the oxide semiconductor layer 230 is preferably formed by an ALD method.

When the oxide semiconductor layer 230 has high crystallinity, diffusion of impurities in the oxide semiconductor layer 230 is inhibited; thus, electrical characteristics of the transistor are less likely to change and the reliability of the transistor can be improved. The oxide semiconductor layer 230 is preferably formed by a sputtering method, in which case a layer with high crystallinity can be obtained easily as compared with the case of using an ALD method.

In the case where the oxide semiconductor layer 230 is formed by a sputtering method, oxygen or a mixed gas of oxygen and a noble gas is used as a sputtering gas. Increasing the proportion of oxygen contained in the sputtering gas can increase the amount of excess oxygen in an oxide film to be formed. In the case where the oxide film is formed by a sputtering method, an In-M-Zn oxide target or the like can be used.

In the formation of the oxide semiconductor layer 230 by a sputtering method, setting the proportion of oxygen contained in the sputtering gas to higher than 30% and lower than or equal to 100%, preferably higher than or equal to 70% and lower than or equal to 100% allows formation of an oxygen-excess oxide semiconductor. A transistor including an oxygen-excess oxide semiconductor in its channel formation region can have relatively high reliability. Note that one embodiment of the present invention is not limited thereto. When the proportion of oxygen contained in the sputtering gas at the time of the film formation is higher than or equal to 1% and lower than or equal to 30%, preferably higher than or equal to 5% and lower than or equal to 20%, an oxygen-deficient oxide semiconductor is formed. A transistor including an oxygen-deficient oxide semiconductor in its channel formation region can have relatively high field-effect mobility. When the film formation is performed while the substrate is heated, the crystallinity of the oxide semiconductor layer can be improved.

Next, heat treatment is preferably performed. The heat treatment is preferably performed in a temperature range where the oxide semiconductor layer 230 does not become polycrystal. The temperature of the heat treatment is preferably higher than or equal to 100° C. and lower than or equal to 650° C., further preferably higher than or equal to 250° C. and lower than or equal to 600° C., still further preferably higher than or equal to 350° C. and lower than or equal to 550° C. For the details of the heat treatment, the above description can be referred to.

The gas used in the above heat treatment is preferably highly purified. The heat treatment using a highly purified gas can prevent entry of moisture or the like into the oxide semiconductor layer 230 as much as possible.

In this embodiment, as the above heat treatment, treatment at 450° C. for one hour is performed with a flow rate ratio of a nitrogen gas to an oxygen gas of 4:1. By the heat treatment using the oxygen gas, impurities such as carbon, water, and hydrogen in the oxide semiconductor layer 230 can be reduced. The reduction of impurities in the film improves the crystallinity of the oxide semiconductor layer 230, thereby offering a dense structure with higher density. Accordingly, the crystal region in the oxide semiconductor layer 230 can be expanded, and an in-plane variation in the crystal region in the oxide semiconductor layer 230 can be reduced. Thus, an in-plane variation in electrical characteristics of transistors can be reduced.

In the case where the insulating layer 280 includes oxygen, oxygen is preferably supplied from the insulating layer 280 to the channel formation region of the oxide semiconductor layer 230 by the heat treatment. Accordingly, oxygen vacancies and VoH can be reduced.

The insulating layer 250 is preferably formed by a method with deposition rate anisotropy. For example, a sputtering method, a CVD method, or the like can provide deposition rate anisotropy.

As a sputtering method, for example, an ionization sputtering method, a long throw sputtering method, or the like can be used.

As a CVD method, for example, a PECVD method can be used. Here, a PECVD method using RF is preferably used.

In the case where the insulating layer 250 includes the insulating layer 250a and the insulating layer 250b over the insulating layer 250a as illustrated in FIG. 6A to FIG. 7B and the like, one of the insulating layer 250a and the insulating layer 250b is preferably formed by a method with high deposition rate anisotropy. In that case, a method with relatively low deposition rate anisotropy is used for the other. As the method with relatively low deposition rate anisotropy, an ALD method is preferably used, for example.

Next, a conductive layer 260af is formed over the insulating layer 250, and a conductive layer 260bf is formed to be stacked over the conductive layer 260af.

The conductive layer 260af is formed in contact with the insulating layer 250 provided in the opening 290 with a high aspect ratio. Thus, the conductive layer 260af is preferably formed by a formation method providing favorable coverage, and is further preferably formed by a CVD method, an ALD method, or the like.

When the conductive layer 260bf is formed by a sputtering method, a CVD method, or the like, for example, a film with a large thickness can be favorably formed at a high film formation rate, making the manufacturing process efficient.

Next, a mask 278 is formed over the conductive layer 260bf (FIG. 10C). A resist mask can be used as the mask 278. Alternatively, as the mask 278, a structure in which an SOC (Spin On Carbon) film, an SOG (Spin On Glass) film, and a resist mask are stacked in this order over the conductive layer 260bf may be used.

Next, the conductive layer 260bf is partially removed using the mask 278, so that the conductive layer 260b is formed.

Next, the conductive layer 260af is partially removed to form the conductive layer 260a (FIG. 11A. Here, the conductive layer 260af is partially removed using the conductive layer 260b as a mask. Here, the mask 278 may remain at the time of forming the conductive layer 260a. In the case where the mask 278 remains, the conductive layer 260af is partially removed using the mask 278 and the conductive layer 260b as masks. In the case where the mask 278 remains, for example, the formation of the conductive layer 260a is followed by removal of the mask 278.

For the processing for the conductive layer 260b and the conductive layer 260a, dry etching is used, for example. After the conductive layer 260af is processed into the conductive layer 260a by removing part thereof in the dry etching step, the surface of the insulating layer 250 is exposed in a region not covered with the conductive layer 260a. In that case, the thickness of the region where the surface of the insulating layer 250 is exposed is reduced by overetching. When a film with deposition rate anisotropy is used for the insulating layer 250, the thickness of the region where the overetching occurs can be large. Accordingly, the thickness can be sufficient to inhibit gate leakage current and a short circuit even in the case where the thickness of the insulating layer 250 is reduced by the overetching.

Next, the insulating layer 283 is formed over the insulating layer 250 and the conductive layer 260 (FIG. 11B).

Through the above steps, the semiconductor device of one embodiment of the present invention can be manufactured.

### Example 2 of Method for Manufacturing Semiconductor Device

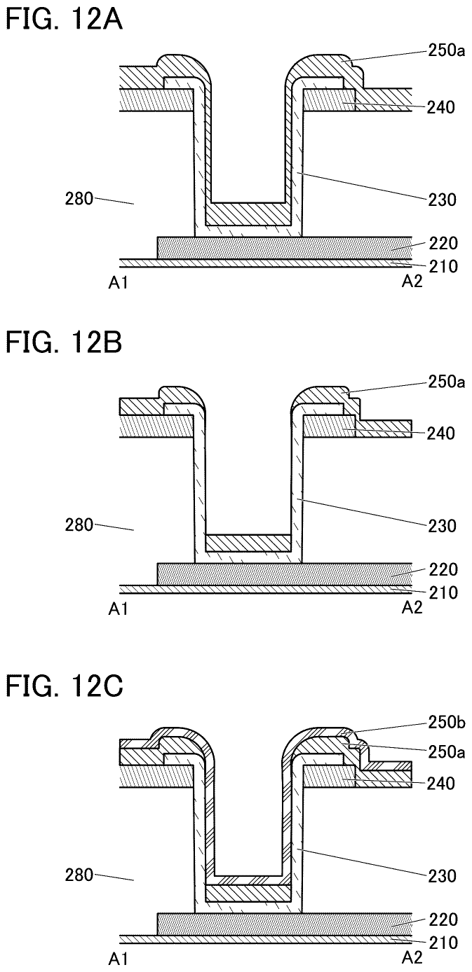

A variation example of the method for forming the insulating layer 250 will be described with reference to FIG. 12A to FIG. 13.

First, the conductive layer 220, the insulating layer 280, and the conductive layer 240 over the insulating layer 210 are formed with reference to FIG. 10A. Next, the oxide semiconductor layer 230 is formed to cover the opening 290.

Subsequently, the insulating layer 250a is formed over the oxide semiconductor layer 230, the conductive layer 240, and the insulating layer 280 (FIG. 12A). The insulating layer 250a is formed by a method with deposition rate anisotropy.

Next, the insulating layer 250a is removed by a desired thickness from its surface, so that a region of the insulating layer 250a that covers the sidewall of the insulating layer 280 in the opening 290a is removed. Consequently, the surface of the oxide semiconductor layer 230 is exposed in a region that covers the sidewall of the insulating layer 280 in the opening 290a (FIG. 12B). As a method for etching the insulating layer 250a, wet etching is preferably used here. In the case of using wet etching, damage to the exposed oxide semiconductor layer 230 due to exposure to etching can be extremely small as compared to the case of using dry etching, for example. As a chemical solution for wet etching, for example, hydrofluoric acid, a mixed solution containing hydrofluoric acid, a solution containing phosphoric acid, or the like can be used.

Subsequently, the insulating layer 250b is formed over the insulating layer 250a and the region where the oxide semiconductor layer 230 is exposed (FIG. 12C). When an ALD method is used for forming the insulating layer 250b, a dense gate insulating layer with a uniform thickness can be formed to overlap with the channel formation region of the oxide semiconductor layer 230.

The insulating layer 250a is formed by an etching method with deposition rate anisotropy. Such a method with anisotropy has difficulty in controlling the thickness of the sidewall in some cases, for example. With the structure illustrated in FIG. 12C, the thickness of the gate insulating layer in the region overlapping with the channel formation region is determined only by the thickness of the insulating layer 250b; hence, the controllability of the thickness can be further increased.

Then, the conductive layer 260 and the insulating layer 283 are formed, whereby a semiconductor device illustrated in FIG. 13 can be manufactured.

### Example 3 of Method for Manufacturing Semiconductor Device

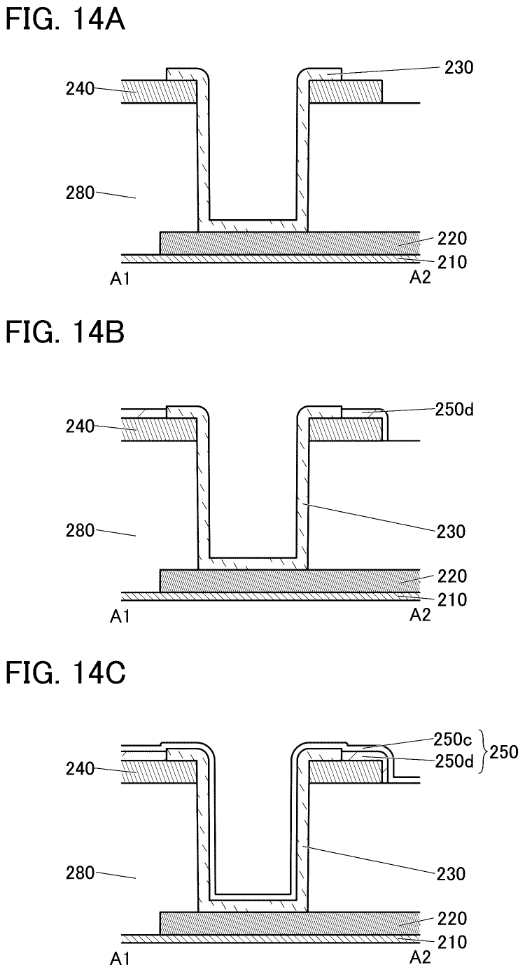

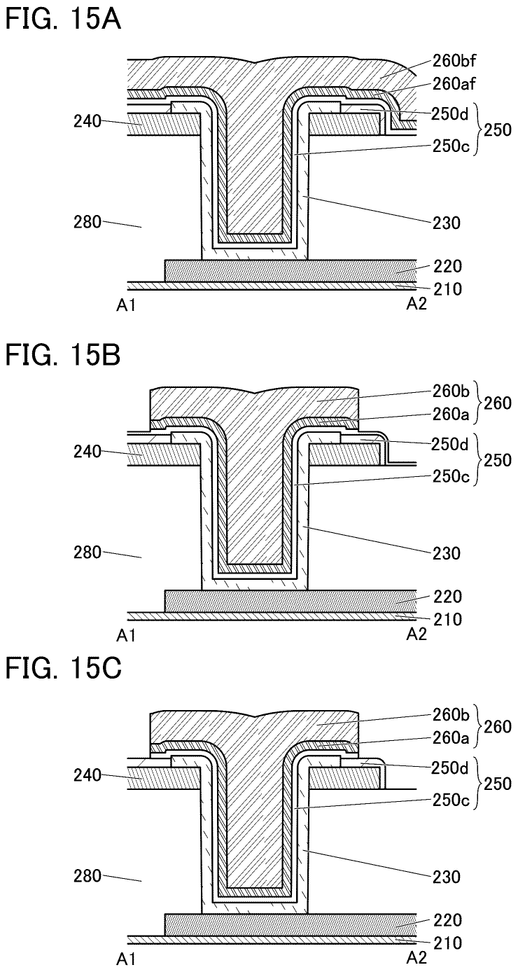

Next, a method for manufacturing the semiconductor illustrated in FIG. 8A to FIG. 8C will be described with reference to FIG. 14A to FIG. 15C.

First, the conductive layer 220, the insulating layer 280, and the conductive layer 240 over the insulating layer 210 are formed with reference to FIG. 10A. Next, the oxide semiconductor layer 230 is formed to cover the opening 290 (FIG. 14A).

The conductive layer 240 preferably includes a metal layer. In the case where the conductive layer 240 has a stacked-layer structure, the uppermost layer is preferably a metal layer. Here, an ITO or an ITSO is used for a lower layer and ruthenium or tungsten is used for an upper layer, for example. The top surface of the upper layer of the conductive layer 240 is in contact with the oxide semiconductor layer 230. When a metal that is easily oxidized, such as aluminum, is used for the upper layer of the conductive layer 240, for example, an insulating oxide (e.g., aluminum oxide) is formed between the conductive layer 240 and the oxide semiconductor layer 230, which might prevent conduction therebetween. Therefore, a conductive material that is not easily oxidized, a conductive material that maintains low electric resistance even after being oxidized, or an oxide conductive material is preferably used for the upper layer of the conductive layer 240. Here, in the case of using a metal for the upper layer of the conductive layer 240, titanium, ruthenium, tungsten, or the like can be used. These materials are preferable because they are conductive materials that are not easily oxidized or materials that maintain the conductivity even after being oxidized.

Then, the insulating layer 250d is selectively formed over a region where the surface of the conductive layer 240 is exposed (FIG. 14B). In the case where vapor phase epitaxy is used as a method for forming the insulating layer 250d, for example, a material that selectively grows over a metal in the growth process, e.g., at the beginning of the growth process, is used, which allows selective formation of the insulating layer 250d over a metal layer, which is the uppermost layer of the conductive layer 240. Here, the insulating layer 250d is preferably formed on the top surface of the conductive layer 240. The insulating layer 250d may be formed also on the side surface of the conductive layer 240. In some cases, the insulating layer 250d is not formed on the side surface of the conductive layer 240, or the film thickness on the side surface is smaller than that on the top surface.

Next, the insulating layer 250c is formed over the oxide semiconductor layer 230, the insulating layer 250d, and the insulating layer 280 (FIG. 14C).

The insulating layer 250c can be formed by an ALD method, a CVD method, an MBE method, a PLD method, a sputtering method, or the like as appropriate.

Next, the conductive layer 260af and the conductive layer 260bf are formed over the insulating layer 250c (FIG. 15A).

Subsequently, the conductive layer 260b and the conductive layer 260a are formed using a mask (FIG. 15B). Here, after the processing for the conductive layer 260a, the surface of the insulating layer 250 is exposed in a region not covered with the conductive layer 260a. In that case, the thickness of the region where the surface of the insulating layer 250 is exposed is reduced by overetching. Since the insulating layer 250d is provided over the conductive layer 240, the insulating layer 250d having a sufficient thickness to inhibit gate leakage current and a short circuit can remain over the conductive layer 240 even in the case where the thickness of the insulating layer 250c is reduced by the overetching.

Here, as illustrated in FIG. 15C, the insulating layer 250c is removed in the region not covered with the conductive layer 260a under some etching conditions for the processing for the conductive layer 260a. Even in such a case, owing to the insulating layer 250d, the insulating layer 250d having a sufficient thickness to inhibit gate leakage current and a short circuit can remain over the conductive layer 240.

Then, the insulating layer 283 is formed over the insulating layer 250 and the conductive layer 260, whereby the semiconductor device of one embodiment of the present invention can be manufactured.

This embodiment can be combined with the other embodiments as appropriate. In this specification, in the case where a plurality of structure examples are shown in one embodiment, the structure examples can be combined as appropriate.

### Embodiment 2

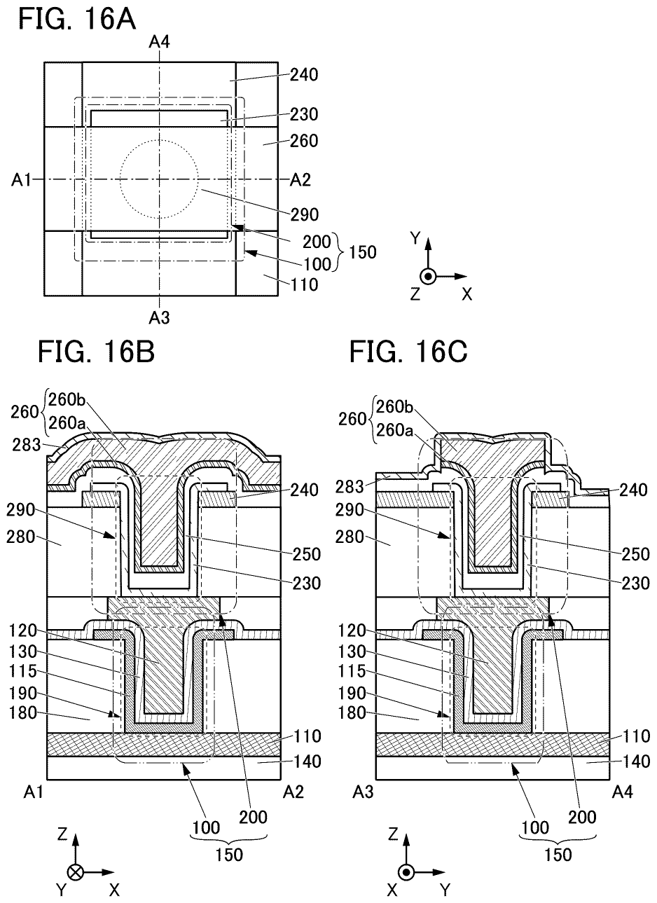

In this embodiment, a memory device of one embodiment of the present invention will be described with reference to FIG. 16 to FIG. 19. The memory device of one embodiment of the present invention includes a memory cell. The memory cell includes a transistor and a capacitor.

### Structure Example 1 of Memory Device

A structure of a memory device including a transistor and a capacitor is described with reference to FIG. 16A to FIG. 16C. FIG. 16A is a plan view of the memory device including the transistor 200 and a capacitor 100. FIG. 16B is a cross-sectional view taken along dashed-dotted line A1-A2 in FIG. 16A. FIG. 16C is a cross-sectional view taken along dashed-dotted line A3-A4 in FIG. 16A.

The memory device illustrated in FIG. 16A to FIG. 16C includes an insulating layer 140 over a substrate (not illustrated), a conductive layer 110 over the insulating layer 140, a memory cell 150 over the conductive layer 110, an insulating layer 180 over the conductive layer 110, the insulating layer 280, and the insulating layer 283 over the memory cell 150. The insulating layer 140, the insulating layer 180, the insulating layer 280, and the insulating layer 283 each function as an interlayer film. The conductive layer 110 functions as a wiring.

The memory cell 150 includes the capacitor 100 over the conductive layer 110 and the transistor 200 over the capacitor 100.

The capacitor 100 includes a conductive layer 115 over the conductive layer 110, the insulating layer 130 over the conductive layer 115, and a conductive layer 120 over the insulating layer 130. The conductive layer 120 functions as one of a pair of electrodes (sometimes referred to as an upper electrode), the conductive layer 115 functions as the other of the pair of electrodes (sometimes referred to as a lower electrode), and the insulating layer 130 functions as a dielectric. That is, the capacitor 100 forms a MIM (Metal-Insulator-Metal) capacitor.

As illustrated in FIG. 16B and FIG. 16C, an opening 190 reaching the conductive layer 110 is provided in the insulating layer 180. At least part of the conductive layer 115 is placed in the opening 190. The conductive layer 115 includes a region in contact with the top surface of the conductive layer 110 in the opening 190, a region in contact with a side surface of the insulating layer 180 in the opening 190, and a region in contact with at least part of the top surface of the insulating layer 180. At least part of the insulating layer 130 is placed in the opening 190. At least part of the conductive layer 120 is placed in the opening 190. The conductive layer 120 is preferably provided to fill the opening 190 as illustrated in FIG. 16B and FIG. 16C. Note that films provided in the opening 190 are preferably formed by an ALD method. In that case, the coverage with the films can be favorable. For example, the conductive layer 115, the insulating layer 130, and the conductive layer 120 are preferably formed by an ALD method.

The capacitor 100 has a structure in which the upper electrode and the lower electrode face each other with the dielectric therebetween on a side surface as well as on the bottom surface of the opening 190; thus, the capacitance per unit area can be increased. Thus, the deeper the opening 190 is, the higher the capacitance of the capacitor 100 can be. Increasing the capacitance per unit area of the capacitor 100 in this manner enables a stable reading operation of the memory device. This also allows further miniaturization or high integration of the memory device.

FIG. 16B and FIG. 16C illustrate an example in which a sidewall of the opening 190 is perpendicular to the top surface of the conductive layer 110. In that case, the opening 190 has a cylindrical shape. With such a structure, the memory device can be miniaturized or highly integrated.

The conductive layer 115 and the insulating layer 130 are stacked along the sidewall of the opening 190 and the top surface of the conductive layer 110. The conductive layer 120 is provided over the insulating layer 130 to fill the opening 190. The capacitor 100 having such a structure may be referred to as a trench-type capacitor or a trench capacitor.

The insulating layer 280 is placed over the capacitor 100. That is, the insulating layer 280 is placed over the conductive layer 115, the insulating layer 130, and the conductive layer 120. In other words, the conductive layer 120 is placed under the insulating layer 280.

The transistor 200 includes the conductive layer 120 (corresponding to the conductive layer 220 in FIG. 1B and the like), the conductive layer 240 over the insulating layer 280, the oxide semiconductor layer 230, the insulating layer 250 over the oxide semiconductor layer 230, and the conductive layer 260 over the insulating layer 250. The oxide semiconductor layer 230 functions as a semiconductor layer, the conductive layer 260 functions as a gate electrode, the insulating layer 250 functions as a gate insulating layer, the conductive layer 120 functions as one of a source electrode and a drain electrode, and the conductive layer 240 functions as the other of the source electrode and the drain electrode.

The description in Embodiment 1 (FIG. 1, FIG. 2, and the like) can be referred to for the transistor 200; thus, the detailed description thereof is omitted. The transistor included in the memory cell 150 is not limited to the transistor 200 of FIG. 1 to FIG. 2 and the like, and any of the transistors described as examples in Embodiment 1 can be used.

As illustrated in FIG. 16A to FIG. 16C, the transistor 200 is provided to overlap with the capacitor 100. The opening 290 where some of the components of the transistor 200 are provided includes a region overlapping with the opening 190 where some of the components of the capacitor 100 are provided. In particular, since the conductive layer 120 has a function of one of the source electrode and the drain electrode of the transistor 200 and a function of the upper electrode of the capacitor 100, the transistor 200 and the capacitor 100 share some of the components. With such a structure, the transistor 200 and the capacitor 100 can be provided without a great increase in the occupation area in a plan view. Thus, the occupation area of the memory cell 150 can be reduced, so that the memory cells 150 can be arranged densely and the memory capacity of the memory device can be increased. In other words, the memory device can be highly integrated.

When the transistor 200 is provided above the capacitor 100, the transistor 200 is not affected by heat treatment in fabricating the capacitor 100. Thus, in the transistor 200, degradation of the electrical characteristics such as variation in threshold voltage or an increase in parasitic resistance, and an increase in variation in electrical characteristics due to the degradation of the electrical characteristics can be inhibited.

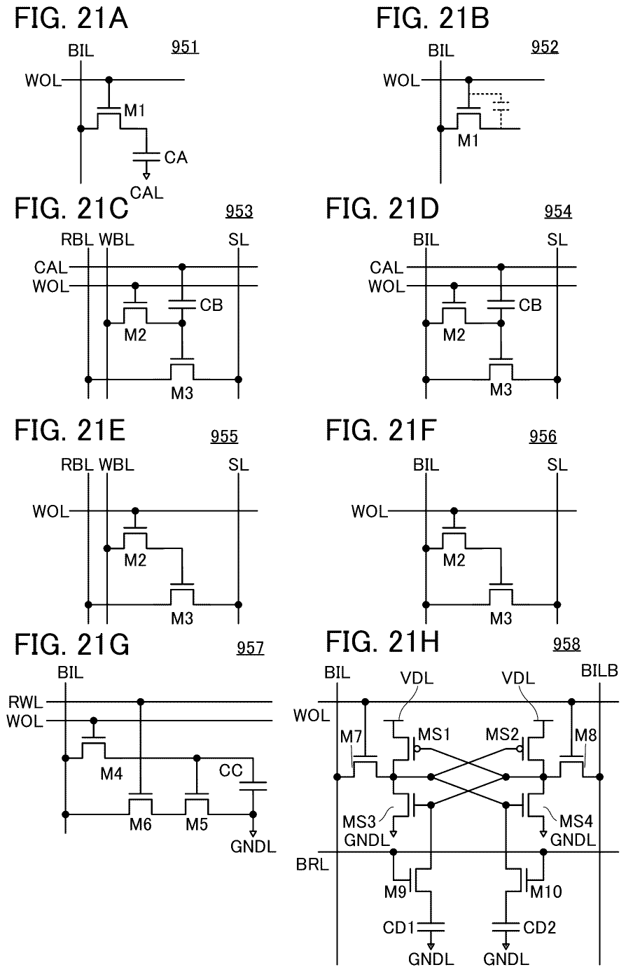

FIG. 21A illustrates a circuit diagram of the memory device described in this embodiment. As illustrated in FIG. 21A, the structure illustrated in FIG. 16A to FIG. 16C functions as a memory cell. A memory cell 951 includes a transistor M1 and a capacitor CA. In this case, the transistor M1 corresponds to the transistor 200 and the capacitor CA corresponds to the capacitor 100.

One of a source and a drain of the transistor M1 is electrically connected to one of a pair of electrodes of the capacitor CA. The other of the source and the drain of the transistor M1 is connected to a wiring BIL. A gate of the transistor M1 is connected to a wiring WOL. The other of the pair of electrodes of the capacitor CA is connected to a wiring CAL.

Here, the wiring BIL corresponds to the conductive layer 240, the wiring WOL corresponds to the conductive layer 260, and the wiring CAL corresponds to the conductive layer 110. As illustrated in FIG. 16A to FIG. 16C, it is preferable that the conductive layer 260 be provided to extend in the X direction and the conductive layer 240 be provided to extend in the Y direction. In this structure, the wiring BIL and the wiring WOL are provided to intersect with each other. Although the wiring CAL (the conductive layer 110) is provided in a planar shape in FIG. 16A, the present invention is not limited thereto. For example, the wiring CAL may be provided in parallel with the wiring WOL (the conductive layer 260) or may be provided in parallel with the wiring BIL (the conductive layer 240).

The memory cell will be described in detail in a later embodiment.

### [Capacitor 100]

The capacitor 100 includes the conductive layer 115, the insulating layer 130, and the conductive layer 120. The conductive layer 110 is provided below the conductive layer 115. The conductive layer 115 includes a region in contact with the conductive layer 110.

The conductive layer 110 is provided over the insulating layer 140. The conductive layer 110 functions as the wiring CAL, and can be provided in a planar shape, for example. The conductive layer 110 can be formed as a single layer or stacked layers using any of the conductive materials described in [Conductive layer] in Embodiment 1. For example, a conductive material with high conductivity such as tungsten can be used for the conductive layer 110. With the use of a conductive material with high conductivity, the conductive layer 110 can have improved conductivity and can function adequately as the wiring CAL.

A single layer or stacked-layer including a conductive material that is not easily oxidized, a conductive material having a function of inhibiting diffusion of oxygen, or the like is preferably used for the conductive layer 115. For example, titanium nitride, an indium tin oxide to which silicon is added, or the like may be used. For another example, a structure in which titanium nitride is stacked over tungsten may be employed. For another example, a structure in which tungsten is stacked over first titanium nitride and second titanium nitride is stacked over the tungsten may be employed. With such a structure, when an oxide is used for the insulating layer 130, oxidation of the conductive layer 110 due to the insulating layer 130 can be inhibited. Furthermore, when an oxide is used for the insulating layer 180, excessive oxidation of the conductive layer 110 due to the insulating layer 180 can be inhibited.

The insulating layer 130 is provided over the conductive layer 115. The insulating layer 130 is provided to be in contact with the top surface and a side surface of the conductive layer 115. That is, the insulating layer 130 preferably covers a side end portion of the conductive layer 115. This can prevent a short circuit between the conductive layer 115 and the conductive layer 120.

In addition, a structure may be employed in which a side end portion of the insulating layer 130 and a side end portion of the conductive layer 115 are substantially aligned with each other. This structure enables the insulating layer 130 and the conductive layer 115 to be formed using the same mask, so that the manufacturing process of the memory device can be simplified.

For the insulating layer 130, a material with a high relative permittivity (high-k material) is preferably used. Using such a high-k material for the insulating layer 130 allows the insulating layer 130 to be thick enough to inhibit leakage current and the capacitor 100 to have a sufficiently high capacitance.

It is preferable for the insulating layer 130 to use stacked insulating layers formed of high-k materials, and it is preferable to use a stacked-layer structure of a material with a high relative permittivity (high-k material) and a material having higher dielectric strength than the high-k material. For the insulating layer 130, an insulating film in which zirconium oxide, aluminum oxide, and zirconium oxide are stacked in this order can be used, for example. Alternatively, an insulating film in which zirconium oxide, aluminum oxide, zirconium oxide, and aluminum oxide are stacked in this order can be used, for example. Alternatively, an insulating film in which a hafnium zirconium oxide, aluminum oxide, a hafnium zirconium oxide, and aluminum oxide are stacked in this order can be used, for example. The use of stacked insulating layers with relatively high dielectric strength, such as aluminum oxide, can improve the dielectric strength and inhibit electrostatic breakdown of the capacitor 100.

Alternatively, a material that can have ferroelectricity may be used for the insulating layer 130. Description in Embodiment 1 can also be referred to for the details of the material that can have ferroelectricity.

A metal oxide containing one or both of hafnium and zirconium can have ferroelectricity even when in a form of a thin film of several nanometers and thus is preferably used for the insulating layer 130. The thickness of the insulating layer 130 is preferably less than or equal to 100 nm, further preferably less than or equal to 50 nm, still further preferably less than or equal to 20 nm, yet still further preferably less than or equal to 10 nm (typically, greater than or equal to 2 nm and less than or equal to 9 nm). The thickness is preferably greater than or equal to 8 nm and less than or equal to 12 nm, for example. When a ferroelectric layer that can be thinned is used, the capacitor 100 can be combined with a semiconductor element such as a miniaturized transistor to form a semiconductor device.

A metal oxide containing one or both of hafnium and zirconium can have ferroelectricity even with a minute area and thus is preferably used for the insulating layer 130. For example, a ferroelectric layer can have ferroelectricity even with an area (occupation area) in a plan view less than or equal to 100 μm², less than or equal to 10 μm², less than or equal to 1 μm², or less than or equal to 0.1 μm². Even with an area less than or equal to 10000 nm² or less than or equal to 1000 nm², a ferroelectric layer has ferroelectricity in some cases. With a small-area ferroelectric layer, the occupation area of the capacitor 100 can be reduced.

A ferroelectric is an insulator and has a property of causing internal polarization by application of an electric field from the outside and maintaining the polarization even after the electric field is made zero. Thus, with the use of a capacitor that uses this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor 100, the memory device described in this embodiment functions as a ferroelectric memory.

The conductive layer 120 is provided in contact with part of the top surface of the insulating layer 130. A side end portion of the conductive layer 120 is preferably positioned inward from the side end portion of the conductive layer 115 in both the X direction and the Y direction. In the structure where the insulating layer 130 covers the side end portion of the conductive layer 115, the side end portion of the conductive layer 120 may be positioned outward from the side end portion of the conductive layer 115.

The conductive layer 120 can be formed as a single layer or stacked layers using any of the conductive materials described in [Conductive layer] in Embodiment 1. A conductive material that is not easily oxidized, a conductive material having a function of inhibiting diffusion of oxygen, or the like is preferably used for the conductive layer 120. For example, titanium nitride, tantalum nitride, or the like can be used. For another example, a structure in which tantalum nitride is stacked over titanium nitride may be used. In that case, titanium nitride is in contact with the insulating layer 130 and tantalum nitride is in contact with the oxide semiconductor layer 230. This structure can inhibit excessive oxidation of the conductive layer 120 due to the oxide semiconductor layer 230. In the case where an oxide is used for the insulating layer 130, excessive oxidation of the conductive layer 120 due to the insulating layer 130 can be inhibited. Alternatively, a structure in which tungsten is stacked over titanium nitride may be employed for the conductive layer 120, for example.

The conductive layer 120 includes a region in contact with the oxide semiconductor layer 230 and thus is preferably formed using a conductive material containing oxygen. When a conductive material containing oxygen is used for the conductive layer 120, the conductive layer 120 can maintain its conductivity even after absorbing oxygen. This is suitable because the conductive layer 120 can maintain its conductivity also in the case where an insulating layer containing oxygen, e.g., zirconium oxide, is used for the insulating layer 130. As the conductive layer 120, a single layer or stacked layers of an ITO, an ITSO, an IZO (registered trademark), or the like can be used, for example.

The insulating layer 180 functions as an interlayer film and thus preferably has a low relative permittivity. When a material with a low relative permittivity is used for an interlayer film, parasitic capacitance generated between wirings can be reduced. As the insulating layer 180, a single layer or stacked layers including an insulating layer including a material with a low relative permittivity can be used. Silicon oxide and silicon oxynitride are preferable because they are thermally stable.

Although FIG. 16B and FIG. 16C illustrate the insulating layer 180 as a single layer, the present invention is not limited thereto. The insulating layer 180 may have a stacked-layer structure of two layers or a stacked-layer structure of three or more layers.

### Structure Example 2 of Memory Device

The memory cell 150 including the transistor 200 and the capacitor 100 described in this embodiment can be used as a memory cell of a memory device. The transistor 200 is a transistor in which a channel is formed in a semiconductor layer including an oxide semiconductor. Since the transistor 200 has a low off-state current, a memory device that uses the transistor 200 can retain stored contents for a long time. In other words, such a memory device does not require refresh operation or has extremely low frequency of the refresh operation, which leads to a sufficient reduction in power consumption of the memory device. The transistor 200 also has high frequency characteristics and thus enables high-speed reading and writing of the memory device.

The memory cells 150 can be arranged in a matrix three-dimensionally to form a memory cell array.

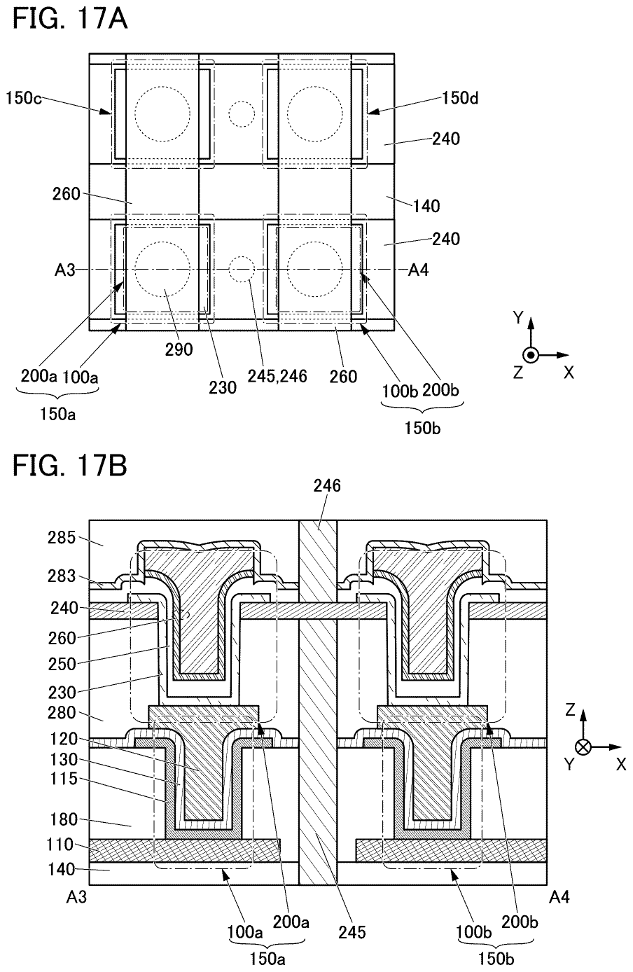

FIG. 17A is a plan view of a memory device. FIG. 17A illustrates an example in which 2×2 memory cells (a memory cell 150a to a memory cell 150d) are arranged in the X direction and the Y direction.

FIG. 17B is a cross-sectional view taken along dashed-dotted line A3-A4 in FIG. 17A. In FIG. 17A and FIG. 17B, two memory cells (the memory cell 150a and the memory cell 150b in FIG. 17B) are connected to a common wiring (a conductive layer 246).

Here, the memory cell 150a and the memory cell 150b illustrated in FIG. 17A and FIG. 17B each have a structure similar to that of the memory cell 150. The memory cell 150a includes a capacitor 100a and a transistor 200a, and the memory cell 150b includes a capacitor 100b and a transistor 200b. The memory cell 150c and the memory cell 150d illustrated in FIG. 17A each have a structure similar to that of the memory cell 150. Thus, in the memory device illustrated in FIG. 17A and FIG. 17B, components having the same functions as the components of the memory device illustrated in FIG. 10 are denoted by the same reference numerals. The description of the memory cell 150 in <Structure example 1 of memory device> can be referred to for the details of the memory cell 150a to the memory cell 150d.

As illustrated in FIG. 17A and FIG. 17B, the conductive layer 260 functioning as the wiring WOL is provided in each of the memory cell 150a and the memory cell 150b. As illustrated in FIG. 17A, one conductive layer 260 is provided to be shared by the memory cell 150a and the memory cell 150c, and another conductive layer 260 is provided to be shared by the memory cell 150b and the memory cell 150d. One conductive layer 240 functioning as part of the wiring BIL is provided to be shared by the memory cell 150a and the memory cell 150b. That is, the conductive layer 240 is in contact with the oxide semiconductor layer 230 of the memory cell 150a and the oxide semiconductor layer 230 of the memory cell 150b. Another conductive layer 240 is provided to be shared by the memory cell 150c and the memory cell 150d.

Here, the memory device illustrated in FIG. 17A and FIG. 17B includes a conductive layer 245 and the conductive layer 246 functioning as plugs (which also can be referred to as connection electrodes) electrically connected to the memory cell 150a and the memory cell 150b. The conductive layer 245 is placed in an opening formed in the insulating layer 140, the insulating layer 180, the insulating layer 130, and the insulating layer 280 and is in contact with the bottom surface of the conductive layer 240. The conductive layer 246 is placed in an opening formed in the insulating layer 285, the insulating layer 283, and the insulating layer 250 and is in contact with the top surface of the conductive layer 240. A conductive material or the like that can be used for the conductive layer 240 can be used for the conductive layer 245 and the conductive layer 246.

The insulating layer 285 functions as an interlayer film and thus preferably has a low relative permittivity. When a material with a low relative permittivity is used for an interlayer film, parasitic capacitance generated between wirings can be reduced.

The concentration of impurities such as water and hydrogen in the insulating layer 285 is preferably reduced. This can inhibit entry of impurities such as water and hydrogen into a channel formation region of the oxide semiconductor layer 230.

The conductive layer 245 and the conductive layer 246 function as plugs or wirings for electrically connecting the memory cell 150a and the memory cell 150b to a circuit element such as a switch, a transistor, a capacitor, an inductor, a resistor, or a diode, a wiring, an electrode, or a terminal. For example, a structure can be employed in which the conductive layer 245 is electrically connected to a sense amplifier (not illustrated) provided below the memory device illustrated in FIG. 17B, and the conductive layer 246 is electrically connected to a similar memory device (not illustrated) provided above the memory device illustrated in FIG. 17B. In that case, the conductive layer 245 and the conductive layer 246 function as part of the wiring BIL. When a memory device or the like is provided above or below the memory device illustrated in FIG. 17B in this manner, the memory capacity per unit area can be increased.

The memory cell 150a and the memory cell 150b are line-symmetrical to each other with a perpendicular bisector of the dashed-dotted line A3-A4 as the symmetric axis. Thus, the transistor 200a and the transistor 200b are also placed symmetrically with the conductive layer 245 and the conductive layer 246 therebetween. Here, the conductive layer 240 has a function of the other of a source electrode and a drain electrode of the transistor 200a and a function of the other of a source electrode and a drain electrode of the transistor 200b. The transistor 200a and the transistor 200b share the conductive layer 245 and the conductive layer 246 functioning as plugs. Accordingly, when two transistors and plugs are connected as described above, a memory device that can be miniaturized or highly integrated can be provided.

The conductive layer 110 functioning as the wiring CAL may be provided in each of the memory cell 150a and the memory cell 150b or may be provided to be shared by the memory cell 150a and the memory cell 150b. However, as illustrated in FIG. 17B, the conductive layer 110 is provided to be apart from the conductive layer 245 so that the conductive layer 110 and the conductive layer 245 are not short-circuited.

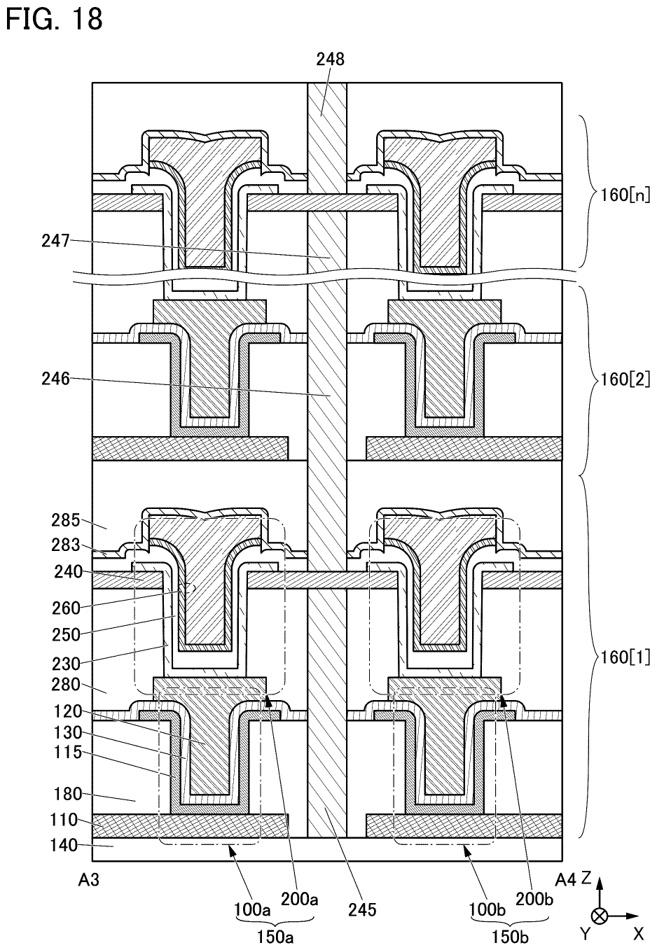

FIG. 18 illustrates an example in which the four memory cells illustrated in FIG. 17A are stacked in n layers (n is an integer greater than or equal to 3) in the Z direction. FIG. 18 is a cross-sectional view taken along dashed-dotted line A3-A4 in FIG. 17A.

A memory device illustrated in FIG. 18 includes n memory layers 160. Specifically, a memory layer 160[2] is provided over a memory layer 160[1], (n−2) memory layers are provided over the memory layer 160[2], and a memory layer 160[n] is provided at the highest stage. There is no particular limitation on the number of memory cells included in one memory layer 160, and two or more memory cells can be included. Through the conductive layer 245, the conductive layer 246, a conductive layer 247, a conductive layer 248, and the like, memory cells included in the n memory layers 160 are electrically connected to a sense amplifier (not illustrated) provided below the n memory layers 160.

When a plurality of memory cells are stacked as illustrated in FIG. 18, cells can be placed in an integrated manner without increasing the area occupied by a memory cell array. In other words, a 3D memory cell array can be formed.

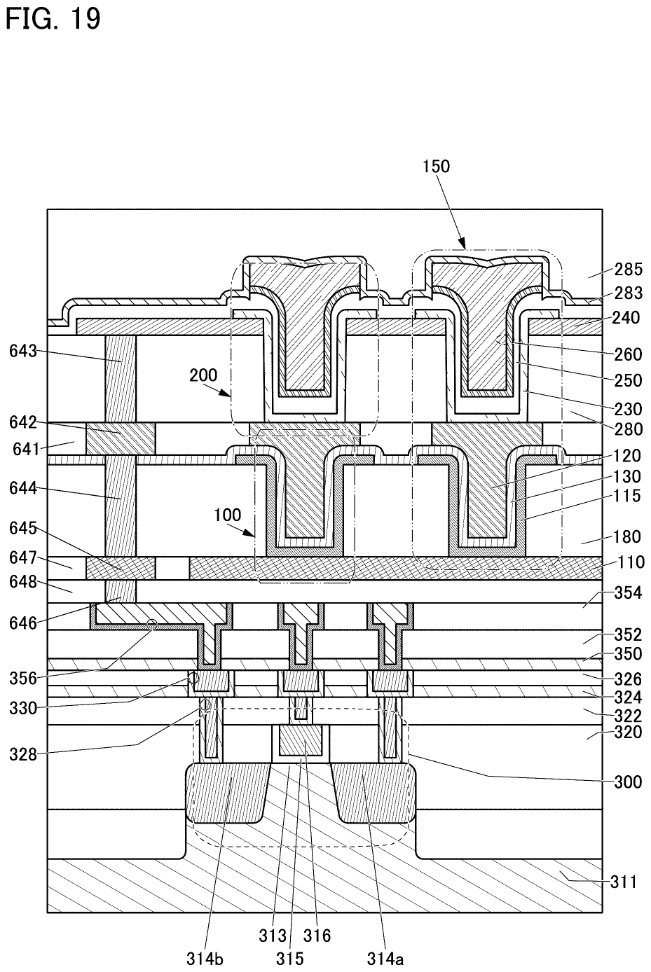

FIG. 19 illustrates a cross-sectional structure example of a memory device in which a layer including a memory cell is stacked over a layer provided with a driver circuit including a sense amplifier.

In FIG. 19, the memory cell 150 (the transistor 200 and the capacitor 100) is provided above a transistor 300.

The transistor 300 is one of transistors included in a sense amplifier.

The description of the memory cell 150 in <Structure example 1 of memory device> can be referred to for the memory cell 150 illustrated in FIG. 19.

When a structure in employed in which the sense amplifier is provided to overlap with the memory cell 150 as illustrated in FIG. 19, a bit line can be shortened. This reduces bit line capacitance, which can reduce the storage capacitance of the memory cell. Accordingly, the memory device can be driven at high speed.

The memory device illustrated in FIG. 19 can correspond to a semiconductor device 900 described in Embodiment 3. Specifically, the transistor 300 corresponds to a transistor included in a sense amplifier 927 in the semiconductor device 900. The memory cell 150 corresponds to a memory cell 950.

The transistor 300 is provided on a substrate 311 and includes a conductive layer 316 functioning as a gate, an insulating layer 315 functioning as a gate insulating layer, a semiconductor region 313 formed of part of the substrate 311, and a low-resistance region 314a and a low-resistance region 314b functioning as a source region and a drain region. The transistor 300 may be a p-channel transistor or an n-channel transistor.

Here, in the transistor 300 illustrated in FIG. 19, the semiconductor region 313 (part of the substrate 311) in which a channel is formed has a protruding shape. In addition, the conductive layer 316 is provided to cover a side surface and the top surface of the semiconductor region 313 with the insulating layer 315 therebetween. Note that a material for adjusting the work function may be used for the conductive layer 316. Such a transistor 300 is also referred to as a FIN-type transistor because it utilizes the protruding portion of the semiconductor substrate. An insulating layer functioning as a mask for forming the protruding portion may be provided in contact with an upper portion of the protruding portion. Although the case where the protruding portion is formed by processing part of the semiconductor substrate is described here, a semiconductor film having a protruding shape may be formed by processing an SOI substrate.

The transistor 300 illustrated in FIG. 19 is an example and the structure is not limited thereto; an appropriate transistor can be used in accordance with a circuit configuration or a driving method.

A wiring layer provided with an interlayer film, a wiring, a plug, and the like may be provided between the components. A plurality of wiring layers can be provided in accordance with the design. Here, a plurality of conductive layers functioning as plugs or wirings are collectively denoted by the same reference numeral in some cases. In this specification and the like, a wiring and a plug electrically connected to the wiring may be a single component. That is, part of a conductive layer functions as a wiring in some cases and part of the conductive layer functions as a plug in other cases.

Over the transistor 300, an insulating layer 320, an insulating layer 322, an insulating layer 324, and an insulating layer 326 are sequentially stacked as interlayer films, for example. A conductive layer 328 is embedded in the insulating layer 320 and the insulating layer 322, and a conductive layer 330 is embedded in the insulating layer 324 and the insulating layer 326. The conductive layer 328 and the conductive layer 330 function as a plug or a wiring.

The insulating layers functioning as interlayer films may also function as planarization films that cover uneven shapes therebelow. For example, the top surface of the insulating layer 322 may be planarized through planarization treatment using a CMP method or the like to increase the planarity.

A wiring layer may be provided over the insulating layer 326 and the conductive layer 330. For example, in FIG. 19, an insulating layer 350, an insulating layer 352, and an insulating layer 354 are stacked sequentially. Furthermore, a conductive layer 356 is formed in the insulating layer 350, the insulating layer 352, and the insulating layer 354. The conductive layer 356 functions as a plug or a wiring.

As each of the insulating layer 352, the insulating layer 354, and the like functioning as interlayer films, the above-described insulating layer that can be used for the semiconductor device or the memory device can be used.

For each of the conductive layers functioning as plugs or wirings, such as the conductive layer 328, the conductive layer 330, and the conductive layer 356, a conductive material that can be used for the conductive layer 240 can be used. It is preferable to use a high-melting-point material that has both heat resistance and conductivity, such as tungsten or molybdenum, and it is preferable to use tungsten. Alternatively, a low-resistance conductive material such as aluminum or copper is preferably used for formation. The use of a low-resistance conductive material can reduce wiring resistance.

The conductive layer 240 included in the transistor 200 is electrically connected to the low-resistance region 314b functioning as the source region or the drain region of the transistor 300 through a conductive layer 643, a conductive layer 642, a conductive layer 644, a conductive layer 645, a conductive layer 646, the conductive layer 356, the conductive layer 330, and the conductive layer 328.

The conductive layer 643 is embedded in the insulating layer 280. The conductive layer 642 is provided over the insulating layer 130 and is embedded in an insulating layer 641. The conductive layer 642 and the conductive layer 120 can be formed using the same material in the same step. The conductive layer 644 is embedded in the insulating layer 180 and the insulating layer 130. The conductive layer 645 is embedded in an insulating layer 647. The conductive layer 645 and the conductive layer 110 can be formed using the same material in the same step. The conductive layer 646 is embedded in an insulating layer 648. The transistor 300 and the conductive layer 110 are electrically insulated from each other by the insulating layer 648. As described above, the memory device of this embodiment includes a transistor with reduced parasitic capacitance, and thus can have a higher operation speed. In addition, since the memory device of this embodiment includes a capacitor and a transistor that overlap with each other, the area occupied by the memory cell in a plan view can be reduced and a memory device with a high degree of integration can be obtained.

This embodiment can be combined with the other embodiments as appropriate.

### Embodiment 3

The semiconductor device 900 of one embodiment of the present invention is described in this embodiment. The semiconductor device 900 can function as a memory device.

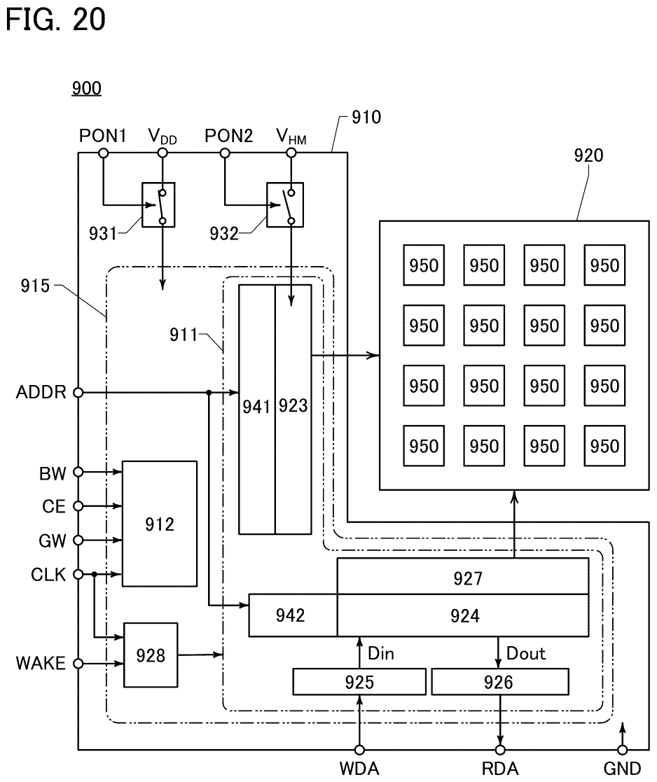

FIG. 20 illustrates a block diagram illustrating a structure example of the semiconductor device 900. The semiconductor device 900 illustrated in FIG. 20 includes a driver circuit 910 and a memory array 920. The memory array 920 includes at least one memory cell 950. FIG. 20 illustrates an example in which the memory array 920 includes a plurality of memory cells 950 arranged in a matrix.

The memory device (e.g., the memory cell 150) described in Embodiment 2 can be used for the memory cell 950.

The driver circuit 910 includes a PSW 931 (power switch), a PSW 932, and a peripheral circuit 915. The peripheral circuit 915 includes a peripheral circuit 911, a control circuit 912 (Control Circuit), and a voltage generation circuit 928.

In the semiconductor device 900, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are input signals from the outside, and a signal RDA is an output signal to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. The signal PON1 and the signal PON2 may be generated in the control circuit 912.

The control circuit 912 is a logic circuit having a function of controlling the overall operation of the semiconductor device 900. For example, the control circuit 912 performs logical operation on the signal CE, the signal GW, and the signal BW to determine an operation mode of the semiconductor device 900 (e.g., write operation or read operation). Alternatively, the control circuit 912 generates a control signal for the peripheral circuit 911 so that the operation mode is executed.

The voltage generation circuit 928 has a function of generating a negative voltage. The signal WAKE has a function of controlling the input of the signal CLK to the voltage generation circuit 928. For example, when an H-level signal is supplied as the signal WAKE, the signal CLK is input to the voltage generation circuit 928, and the voltage generation circuit 928 generates a negative voltage.

The peripheral circuit 911 is a circuit for performing writing and reading of data to/from the memory cell 950. The peripheral circuit 911 includes a row decoder 941 (Row decoder), a column decoder 942 (Column Decoder), a row driver 923 (Row driver), a column driver 924 (Column Driver), an input circuit 925 (Input Cir.), an output circuit 926 (Output Cir.), and the sense amplifier 927 (Sense Amplifier).

The row decoder 941 and the column decoder 942 have a function of decoding the signal ADDR. The row decoder 941 is a circuit for specifying a row to be accessed, and the column decoder 942 is a circuit for specifying a column to be accessed. The row driver 923 has a function of selecting the row specified by the row decoder 941. The column driver 924 has a function of writing data to the memory cell 950, a function of reading data from the memory cell 950, a function of retaining the read data, and the like.

The input circuit 925 has a function of retaining the signal WDA. Data retained by the input circuit 925 is output to the column driver 924. Data output from the input circuit 925 is data (Din) to be written to the memory cell 950. Data (Dout) read from the memory cell 950 by the column driver 924 is output to the output circuit 926. The output circuit 926 has a function of retaining Dout. In addition, the output circuit 926 has a function of outputting Dout to the outside of the semiconductor device 900. Data output from the output circuit 926 is the signal RDA.

The PSW 931 has a function of controlling supply of VDD to the peripheral circuit 915. The PSW 932 has a function of controlling supply of VHM to the row driver 923. Here, in the semiconductor device 900, a high power supply voltage is VDD and a low power supply voltage is GND (ground potential). In addition, VHM is a high power supply voltage used to set a word line at a high level and is higher than VDD. The on/off of the PSW 931 is controlled by the signal PON1, and the on/off of the PSW 932 is controlled by the signal PON2. The number of power domains to which VDD is supplied is one in the peripheral circuit 915 in FIG. 20 but can be more than one. In that case, a power switch may be provided for each power domain.

Configuration examples of a memory cell that can be used as the memory cell 950 are described with reference to FIG. 21A to FIG. 21H.

In the following description, the expression “two components are connected to each other” includes the case where the two components are electrically connected through a circuit element (a transistor, a switch, a diode, a resistor, or the like). Electrical connection means a possibility of a state where current flows between two components. Note that the case where two components are connected through a switch or a transistor is included as electrical connection because current might flow when the switch or the transistor is in an on state.

### [DOSRAM]

FIG. 21A illustrates a circuit configuration example of a memory cell of a DRAM. In this specification and the like, a DRAM including an OS transistor is referred to as a DOSRAM (Dynamic Oxide Semiconductor Random Access Memory). The memory cell 951 includes the transistor M1 and the capacitor CA.

The transistor M1 may include a front gate (simply referred to as a gate in some cases) and a back gate. In that case, the back gate may be connected to a wiring supplied with a constant potential or a signal, and the front gate and the back gate may be connected to each other.

A first terminal of the transistor M1 is connected to a first terminal of the capacitor CA, a second terminal of the transistor M1 is connected to the wiring BIL, and the gate of the transistor M1 is connected to the wiring WOL. A second terminal of the capacitor CA is connected to the wiring CAL.

The wiring BIL functions as a bit line, and the wiring WOL functions as a word line. The wiring CAL functions as a wiring for applying a predetermined potential to the second terminal of the capacitor CA. In data writing and reading, a low-level potential (referred to as a reference potential in some cases) is preferably applied to the wiring CAL.

Data writing and reading are performed in such a manner that a high-level potential is applied to the wiring WOL to bring the transistor M1 into an on state and establish electrical continuity between the wiring BIL and the first terminal of the capacitor CA (make a state where current can flow therebetween).

The memory cell that can be used as the memory cell 950 is not limited to the memory cell 951, and the circuit configuration can be changed. For example, a memory cell 952 illustrated in FIG. 21B may be used. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is indicated by a dashed line. Such a structure can greatly simplify the structure of the memory cell.

An OS transistor is preferably used as the transistor M1. An OS transistor has characteristics of having an extremely low off-state current. When an OS transistor is used as the transistor M1, the leakage current of the transistor M1 can be extremely low. That is, with the use of the transistor M1, written data can be retained for a long time, and thus the frequency of the refresh operation for the memory cell can be decreased. Alternatively, refresh operation for the memory cell can be unnecessary. In addition, the extremely low leakage current allows multi-level data or analog data to be retained in the memory cell 951 and the memory cell 952.

### [NOSRAM]

FIG. 21C illustrates a circuit configuration example of a gain-cell memory cell including two transistors and one capacitor. A memory cell 953 includes a transistor M2, a transistor M3, and a capacitor CB. In this specification and the like, a memory device including a gain memory cell including an OS transistor as the transistor M2 is referred to as a NOSRAM (Nonvolatile Oxide Semiconductor RAM).

A first terminal of the transistor M2 is connected to a first terminal of the capacitor CB, a second terminal of the transistor M2 is connected to a wiring WBL, and a gate of the transistor M2 is connected to the wiring WOL. A second terminal of the capacitor CB is connected to the wiring CAL. A first terminal of the transistor M3 is connected to a wiring RBL, a second terminal of the transistor M3 is connected to a wiring SL, and a gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In data writing, data retention, and data reading, a low-level potential (referred to as a reference potential in some cases) is preferably applied to the wiring CAL.

Data writing is performed in such a manner that a high-level potential is applied to the wiring WOL to bring the transistor M2 into an on state and establish electrical continuity between the wiring WBL and the first terminal of the capacitor CB. Specifically, when the transistor M2 is in an on state, a potential corresponding to information to be stored is applied to the wiring WBL, whereby the potential is written to the first terminal of the capacitor CB and the gate of the transistor M3. After that, a low-level potential is applied to the wiring WOL to bring the transistor M2 into an off state, whereby the potential of the first terminal of the capacitor CB and the potential of the gate of the transistor M3 are retained.

Data reading is performed by applying a predetermined potential to the wiring SL. The current flowing between a source and a drain of the transistor M3 and the potential of the first terminal of the transistor M3 are determined by the potential of the gate of the transistor M3 and the potential of the second terminal of the transistor M3; therefore, by reading the potential of the wiring RBL connected to the first terminal of the transistor M3, the potential retained in the first terminal of the capacitor CB (or the gate of the transistor M3) can be read. In other words, information written to the memory cell can be read on the basis of the potential retained in the first terminal of the capacitor CB (or the gate of the transistor M3).

Alternatively, for example, the wiring WBL and the wiring RBL may be combined into one wiring BIL. FIG. 21D illustrates a circuit configuration example of the memory cell. In a memory cell 954, one wiring BIL corresponds to the wiring WBL and the wiring RBL in the memory cell 953, and the second terminal of the transistor M2 and the first terminal of the transistor M3 are connected to the wiring BIL. In other words, the memory cell 954 has a structure in which one wiring BIL operates as a write bit line and a read bit line.

A memory cell 955 illustrated in FIG. 21E is an example in which the capacitor CB and the wiring CAL in the memory cell 953 are omitted. A memory cell 956 illustrated in FIG. 21F is an example in which the capacitor CB and the wiring CAL in the memory cell 954 are omitted. With such structures, the integration degree of the memory cells can be increased.

It is preferable to use an OS transistor as at least the transistor M2. It is particularly preferable to use OS transistors as the transistor M2 and the transistor M3.

Since an OS transistor has characteristics of an extremely low off-state current, written data can be retained for a long time by the transistor M2, and thus the frequency of refresh operation for the memory cell can be decreased. Alternatively, refresh operation for the memory cell can be unnecessary. In addition, the extremely low leakage current allows multi-level data or analog data to be retained in the memory cell 953, the memory cell 954, the memory cell 955, and the memory cell 956.

The memory cell 953, the memory cell 954, the memory cell 955, and the memory cell 956 each including an OS transistor as the transistor M2 are embodiments of a NOSRAM.

A Si transistor may be used as the transistor M3. A Si transistor can have high field-effect mobility and can be a p-channel transistor, so that circuit design flexibility can be increased.

In the case where an OS transistor is used as the transistor M3, the memory cell can be composed of a single-polarity circuit.

FIG. 21G illustrates a gain-cell memory cell 957 including three transistors and one capacitor. The memory cell 957 includes a transistor M4 to a transistor M6 and a capacitor CC.

A first terminal of the transistor M4 is connected to a first terminal of the capacitor CC, a second terminal of the transistor M4 is connected to the wiring BIL, and a gate of the transistor M4 is connected to the wiring WOL. A second terminal of the capacitor CC is connected to a first terminal of a transistor M5 and a wiring GNDL. A second terminal of the transistor M5 is connected to a first terminal of the transistor M6, and a gate of the transistor M5 is connected to the first terminal of the capacitor CC. A second terminal of the transistor M6 is connected to the wiring BIL, and a gate of the transistor M6 is connected to a wiring RWL.

The wiring BIL functions as a bit line, the wiring WOL functions as a write word line, and the wiring RWL functions as a read word line. The wiring GNDL is a wiring for applying a low-level potential.

Data writing is performed in such a manner that a high-level potential is applied to the wiring WOL to bring the transistor M4 into an on state and establish electrical continuity between the wiring BIL and the first terminal of the capacitor CC. Specifically, when the transistor M4 is in an on state, a potential corresponding to information to be stored is applied to the wiring BIL, whereby the potential is written to the first terminal of the capacitor CC and the gate of the transistor M5. After that, a low-level potential is applied to the wiring WOL to bring the transistor M4 into an off state, whereby the potential of the first terminal of the capacitor CC and the potential of the gate of the transistor M5 are retained.

Data reading is performed in such a manner that after a predetermined potential is precharged to the wiring BIL, the wiring BIL is made in an electrically floating state, and a high-level potential is applied to the wiring RWL. Since the wiring RWL has the high-level potential, the transistor M6 is brought into an on state, so that electrical continuity is established between the wiring BIL and the second terminal of the transistor M5. At this time, the potential of the wiring BIL is applied to the second terminal of the transistor M5; the potential of the second terminal of the transistor M5 and the potential of the wiring BIL are changed in accordance with the potential retained at the first terminal of the capacitor CC (or the gate of the transistor M5). Here, by reading the potential of the wiring BIL, the potential retained in the first terminal of the capacitor CC (or the gate of the transistor M5) can be read. In other words, information written to the memory cell can be read on the basis of the potential retained at the first terminal of the capacitor CC (or the gate of the transistor M5).

It is preferable to use an OS transistor as at least the transistor M4.

As the transistors M5 and M6, Si transistors may be used. As described above, a Si transistor has higher field-effect mobility than an OS transistor in some cases depending on the crystal state of silicon used in a semiconductor layer, for example.

In the case where OS transistors are used as the transistors M5 and M6, the memory cell can be composed of a single-polarity circuit.

### [OS-SRAM]

FIG. 21H illustrates an example of an SRAM (Static Random Access Memory) including an OS transistor. In this specification and the like, an SRAM including an OS transistor is referred to as an OS-SRAM (Oxide Semiconductor-SRAM). A memory cell 958 illustrated in FIG. 21H is a memory cell of an SRAM capable of backup.

The memory cell 958 includes a transistor M7 to a transistor M10, a transistor MS1 to a transistor MS4, a capacitor CD1, and a capacitor CD2. The transistor MS1 and the transistor MS2 are p-channel transistors, and the transistor MS3 and the transistor MS4 are n-channel transistors.

A first terminal of the transistor M7 is connected to the wiring BIL, and a second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB, and a second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is connected to a wiring VDL. A second terminal of the transistor MS2 is connected to the wiring VDL. A second terminal of the transistor MS3 is connected to the wiring GNDL. A second terminal of the transistor MS4 is connected to the wiring GNDL.

A second terminal of the transistor M9 is connected to a first terminal of the capacitor CD1, and a gate of the transistor M9 is connected to a wiring BRL. A second terminal of the transistor M10 is connected to a first terminal of the capacitor CD2, and a gate of the transistor M10 is connected to the wiring BRL.

A second terminal of the capacitor CD1 is connected to the wiring GNDL, and a second terminal of the capacitor CD2 is connected to the wiring GNDL.

The wiring BIL and the wiring BILB each function as a bit line, the wiring WOL functions as a word line, and the wiring BRL is a wiring for controlling on states and off states of the transistor M9 and the transistor M10.

The wiring VDL is a wiring for applying a high-level potential, and the wiring GNDL is a wiring for applying a low-level potential.

Data writing is performed by applying a high-level potential to the wiring WOL and applying a high-level potential to the wiring BRL. Specifically, when the transistor M10 is in an on state, a potential corresponding to information to be stored is applied to the wiring BIL, whereby the potential is written to the second terminal side of the transistor M10.

In the memory cell 958, an inverter loop is constructed by the transistor MS1 to the transistor MS2; thus, an inverted signal of a data signal corresponding to the potential is input to the second terminal side of the transistor M8. Since the transistor M8 is in an on state, an inverted signal of the potential applied to the wiring BIL, that is, the signal input to the wiring BIL is output to the wiring BILB. Since the transistor M9 and the transistor M10 are in on states, the potentials of the second terminal of the transistor M7 and the second terminal of the transistor M8 are retained in the first terminal of the capacitor CD2 and the first terminal of the capacitor CD1, respectively. After that, a low-level potential is applied to the wiring WOL and a low-level potential is applied to the wiring BRL to bring the transistor M7 to the transistor M10 into off states, whereby the potentials of the first terminal of the capacitor CD1 and the first terminal of the capacitor CD2 are retained.

Data reading is performed in the following manner: after the wiring BIL and the wiring BILB are precharged at a predetermined potential in advance, a high-level potential is applied to the wiring WOL and a high-level potential is applied to the wiring BRL, whereby the potential of the first terminal of the capacitor CD1 is refreshed by the inverter loop in the memory cell 958 and is output to the wiring BILB. Moreover, the potential of the first terminal of the capacitor CD2 is refreshed by the inverter loop in the memory cell 958 and is output to the wiring BIL. Since the potentials of the wiring BIL and the wiring BILB are changed from the precharged potentials to the potential of the first terminal of the capacitor CD2 and the potential of the first terminal of the capacitor CD1, the potential retained in the memory cell can be read on the basis of the potential of the wiring BIL or the wiring BILB.

OS transistors are preferably used as the transistor M7 to the transistor M10. Accordingly, written data can be retained for a long time by the transistor M7 to the transistor M10; thus, the frequency of refresh operation for the memory cell can be decreased. Alternatively, refresh operation for the memory cell can be unnecessary.

As the transistor MS1 to the transistor MS4, Si transistors may be used.

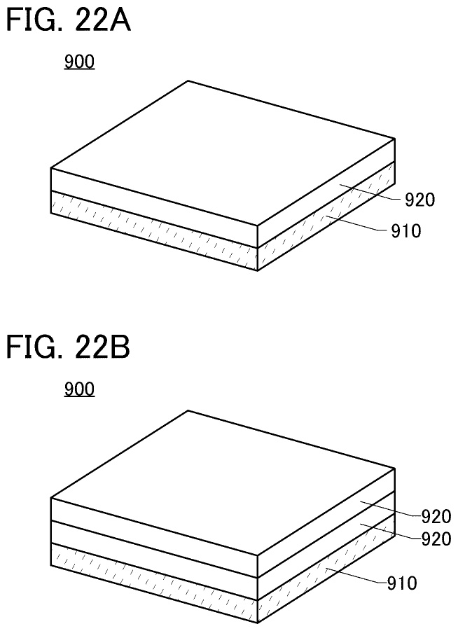

The driver circuit 910 and the memory array 920 that are included in the semiconductor device 900 may be provided on the same plane. As illustrated in FIG. 22A, the driver circuit 910 and the memory array 920 may be provided to overlap with each other. When the driver circuit 910 and the memory array 920 are provided to overlap with each other, the signal transmission distance can be shortened. Alternatively, a plurality of the memory arrays 920 may be provided over the driver circuit 910 as illustrated in FIG. 22B.

Next, an example of an arithmetic processing unit that can include a semiconductor device such as the memory device described above is described.

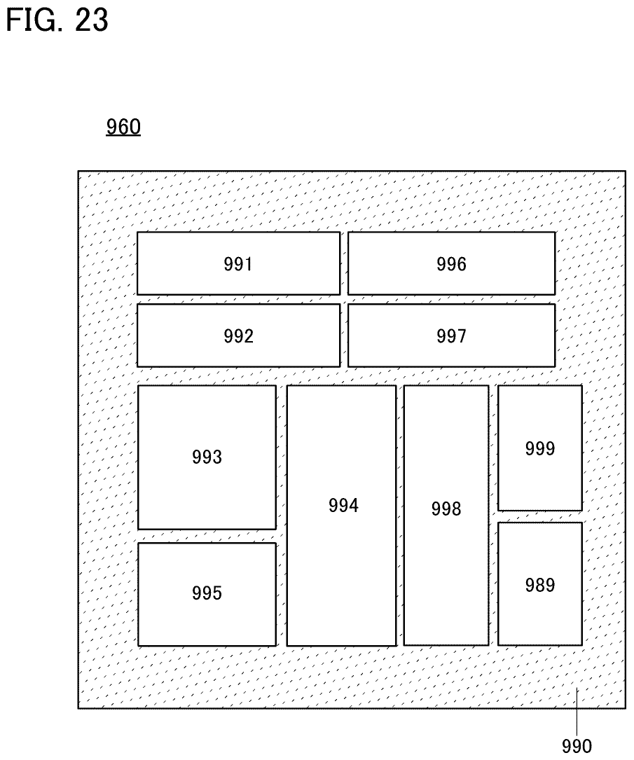

FIG. 23 illustrates a block diagram of an arithmetic unit 960. The arithmetic unit 960 illustrated in FIG. 23 can be used for a CPU (Central Processing Unit), for example. The arithmetic unit 960 can also be used for a processor including a larger number of (several tens to several hundreds of) processor cores capable of parallel processing than a CPU, such as a GPU (Graphics Processing Unit), a TPU (Tensor Processing Unit), or an NPU (Neural Processing Unit).

The arithmetic unit 960 illustrated in FIG. 23 includes, over a substrate 990, an ALU 991 (Arithmetic logic unit, arithmetic circuit), an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. A rewritable ROM and a ROM interface may be included. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 has a function of outputting part of data retained in the cache 999 to the ALU 991, the register 996, or the like via the bus interface 998.

As described later, the memory array 920 can be stacked over the arithmetic unit 960. The memory array 920 can be used as a cache. In that case, the cache interface 989 may have a function of supplying data retained in the memory array 920 to the cache 999. Moreover, in that case, the driver circuit 910 is preferably included in part of the cache interface 989.

It is also possible that the cache 999 is not provided and only the memory array 920 is used as a cache.

The arithmetic unit 960 illustrated in FIG. 23 is only an example with a simplified structure, and the actual arithmetic unit 960 has a variety of structures depending on the application. For example, what is called a multicore structure is preferably employed in which a plurality of cores each including the arithmetic unit 960 illustrated in FIG. 23 operate in parallel.

A larger number of cores can enhance the arithmetic performance. The number of cores is preferably as large as possible; for example, the number is preferably 2, further preferably 4, still further preferably 8, yet further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic unit 960 can process in an internal arithmetic circuit or in a data bus can be 8, 16, 32, or 64, for example.

An instruction that is input to the arithmetic unit 960 through the bus interface 998 is input to the instruction decoder 993 and decoded therein, and then, input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. While the arithmetic unit 960 is executing a program, the interrupt controller 994 judges an interrupt request from an external input/output device, a peripheral circuit, or the like on the basis of its priority or a mask state, and processes the request. The register controller 997 generates an address of the register 996, and reads/writes data from/to the register 996 in accordance with the state of the arithmetic unit 960.

The timing controller 995 generates signals for controlling operation timings of the ALU 991, the ALU controller 992, the instruction decoder 993, the interrupt controller 994, and the register controller 997. For example, the timing controller 995 includes an internal clock generating portion for generating an internal clock signal on the basis of a reference clock signal, and supplies the internal clock signal to the above various circuits.

In the arithmetic unit 960 illustrated in FIG. 23, the register controller 997 selects a retention operation in the register 996 in accordance with an instruction from the ALU 991. That is, the register controller 997 selects whether data is retained by a flip-flop or data is retained by a capacitor in the memory cell included in the register 996. When data retention by the flip-flop is selected, power supply voltage is supplied to the memory cell in the register 996. When data retention by the capacitor is selected, the data is rewritten in the capacitor, and supply of the power supply voltage to the memory cell in the register 996 can be stopped.

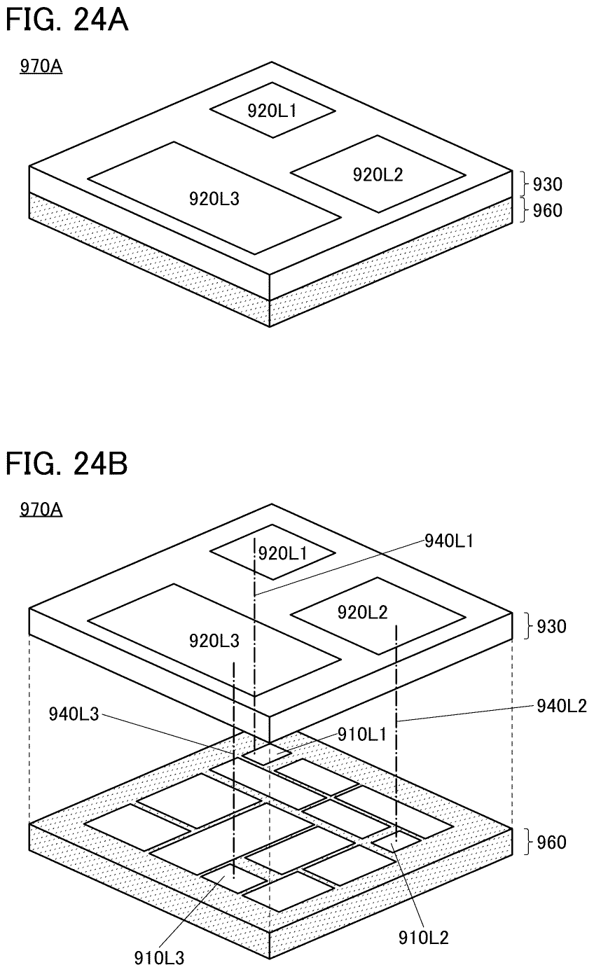

The memory array 920 and the arithmetic unit 960 can be provided to overlap with each other. FIG. 24A and FIG. 24B illustrate perspective views of a semiconductor device 970A. The semiconductor device 970A includes a layer 930 provided with memory arrays over the arithmetic unit 960. A memory array 920L1, a memory array 920L2, and a memory array 920L3 are provided in the layer 930. The arithmetic unit 960 and each of the memory arrays include overlap regions. For easy understanding of the structure of the semiconductor device 970A, the arithmetic unit 960 and the layer 930 are separately illustrated in FIG. 24B.

Providing the layer 930 including the memory arrays and the arithmetic unit 960 to overlap with each other can shorten the connection distance therebetween. Accordingly, the communication speed therebetween can be increased. Moreover, since the connection distance is short, power consumption can be reduced.

As a method for stacking the layer 930 including the memory arrays and the arithmetic unit 960, it is possible to employ a method in which the layer 930 including the memory arrays is stacked directly on the arithmetic unit 960 (also referred to as monolithic stacking); or a method in which the arithmetic unit 960 and the layer 930 are formed over different substrates, the two substrates are bonded to each other, and the arithmetic unit 960 and the layer 930 are electrically connected to each other using a through via or a technique for bonding conductive films (e.g., Cu—Cu bonding). The former method does not require consideration of misalignment in bonding; thus, not only the chip size but also the manufacturing cost can be reduced.

Here, it is possible that the arithmetic unit 960 does not include the cache 999 and the memory arrays 920L1, 920L2, and 920L3 provided in the layer 930 are each used as a cache. In that case, for example, the memory array 920L1 can be used as an L1 cache (also referred to as a level 1 cache), the memory array 920L2 can be used as an L2 cache (also referred to as a level 2 cache), and the memory array 920L3 can be used as an L3 cache (also referred to as a level 3 cache). Among the three memory arrays, the memory array 920L3 has the highest capacity and the lowest access frequency. The memory array 920L1 has the lowest capacity and the highest access frequency.

In the case where the cache 999 provided in the arithmetic unit 960 is used as the L1 cache, the memory arrays provided in the layer 930 can each be used as the lower-level cache or the main memory. The main memory has higher capacity and lower access frequency than the cache.

As illustrated in FIG. 24B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Although the case where three memory arrays function as caches is described here, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuit 910L2 and the driver circuit 910L3 may function as part of the cache interface 989 or be connected thereto.

Whether the memory array 920 functions as the cache or the main memory is determined by the control circuit 912 included in each of the driver circuits 910. The control circuit 912 can make some of the plurality of memory cells 950 included in the semiconductor device 900 function as RAMs in accordance with a signal supplied from the arithmetic unit 960.

In the semiconductor device 900, some of the plurality of memory cells 950 can function as the caches and the other memory cells 950 can function as the main memory. That is, the semiconductor device 900 can have both the function of the cache and the function of the main memory. The semiconductor device 900 of one embodiment of the present invention can function as a universal memory, for example.

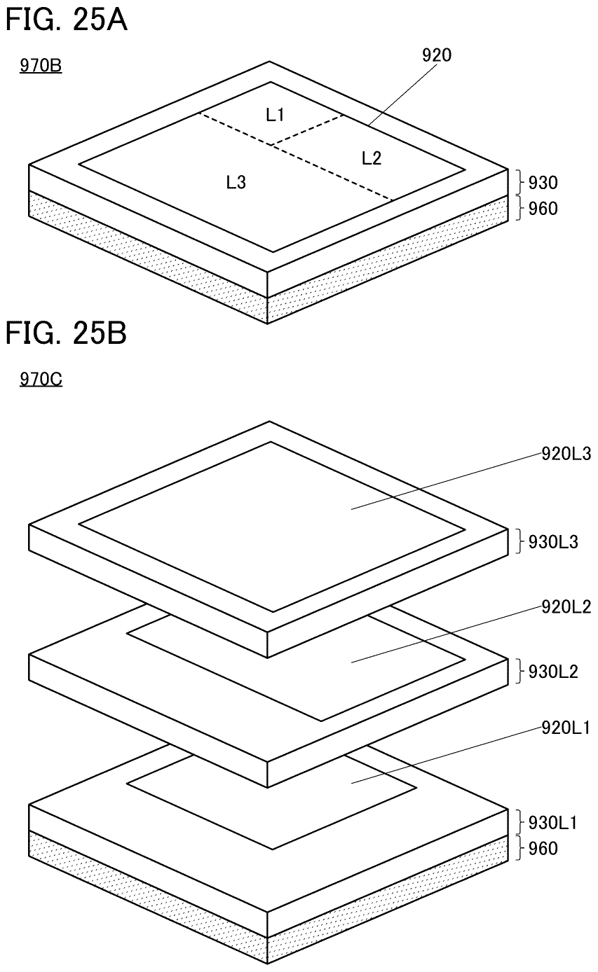

The layer 930 including one memory array 920 may be provided to overlap with the arithmetic unit 960. FIG. 25A illustrates a perspective view of a semiconductor device 970B.

In the semiconductor device 970B, one memory array 920 can be divided into a plurality of areas having different functions. FIG. 25A illustrates an example in which a region L1, a region L2, and a region L3 are used as the L1 cache, the L2 cache, and the L3 cache, respectively.

In the semiconductor device 970B, the capacity of each of the region L1 to the region L3 can be changed depending on circumstances. For example, the capacity of the L1 cache can be increased by increasing the area of the region L1. With such a structure, the arithmetic processing efficiency can be improved and the processing speed can be improved.

A plurality of memory arrays may be stacked. FIG. 25B illustrates a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic unit 960 can be used as a high-level cache, and the memory array 920L3 farthest from the arithmetic unit 960 can be used as a low-level cache or a main memory. Such a structure can increase the capacity of each memory array, thereby improving processing capability.

This embodiment can be combined with the other embodiments as appropriate.

### Embodiment 4

In this embodiment, application examples of the memory device of one embodiment of the present invention are described.

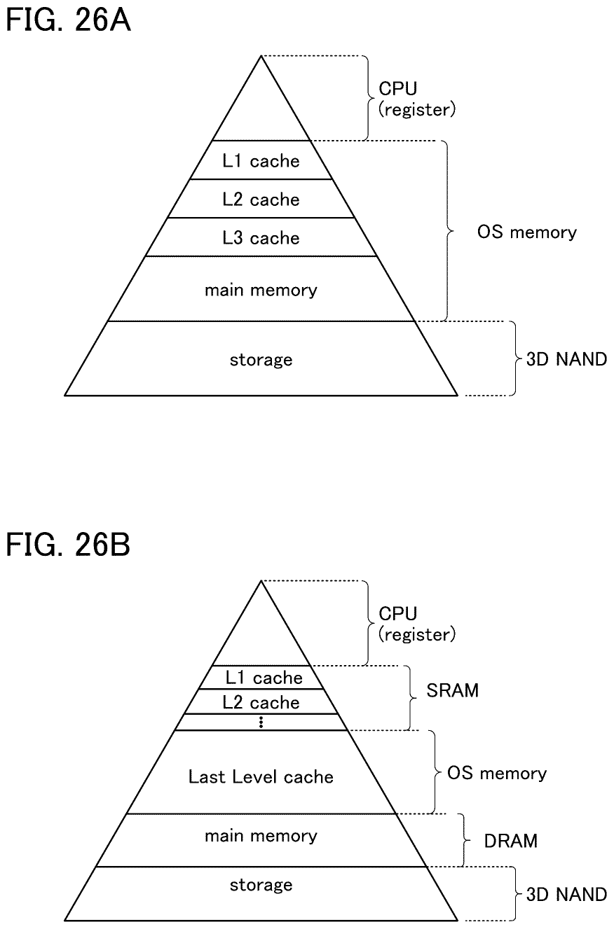

In general, a variety of memory devices are used in semiconductor devices such as computers in accordance with the intended use. FIG. 26A shows the hierarchy of various memory devices used in a semiconductor device. The memory devices at the upper levels require a higher operation speed, whereas the memory devices at the lower levels require a larger memory capacity and a higher storage density. In FIG. 26A, sequentially from the top level, a memory included as a register in an arithmetic processing unit such as a CPU, the L1 cache, the L2 cache, the L3 cache, a main memory, a storage, and the like are shown. Although an example including the caches up to the L3 cache is described here, a lower-level cache may further be included.

A memory included as a register in an arithmetic processing unit such as a CPU is used for temporary storage of arithmetic operation results, for example, and thus is frequently accessed by the arithmetic processing unit. Accordingly, a high operation speed is required rather than memory capacity. The register also has a function of retaining settings information of the arithmetic processing unit, for example.

The cache has a function of duplicating and retaining part of data retained in the main memory. Duplicating frequently used data and retaining the data in the cache facilitates rapid data access. The cache requires a smaller memory capacity than the main memory but a higher operation speed than the main memory. Data that is rewritten in the cache is duplicated and supplied to the main memory.

The main memory has a function of retaining a program, data, and the like that are read from the storage.

The storage has a function of retaining data that needs to be retained for a long time and a variety of programs used in an arithmetic processing unit, for example. Therefore, the storage requires a large memory capacity and a high storage density rather than operation speed. For example, a high-capacity nonvolatile memory device such as a 3D NAND can be used.

The memory device including an oxide semiconductor (the OS memory) of one embodiment of the present invention operates at high speed and can retain data for a long time. Thus, as illustrated in FIG. 26A, the memory device of one embodiment of the present invention can be suitably used at both the level where the cache is positioned and the level where the main memory is positioned. The memory device of one embodiment of the present invention can also be used at the level where the storage is positioned.

FIG. 26B illustrates an example in which an SRAM is used as some caches and the OS memory of one embodiment of the present invention is used as the other cache.

Among the caches, the lowest-level cache can be referred to as an LLC (Last Level cache). The LLC does not require a higher operating speed than a higher-level cache, but desirably has a large memory capacity. The OS memory of one embodiment of the present invention operates at high speed and can retain data for a long time, and thus can be suitably used as the LLC. The OS memory of one embodiment of the present invention can also be used as an FLC (Final Level cache).

As illustrated in FIG. 26B, for example, an SRAM can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 26B.

This embodiment can be combined with the other embodiments as appropriate.

### Embodiment 5

In this embodiment, a display apparatus of one embodiment of the present invention is described.

The semiconductor device of one embodiment of the present invention can be used for a display apparatus or a module including the display apparatus. Examples of the module including the display apparatus include a module in which a connector such as a flexible printed circuit board (hereinafter referred to as an FPC) or a TCP (Tape Carrier Package) is attached to the display apparatus and a module in which the display apparatus is mounted with an integrated circuit (IC) by a COG (Chip On Glass) method, a COF (Chip On Film) method, or the like.

The display apparatus in this embodiment may have a function of a touch panel. The display apparatus can employ any of a variety of sensing elements (also referred to as sensor elements) that can sense proximity or touch of a sensing target such as a finger, for example.

Examples of a sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The use of a mutual capacitive type is preferable because multiple points can be sensed simultaneously.

Examples of a touch panel include an out-cell touch panel, an on-cell touch panel, and an in-cell touch panel. Note that an in-cell touch panel has a structure in which an electrode included in a sensing element is provided on one or both of a substrate supporting a display element and a counter substrate.

### [Display Module]

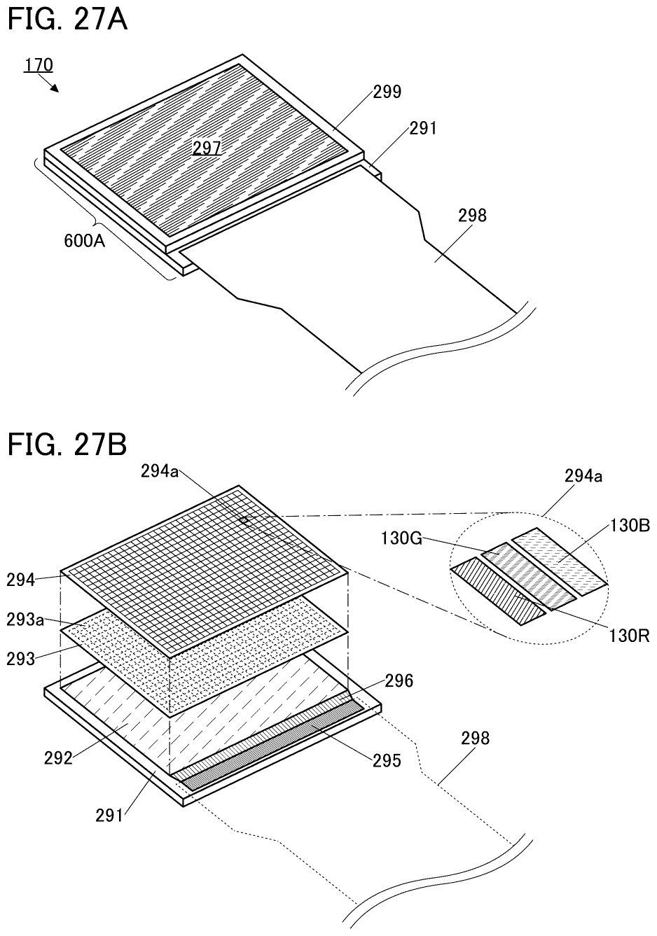

FIG. 27A illustrates a perspective view of a display module 170. The display module 170 includes a display apparatus 600A and an FPC 298. The display apparatus included in the display module 170 is not limited to the display apparatus 600A, and may be a display apparatus 600B described later.

The display module 170 includes a substrate 291 and a substrate 299. The display module 170 includes a display portion 297. The display portion 297 is a region of the display module 170 where an image is displayed, and is a region where light from pixels provided in a pixel portion 294 described later can be seen.

FIG. 27B illustrates a perspective view schematically illustrating a structure on the substrate 291 side. Over the substrate 291, a circuit portion 292, a pixel circuit portion 293 over the circuit portion 292, and the pixel portion 294 over the pixel circuit portion 293 are stacked. A terminal portion 295 to be connected to the FPC 298 is provided in a portion over the substrate 291 that does not overlap with the pixel portion 294. The terminal portion 295 and the circuit portion 292 are electrically connected to each other through a wiring portion 296 formed of a plurality of wirings.

The semiconductor device of one embodiment of the present invention can be used for one or both of the circuit portion 292 and the pixel circuit portion 293.

The pixel portion 294 includes a plurality of pixels 294a arranged periodically. An enlarged view of one pixel 294a is illustrated on the right side of FIG. 27B. FIG. 27B illustrates an example in which one pixel 294a includes a subpixel 130R emitting red light, a subpixel 130G emitting green light, and a subpixel 130B emitting blue light.

Each of the subpixels includes a display element. Any of a variety of elements can be used as the display element, and a liquid crystal element or a light-emitting element can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (Quantum-dot LED) employing a light source and color conversion technology using quantum dot materials may be used.

Examples of light-emitting elements include self-luminous type light-emitting elements such as an LED (Light Emitting Diode), an OLED (Organic LED), and a semiconductor laser. As the LED, for example, a mini LED, a micro LED, or the like can be used.

There is no particular limitation on the arrangement of the pixels in the display apparatus of this embodiment, and any of a variety of arrangements can be employed. Examples of the arrangement of the pixels include stripe arrangement, S-stripe arrangement, matrix arrangement, delta arrangement, Bayer arrangement, and PenTile arrangement. FIG. 27B illustrates an example in which stripe arrangement is employed as the arrangement of the pixels.

The pixel circuit portion 293 includes a plurality of pixel circuits 293a arranged periodically.

One pixel circuit 293a is a circuit that controls driving of a plurality of elements included in one pixel 294a. One pixel circuit 293a can be provided with three circuits each controlling light emission of one light-emitting element. For example, the pixel circuit 293a can include at least one selection transistor, one current control transistor (driving transistor), and a capacitor for one light-emitting element. In that case, a gate signal is input to a gate of the selection transistor, and a source signal is input to a source of the selection transistor. Thus, an active-matrix display apparatus is achieved.

The circuit portion 292 includes a circuit for driving the pixel circuits 293a in the pixel circuit portion 293. For example, one or both of a gate line driver circuit and a source line driver circuit are preferably included. In addition, at least one of an arithmetic circuit, a memory circuit, a power supply circuit, and the like may be included.

The FPC 298 functions as a wiring for supplying a video signal, a power supply potential, or the like to the circuit portion 292 from the outside. An IC may be mounted on the FPC 298.

The display module 170 can have a structure in which one or both of the pixel circuit portion 293 and the circuit portion 292 are provided to be stacked below the pixel portion 294; thus, the aperture ratio (effective display area ratio) of the display portion 297 can be significantly high. Furthermore, the pixels 294a can be arranged extremely densely, and thus, the display portion 297 can have extremely high resolution.

Such a display module 170 has extremely high resolution, and thus can be suitably used for a VR device such as an HMD or a glasses-type AR device. Even with a structure in which the display portion of the display module 170 is seen through a lens, for example, pixels of the extremely-high-resolution display portion 297 included in the display module 170 are prevented from being seen when the display portion is enlarged by the lens, so that display providing a high level of immersion can be performed. Without being limited thereto, the display module 170 can be suitably used for electronic appliances including relatively small display portions. For example, the display module 170 can be suitably used for a display portion of a wearable electronic appliance such as a wristwatch.

### Structure Example 1 of Display Apparatus

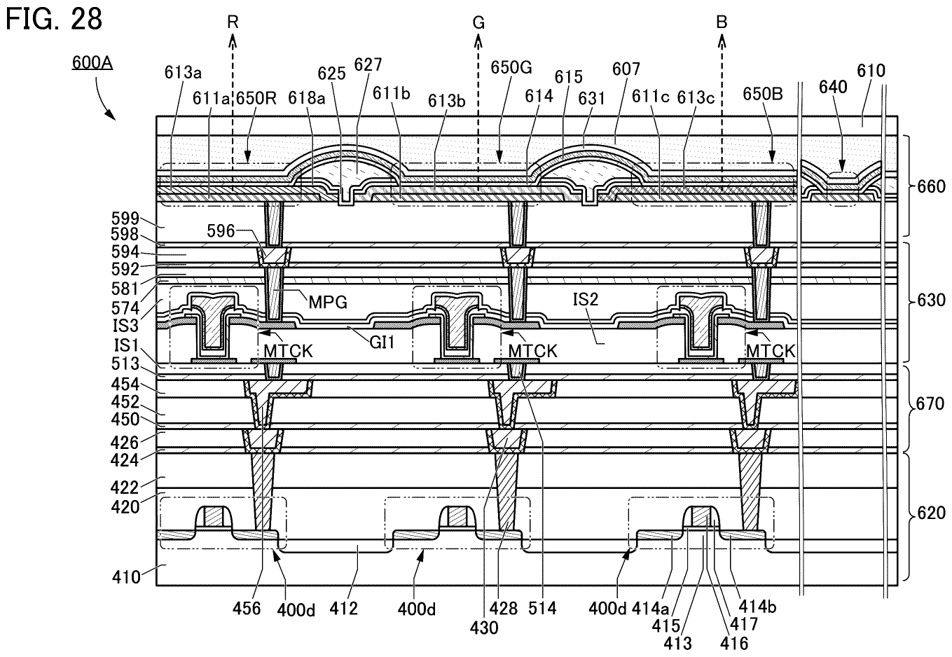

FIG. 28 illustrates a cross-sectional view of the display apparatus 600A. The display apparatus 600A is an example of a display apparatus having an MML (metal maskless) structure. In other words, the display apparatus 600A includes a light-emitting element that is formed without using a fine metal mask.

An island-shaped light-emitting layer of the light-emitting element included in the display apparatus having an MML structure is formed by forming a light-emitting layer on the entire surface and then processing the light-emitting layer by a photolithography method. Accordingly, a high-resolution display apparatus or a display apparatus with a high aperture ratio, which has been difficult to achieve, can be obtained. Moreover, light-emitting layers can be formed separately for the respective colors, enabling the display apparatus to perform extremely clear display with high contrast and high display quality. In the case where the display apparatus includes three kinds of light-emitting elements, which are a light-emitting element that emits blue light, a light-emitting element that emits green light, and a light-emitting element that emits red light, for example, three kinds of island-shaped light-emitting layers can be formed by repeating formation of a light-emitting layer and processing by photolithography three times.

A device having an MML structure can be manufactured without using a metal mask, and thus can break through the resolution limit due to alignment accuracy of the metal mask. Furthermore, manufacturing a device without using a metal mask can eliminate the need for the manufacturing facilities of a metal mask and a cleaning step of the metal mask. For the processing by photolithography, an apparatus that is the same as or similar to that used for manufacturing a transistor can be used; thus, there is no need to introduce a special apparatus to manufacture the device having an MML structure. An MML structure can reduce the manufacturing cost as described above, and thus is suitable for mass production of the device.

A display apparatus having an MML structure does not require a pseudo improvement in resolution by employing unique pixel arrangement such as PenTile arrangement; thus, the display apparatus can achieve high resolution (e.g., higher than or equal to 500 ppi, higher than or equal to 1000 ppi, higher than or equal to 2000 ppi, higher than or equal to 3000 ppi, or higher than or equal to 5000 ppi) while having what is called stripe arrangement where R, G, and B subpixels are arranged in one direction.

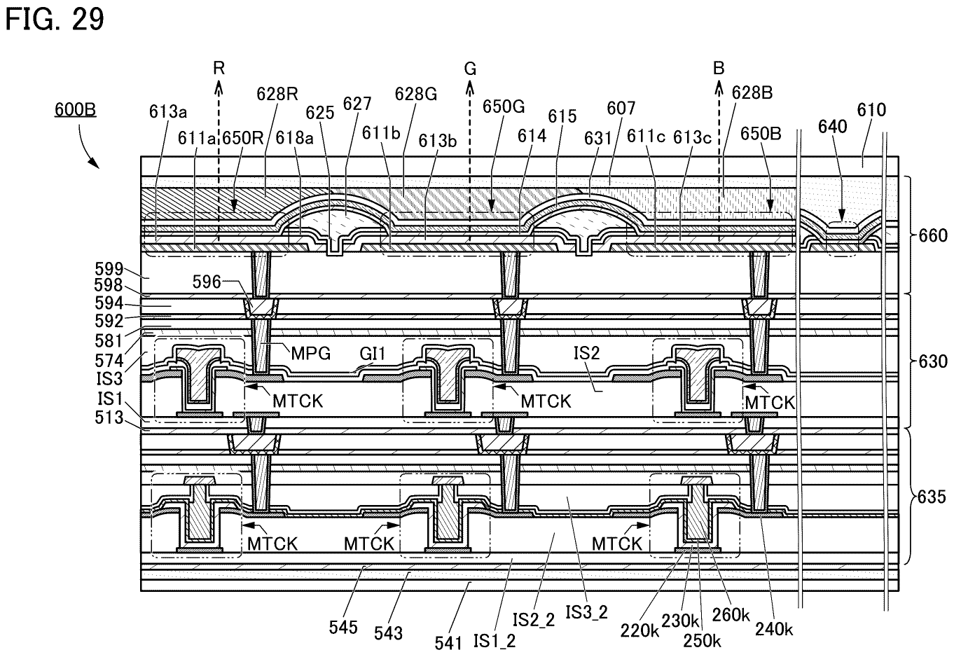

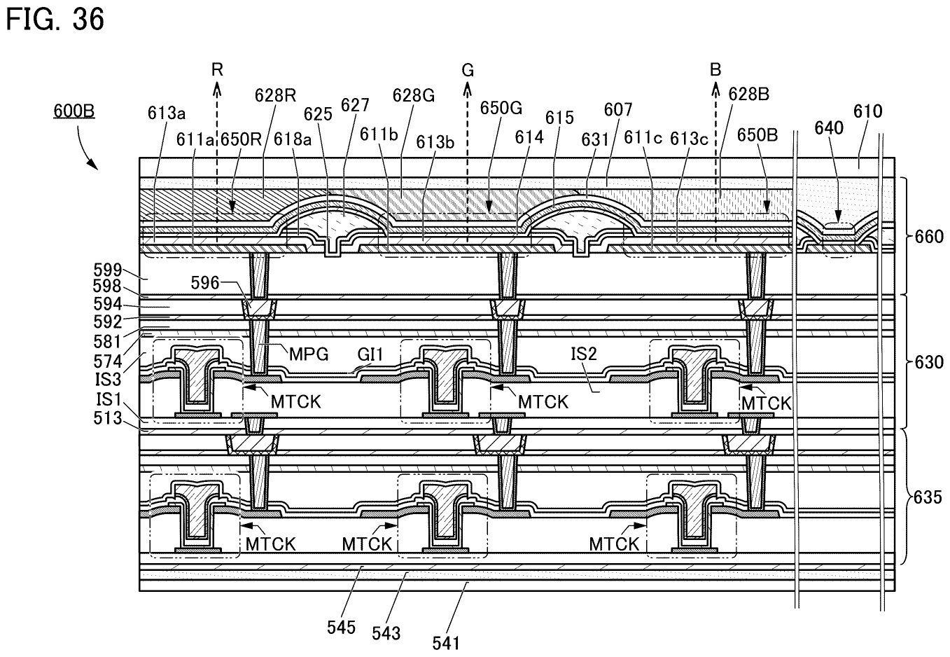

Providing a sacrificial layer over a light-emitting layer can reduce damage to the light-emitting layer in the manufacturing process of the display apparatus, resulting in an increase in reliability of the light-emitting element. Note that the sacrificial layer may remain in the completed display apparatus or may be removed in the manufacturing process. For example, a sacrificial layer 618a illustrated in each of FIG. 28, FIG. 29 described later, and FIG. 36 described later is part of the sacrificial layer provided over the light-emitting layer.

Furthermore, employing a film formation step using an area mask and a processing step using a resist mask enables a light-emitting element to be manufactured by a relatively easy process.

FIG. 28 is a schematic cross-sectional view of the display apparatus 600A that is the display apparatus (semiconductor device) of one embodiment of the present invention. The display apparatus 600A has a structure including a pixel circuit, a driver circuit, and the like provided over a substrate 410. In the display apparatus 600A in FIG. 28, a wiring layer 670 is illustrated in addition to an element layer 620, an element layer 630, and an element layer 660. The wiring layer 670 is a layer provided with a wiring.

A pixel circuit of the display apparatus is preferably provided in the element layer 630. A driver circuit (one or both of a gate driver and a source driver) of the display apparatus is preferably provided in the element layer 620. One or more of a variety of circuits such as an arithmetic circuit and a memory circuit may be provided in the element layer 620.

The element layer 620 includes the substrate 410, for example, and a transistor 400d is formed on the substrate 410. The wiring layer 670 is provided above the transistor 400d, and a wiring for electrically connecting the transistor 400d to a conductive layer, a transistor, or the like provided in the element layer 630 (a conductive layer 514 in FIG. 28) is provided in the wiring layer 670. The element layer 630 and the element layer 660 are provided above the wiring layer 670, and the element layer 630 includes a transistor MTCK and the like, for example. The element layer 660 includes a light-emitting element 650 (a light-emitting element 650R, a light-emitting element 650G, and a light-emitting element 650B in FIG. 28) and the like.

The transistor 400d is an example of a transistor included in the element layer 620. The transistor MTCK is an example of a transistor included in the element layer 630. The light-emitting element (the light-emitting element 650R, the light-emitting element 650G, and the light-emitting element 650B) is an example of a light-emitting element included in the element layer 660.

As the transistor MTCK, an OS transistor can be used, for example. FIG. 28 illustrates an example in which the transistor 200 described in the above embodiments is used as the transistor MTCK.

As the substrate 410, a semiconductor substrate (e.g., a single crystal substrate including silicon or germanium as a material) can be used, for example. Besides the semiconductor substrate, for example, an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film containing a fibrous material can be used as the substrate 410. In this embodiment, the substrate 410 is described as a semiconductor substrate including silicon as a material. Therefore, a transistor included in the element layer 620 can be a Si transistor.

The transistor 400d includes an element isolation layer 412, a conductive layer 416, an insulating layer 415, an insulating layer 417, a semiconductor region 413 that is part of the substrate 410, and a low-resistance region 414a and a low-resistance region 414b that function as a source region and a drain region. Thus, the transistor 400d is a Si transistor. Although FIG. 28 illustrates a structure in which one of a source and a drain of the transistor 400d is electrically connected to the conductive layer 514 provided in the element layer 630 through a conductive layer 428, a conductive layer 430, and a conductive layer 456, the electrical connection structure in the display apparatus of one embodiment of the present invention is not limited thereto.

The transistor 400d can have a Fin type structure when, for example, the top surface of the semiconductor region 413 and a side surface thereof in the channel width direction are covered with the conductive layer 416 with the insulating layer 415 functioning as a gate insulating layer therebetween. An effective channel width can be increased when the transistor 400d has a Fin type structure, so that the on-state characteristics of the transistor 400d can be improved. In addition, since contribution of an electric field of a gate electrode can be increased, the off-state characteristics of the transistor 400d can be improved. The transistor 400d may have a planar structure instead of a Fin-type structure.

The transistor 400d may be either a p-channel transistor or an n-channel transistor. Alternatively, a plurality of the transistors 400d may be provided and both the p-channel transistor and the n-channel transistor may be used.

A region of the semiconductor region 413 where a channel is formed, a region in the vicinity thereof, and the low-resistance region 414a and the low-resistance region 414b that function as the source region and the drain region preferably contain a silicon-based semiconductor, specifically, preferably contain single crystal silicon. Alternatively, each of the regions may be formed using germanium, silicon germanium, gallium arsenide, aluminum gallium arsenide, or gallium nitride, for example. A structure using silicon whose effective mass is controlled by applying stress to a crystal lattice and changing lattice spacing may be employed. Alternatively, the transistor 400d may be a HEMT (High Electron Mobility Transistor) including gallium arsenide and aluminum gallium arsenide, for example.

For the conductive layer 416 functioning as the gate electrode, a semiconductor material such as silicon including an element that imparts n-type conductivity, such as arsenic or phosphorus, or an element that imparts p-type conductivity, such as boron or aluminum, can be used. Alternatively, for the conductive layer 416, a conductive material such as a metal material, an alloy material, or a metal oxide material can be used, for example.

Since a work function depends on the material for the conductive layer, the threshold voltage of the transistor can be adjusted by selecting the material for the conductive layer. Specifically, it is preferable to use one or both of titanium nitride and tantalum nitride as the material for the conductive layer. Moreover, for both conductivity and embeddability, it is preferable to use stacked layers of metal materials of one or both of tungsten and aluminum as the conductive layer, and it is particularly preferable to use tungsten in terms of heat resistance.

The element isolation layer 412 is provided to separate a plurality of transistors formed on the substrate 410 from each other. The element isolation layer can be formed by, for example, a LOCOS (Local Oxidation of Silicon) method, an STI (Shallow Trench Isolation) method, or a mesa isolation method.

Over the transistor 400d illustrated in FIG. 28, an insulating layer 420 and an insulating layer 422 are sequentially stacked from the substrate 410 side.

For each of the insulating layer 420 and the insulating layer 422, one or more selected from silicon oxide, silicon oxynitride, silicon nitride oxide, silicon nitride, aluminum oxide, aluminum oxynitride, aluminum nitride oxide, and aluminum nitride can be used, for example.

The insulating layer 422 may have a function of a planarization film for eliminating a level difference caused by the transistor 400d and the like covered with the insulating layer 420 and the insulating layer 422. For example, the top surface of the insulating layer 422 may be planarized through planarization treatment using a CMP method or the like to increase the planarity.

The conductive layer 428 connected to the transistor MTCK and the like provided above the insulating layer 422 is embedded in the insulating layer 420 and the insulating layer 422. The conductive layer 428 has a function of a plug or a wiring.

In the display apparatus 600A, the wiring layer 670 is provided over the transistor 400d. The wiring layer 670 includes, for example, an insulating layer 424, an insulating layer 426, the conductive layer 430, an insulating layer 450, an insulating layer 452, an insulating layer 454, and the conductive layer 456.

Over the insulating layer 422 and the conductive layer 428, the insulating layer 424 and the insulating layer 426 are sequentially stacked. An opening is formed in the insulating layer 424 and the insulating layer 426 in a region overlapping with the conductive layer 428. The conductive layer 430 is embedded in the opening.

The insulating layer 450, the insulating layer 452, and the insulating layer 454 are sequentially stacked over the insulating layer 426 and the conductive layer 430. An opening is formed in the insulating layer 450, the insulating layer 452, and the insulating layer 454 in a region overlapping with the conductive layer 430. The conductive layer 456 is embedded in the opening. The conductive layer 430 and the conductive layer 456 have a function of a plug or a wiring that is connected to the transistor 400d.

Like an insulating layer 592 described later, for example, each of the insulating layer 424 and the insulating layer 450 is preferably formed using an insulating layer having a barrier property against one or more selected from hydrogen, oxygen, and water. Like an insulating layer 594 described later, each of the insulating layer 426, the insulating layer 452, and the insulating layer 454 is preferably formed using an insulating layer having a relatively low relative permittivity to reduce parasitic capacitance generated between wirings. Each of the insulating layer 426, the insulating layer 452, and the insulating layer 454 has functions of an interlayer insulating film and a planarization film.

The conductive layer 456 preferably includes a conductive layer having a barrier property against one or more selected from hydrogen, oxygen, and water.

For the insulating layer having a barrier property against hydrogen, tantalum nitride is preferably used, for example. Using a stack of tantalum nitride and tungsten, which has high conductivity, can inhibit diffusion of hydrogen from the transistor 400d while the conductivity of a wiring is kept. In that case, the tantalum nitride layer having a barrier property against hydrogen is preferably in contact with the insulating layer 450 having a barrier property against hydrogen.

An insulating layer 513 is provided above the insulating layer 454 and the conductive layer 456. An insulating layer IS1 is provided over the insulating layer 513. A conductive layer functioning as a plug or a wiring is embedded in the insulating layer IS1 and the insulating layer 513. Thus, the transistor 400d can be electrically connected to the conductive layer 514 provided in the element layer 630. Alternatively, one of a source and a drain of the transistor MTCK and one of the source and the drain of the transistor 400d may be electrically connected to each other.

The transistor MTCK and an insulating layer IS2 are provided over the insulating layer IS1. A semiconductor layer of the transistor MTCK, an insulating layer functioning as a gate insulating layer, a conductive layer functioning as a gate electrode, and the like are placed in an opening of the insulating layer IS2. An insulating layer IS3, an insulating layer 574, and an insulating layer 581 are stacked in this order over the transistor MTCK. A conductive layer MPG functioning as a plug or a wiring is embedded in the insulating layer IS3, the insulating layer 574, and the insulating layer 581.

The insulating layer 574 preferably has a function of inhibiting diffusion of impurities such as water and hydrogen (e.g., one or both of a hydrogen atom and a hydrogen molecule). In other words, the insulating layer 574 preferably functions as a barrier insulating film that inhibits entry of the impurities into the transistor MTCK. Moreover, the insulating layer 574 preferably has a function of inhibiting diffusion of oxygen (e.g., one or both of an oxygen atom and an oxygen molecule). For example, the insulating layer 574 preferably has a lower oxygen permeability than an insulating layer IS2 and the insulating layer IS3.

Thus, the insulating layer 574 preferably functions as a barrier insulating film that inhibits diffusion of impurities such as water and hydrogen. Accordingly, it is preferable to use, for the insulating layer 574, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the impurities are less likely to pass). Alternatively, it is preferable to use an insulating material having a function of inhibiting diffusion of oxygen (e.g., one or both of an oxygen atom and an oxygen molecule) (an insulating material through which the oxygen is less likely to pass).

For the insulating layer having a function of inhibiting passage of oxygen and impurities such as water and hydrogen, it is possible to use any of the materials that can be used for the insulating layer having a function of inhibiting passage of oxygen and impurities described as examples in Embodiment 1.

In particular, aluminum oxide or silicon nitride is preferably used for the insulating layer 574. Accordingly, it is possible to inhibit diffusion of impurities such as water and hydrogen into the transistor MTCK from above the insulating layer 574. Alternatively, it is possible to inhibit diffusion of oxygen included in the insulating layer IS3 or the like to above the insulating layer 574.

The insulating layer 581 is preferably a film functioning as an interlayer film and having a lower dielectric constant than the insulating layer 574. The use of a material with a low dielectric constant for the interlayer film can reduce parasitic capacitance between wirings. The relative permittivity of the insulating layer 581 is preferably lower than 4, further preferably lower than 3, for example. The relative permittivity of the insulating layer 581 is, for example, preferably 0.7 times or less, further preferably 0.6 times or less the relative permittivity of the insulating layer 574. When a material with a low dielectric constant is used for the insulating layer 581 functioning as an interlayer film, parasitic capacitance generated between wirings can be reduced.

The concentration of impurities such as water and hydrogen in the film of the insulating layer 581 is preferably reduced. In this case, for the insulating layer 581, silicon oxide, silicon oxynitride, silicon nitride oxide, or silicon nitride can be used, for example. Alternatively, for the insulating layer 581, silicon oxide to which fluorine is added, silicon oxide to which carbon is added, silicon oxide to which carbon and nitrogen are added, or porous silicon oxide can be used, for example. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Alternatively, for the insulating layer 581, a resin can be used. A material that can be used for the insulating layer 581 may be an appropriate combination of the above-described materials.

The insulating layer 592 and the insulating layer 594 are stacked in this order over the insulating layer 574 and the insulating layer 581.

For the insulating layer 592, it is preferable to use an insulating film having a barrier property (referred to as a barrier insulating film) which can prevent diffusion of impurities such as water and hydrogen from the substrate 410 or the transistor MTCK to a region above the insulating layer 592 (e.g., the region where the light-emitting element 650R, the light-emitting element 650G, the light-emitting element 650B, and the like are provided). Accordingly, for the insulating layer 592, it is preferable to use an insulating material that has a function of inhibiting diffusion of impurities such as a hydrogen atom, a hydrogen molecule, and a water molecule (an insulating material through which the above impurities are less likely to pass). Depending on the situation, it is preferable to use, for the insulating layer 592, an insulating material having a function of inhibiting diffusion of impurities such as a nitrogen atom, a nitrogen molecule, a nitrogen oxide molecule (e.g., N₂O, NO, or NO₂), and a copper atom (an insulating material through which the oxygen is less likely to pass). Alternatively, it is preferable that the insulating layer 592 have a function of inhibiting diffusion of oxygen (e.g., one or both of an oxygen atom and an oxygen molecule).

For the film having a barrier property against hydrogen, silicon nitride formed by a CVD method can be used, for example.

The amount of released hydrogen can be analyzed by thermal desorption spectroscopy (TDS), for example. The amount of hydrogen released from the insulating layer 424 that is converted into hydrogen atoms per area of the insulating layer 424 is less than or equal to 10×10¹⁵ atoms/cm², preferably less than or equal to 5×10¹⁵ atoms/cm², in the TDS analysis in a film-surface temperature range of 50° C. to 500° C., for example.

Like the insulating layer 581, the insulating layer 594 is preferably an interlayer film with a low dielectric constant. Thus, for the insulating layer 594, a material that can be used for the insulating layer 581 can be used.

The insulating layer 594 preferably has a lower dielectric constant than the insulating layer 592. The relative permittivity of the insulating layer 594 is preferably lower than 4, further preferably lower than 3, for example. The relative permittivity of the insulating layer 594 is, for example, preferably 0.7 times or less, further preferably 0.6 times or less the relative permittivity of the insulating layer 592. When a material with a low dielectric constant is used for the insulating layer 594 functioning as an interlayer film, parasitic capacitance generated between wirings can be reduced.

The conductive layer MPG functioning as a plug or a wiring is embedded in an insulating layer GI1 and the insulating layer IS3, and a conductive layer 596 functioning as a plug or a wiring is embedded in the insulating layer 592 and the insulating layer 594. In particular, the conductive layer MPG and the conductive layer 596 are electrically connected to the light-emitting element or the like provided above the insulating layer 594. A plurality of conductive layers functioning as plugs or wirings are collectively denoted by the same reference numeral in some cases. In this specification and the like, a wiring and a plug connected to the wiring may be a single component. That is, part of a conductive layer functions as a wiring in some cases and part of the conductive layer functions as a plug in other cases.

As a material for each of plugs and wirings (e.g., the conductive layer MPG, the conductive layer 428, the conductive layer 430, the conductive layer 456, the conductive layer 514, and the conductive layer 596), one or more conductive materials selected from a metal material, an alloy material, a metal nitride material, and a metal oxide material can be used as a single layer or stacked layers. It is preferable to use a high-melting-point material that has both heat resistance and conductivity, such as tungsten or molybdenum, and it is preferable to use tungsten. Alternatively, a low-resistance conductive material such as aluminum or copper is preferably used for formation. The use of a low-resistance conductive material can reduce wiring resistance.

An insulating layer 598 and an insulating layer 599 are sequentially formed over the insulating layer 594 and the conductive layer 596.

Like the insulating layer 592, for example, the insulating layer 598 is preferably formed using an insulating layer having a barrier property against one or more selected from hydrogen, oxygen, and water. Like the insulating layer 594, the insulating layer 599 is preferably formed using an insulating layer having relatively a low relative permittivity to reduce parasitic capacitance generated between wirings. The insulating layer 599 has functions of an interlayer insulating film and a planarization film.

The light-emitting element 650 and a connection portion 640 are formed over the insulating layer 599.

The connection portion 640 is referred to as a cathode contact portion in some cases, and is electrically connected to cathode electrodes of the light-emitting element 650R, the light-emitting element 650G, and the light-emitting element 650B. In the connection portion 640 illustrated in FIG. 28, a conductive layer formed using the same material in the same step as a conductive layer 611a to a conductive layer 611c is electrically connected to a common electrode 615 described later. Although FIG. 28 illustrates an example in which the conductive layer is electrically connected to the common electrode 615 through a common layer 614 described later, the conductive layer and the common electrode 615 may be in direct contact with each other.

The connection portion 640 may be provided to surround four sides of the display portion in a plan view, or may be provided in the display portion (e.g., between adjacent light-emitting elements 650) (not illustrated).

The light-emitting element 650R includes the conductive layer 611a as a pixel electrode. Similarly, the light-emitting element 650G includes the conductive layer 611b as a pixel electrode, and the light-emitting element 650B includes the conductive layer 611c as a pixel electrode. Each of the conductive layer 611a, the conductive layer 611b, and the conductive layer 611c is connected to the conductive layer 596 embedded in the insulating layer 594 through a conductive layer (plug) embedded in the insulating layer 599.

The light-emitting element 650R includes a layer 613a, the common layer 614 over the layer 613a, and the common electrode 615 over the common layer 614. The light-emitting element 650G includes a layer 613b, the common layer 614 over the layer 613b, and the common electrode 615 over the common layer 614. The light-emitting element 650B includes a layer 613c, the common layer 614 over the layer 613c, and the common electrode 615 over the common layer 614.

As materials for a pair of electrodes (the pixel electrode and the common electrode) of the light-emitting element, a metal, an alloy, an electrically conductive compound, a mixture thereof, and the like can be used as appropriate. Specific examples of the materials include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the materials include an indium tin oxide (an In—Sn oxide, also referred to as an ITO), an In—Si—Sn oxide (also referred to as an ITSO), an indium zinc oxide (an In—Zn oxide), and an In—W—Zn oxide. Other examples of the materials include an alloy containing aluminum (aluminum alloy), such as an alloy of aluminum, nickel, and lanthanum (Al—Ni—La); and an alloy containing silver, such as an alloy of silver and magnesium and an alloy of silver, palladium, and copper (Ag—Pd—Cu, also referred to as APC). Other examples of the materials include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The display apparatus 600A employs an SBS structure. The SBS structure can optimize materials and structures of light-emitting elements and thus can extend freedom of choice of materials and structures, whereby the luminance and the reliability can be easily improved.

The display apparatus 600A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

The layer 613a is formed to cover the top surface and a side surface of the conductive layer 611a. Similarly, the layer 613b is formed to cover the top surface and a side surface of the conductive layer 611b. Similarly, the layer 613c is formed to cover the top surface and a side surface of the conductive layer 611c. Accordingly, regions provided with the conductive layer 611a, the conductive layer 611b, and the conductive layer 611c can be entirely used as the light-emitting regions of the light-emitting element 650R, the light-emitting element 650G, and the light-emitting element 650B, increasing the aperture ratio of the pixels.

In the light-emitting element 650R, the layer 613a and the common layer 614 can be collectively referred to as an EL layer. Similarly, in the light-emitting element 650G, the layer 613b and the common layer 614 can be collectively referred to as an EL layer. Similarly, in the light-emitting element 650B, the layer 613c and the common layer 614 can be collectively referred to as an EL layer.

The EL layer includes at least a light-emitting layer. The light-emitting layer includes one or more kinds of light-emitting substances. As the light-emitting substance, a substance emitting light of emission color of blue, violet, bluish violet, green, yellowish green, yellow, orange, red, or the like is appropriately used. Alternatively, as the light-emitting substance, a substance that emits near-infrared light can be used.

Examples of the light-emitting substance included in the light-emitting element include a substance that emits fluorescent light (a fluorescent material), a substance that emits phosphorescent light (a phosphorescent material), a substance that exhibits thermally activated delayed fluorescence (a TADF material), and an inorganic compound (e.g., a quantum dot material).

The light-emitting layer may include one or more kinds of organic compounds (e.g., a host material or an assist material) in addition to the light-emitting substance (a guest material). As one or more kinds of organic compounds, one or both of a substance having a high hole-transport property (a hole-transport material) and a substance having a high electron-transport property (an electron-transport material) can be used. As one or more kinds of organic compounds, a substance having a bipolar property (a substance having a high electron-transport property and a high hole-transport property) or a TADF material may be used.

In addition to the light-emitting layer, the EL layer can include one or more of a layer including a substance having a high hole-injection property (a hole-injection layer), a layer including a hole-transport material (a hole-transport layer), a layer including a substance having a high electron-blocking property (an electron-blocking layer), a layer including a substance having a high electron-injection property (an electron-injection layer), a layer including an electron-transport material (an electron-transport layer), and a layer including a substance having a high hole-blocking property (a hole-blocking layer). The EL layer may further include one or both of a substance having a bipolar property and a TADF material.

Either a low molecular compound or a high molecular compound can be used in the light-emitting element, and an inorganic compound may also be included. Each layer included in the light-emitting element can be formed by an evaporation method (including a vacuum evaporation method), a transfer method, a printing method, an inkjet method, a coating method, or the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when voltage is applied between a pair of electrodes. A tandem structure enables a light-emitting element capable of emitting light with high luminance. Furthermore, the amount of current needed for obtaining a predetermined luminance can be smaller in a tandem structure than in a single structure; thus, a tandem structure enables higher reliability. A tandem structure may also be referred to as a stack structure.

When the light-emitting element has a microcavity structure, higher color purity can be achieved.

The layer 613a, the layer 613b, and the layer 613c are each processed into an island shape by a photolithography method. Thus, at each of end portions of the layer 613a, the layer 613b, and the layer 613c, an angle between the top surface and the side surface is approximately 90°. By contrast, for example, an organic film formed using an FMM (Fine Metal Mask) has a thickness that tends to gradually decrease with decreasing distance to an end portion, and has a top surface forming a slope in an area extending greater than or equal to 1 μm and less than or equal to 10 μm to the end portion, for example; thus, such an organic film has a shape whose top surface and side surface cannot be easily distinguished from each other.

The top surface and the side surface of each of the layer 613a, the layer 613b, and the layer 613c are clearly distinguished from one another. Accordingly, regarding the layer 613a and the layer 613b which are adjacent to each other, one of the side surfaces of the layer 613a and one of the side surfaces of the layer 613b are placed to face each other. This applies to a combination of any of the layer 613a, the layer 613b, and the layer 613c.

The layer 613a, the layer 613b, and the layer 613c each include at least a light-emitting layer. For example, a structure is preferably employed in which the layer 613a includes a light-emitting layer that emits red light, the layer 613b includes a light-emitting layer that emits green light, and the layer 613c includes a light-emitting layer that emits blue light. Other than the above colors, cyan, magenta, yellow, or white can be employed for the light-emitting layers.

The layer 613a, the layer 613b, and the layer 613c each preferably include a light-emitting layer and a carrier-transport layer (an electron-transport layer or a hole-transport layer) over the light-emitting layer. Since each of the surfaces of the layer 613a, the layer 613b, and the layer 613c is exposed in the manufacturing process of the display apparatus in some cases, providing the carrier-transport layer over the light-emitting layer inhibits the light-emitting layer from being exposed on the outermost surface, so that damage to the light-emitting layer can be reduced. Thus, the reliability of the light-emitting element can be increased.

The common layer 614 includes, for example, an electron-injection layer or a hole-injection layer. Alternatively, the common layer 614 may include a stack of an electron-transport layer and an electron-injection layer, or may include a stack of a hole-transport layer and a hole-injection layer. The common layer 614 is shared by the light-emitting element 650R, the light-emitting element 650G, and the light-emitting element 650B. The common layer 614 is not necessarily provided, and the whole EL layer included in the light-emitting element may be provided in an island shape like the layer 613a, the layer 613b, and the layer 613c.

The common electrode 615 is shared by the light-emitting element 650R, the light-emitting element 650G, and the light-emitting element 650B. As illustrated in FIG. 28, the common electrode 615 shared by the plurality of light-emitting elements is electrically connected to a conductive layer included in the connection portion 640.

An insulating layer 625 preferably has a function of a barrier insulating layer against one or both of water and oxygen. The insulating layer 625 preferably has a function of inhibiting diffusion of one or both of water and oxygen. The insulating layer 625 preferably has a function of capturing or fixing (also referred to as gettering) one or both of water and oxygen. When the insulating layer 625 has a function of a barrier insulating layer or a gettering function, entry of impurities (typified by one or both of water and oxygen) that would be diffused into the light-emitting elements from the outside can be inhibited. With such a structure, a highly reliable light-emitting element and a highly reliable display apparatus can be provided.

The insulating layer 625 preferably has a low impurity concentration. Accordingly, degradation of the EL layer, which is caused by entry of impurities into the EL layer from the insulating layer 625, can be inhibited. In addition, when the impurity concentration is reduced in the insulating layer 625, a barrier property against one or both of water and oxygen can be increased. For example, it is desirable that one of the hydrogen concentration and the carbon concentration, preferably both, in the insulating layer 625 be sufficiently low.

As an insulating layer 627, an insulating layer including an organic material can be suitably used. As the organic material, a photosensitive organic resin is preferably used; for example, a photosensitive resin composition containing an acrylic resin is preferably used. In this specification and the like, an acrylic resin refers to not only a polymethacrylic acid ester or a methacrylic resin, but also all the acrylic polymer in a broad sense in some cases.

The organic material that can be used for the insulating layer 627 is not limited to the above. For the insulating layer 627, an acrylic resin, a polyimide resin, an epoxy resin, a polyamide resin, a polyimide-amide resin, a silicone resin, a siloxane resin, a benzocyclobutene-based resin, a phenol resin, or a precursor of any of these resins can be used in some cases, for example. Alternatively, an organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be used for the insulating layer 627 in some cases. For the insulating layer 627, for example, a photoresist can be used as the photosensitive resin in some cases. As the photosensitive resin, a positive material or a negative material is given.

The insulating layer 627 may be formed using a material absorbing visible light. When the insulating layer 627 absorbs light emitted from the light-emitting element, light leakage (stray light) from the light-emitting element to the adjacent light-emitting element through the insulating layer 627 can be inhibited. Thus, the display quality of the display apparatus can be improved. Since no polarizing plate is required to improve the display quality of the display apparatus, the weight and thickness of the display apparatus can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two or three or more colors is particularly preferable to enhance the effect of blocking visible light. In particular, mixing color filter materials of three or more colors enables the formation of a black or nearly black resin layer.

The insulating layer 627 can be formed by a wet film formation method such as spin coating, dipping, spray coating, inkjetting, dispensing, screen printing, offset printing, doctor blade coating, slit coating, roll coating, curtain coating, or knife coating, for example. It is particularly preferable to form an organic insulating film to be the insulating layer 627 by spin coating.

The insulating layer 627 is formed at a temperature lower than the heat resistance temperature of the EL layer. The typical substrate temperature in formation of the insulating layer 627 is lower than or equal to 200° C., preferably lower than or equal to 180° C., further preferably lower than or equal to 160° C., still further preferably lower than or equal to 150° C., yet still further preferably lower than or equal to 140° C.

The insulating layer 627 preferably has a tapered side surface. Such a forward tapered shape (less than 90°, preferably less than or equal to 60°, further preferably less than or equal to) 45° of an end portion of the side surface of the insulating layer 627 can prevent step disconnection, local thinning, or the like from occurring in the common layer 614 and the common electrode 615 which are provided over the end portion of the side surface of the insulating layer 627, leading to film formation with good coverage. Accordingly, the in-plane uniformity of the common layer 614 and the common electrode 615 can be improved, leading to higher display quality of the display apparatus.

The top surface of the insulating layer 627 preferably has a convex curved shape in a cross-sectional view of the display apparatus. The top surface of the insulating layer 627 preferably has a convex curved shape that bulges gradually toward the center. When the insulating layer 627 has such a shape, the common layer 614 and the common electrode 615 can be formed with good coverage over the entire insulating layer 627.

The insulating layer 627 is formed in a region between two EL layers (e.g., a region between the layer 613a and the layer 613b). At this time, part of the insulating layer 627 is placed at a position sandwiched between an end portion of a side surface of one of the EL layers (e.g., the layer 613a) and an end portion of a side surface of the other of the EL layers (e.g., the layer 613b).

One end portion of the insulating layer 627 preferably overlaps with the conductive layer 611a functioning as a pixel electrode, and the other end portion of the insulating layer 627 preferably overlaps with the conductive layer 611b functioning as a pixel electrode. Such a structure enables the end portion of the insulating layer 627 to be formed over flat or substantially flat region in the layer 613a (the layer 613b). This makes it relatively easy to process the tapered shape of the insulating layer 627 as described above.

By providing the insulating layer 627 and the like in the above manner, a step disconnection portion and a locally thinned portion can be prevented from being formed in the common layer 614 and the common electrode 615 from a flat or substantially flat region in the layer 613a to a flat or substantially flat region in the layer 613b. Thus, between the light-emitting elements, a connection defect caused by the step disconnection portion and an increase in electric resistance caused by the locally thinned portion can be inhibited from occurring in the common layer 614 and the common electrode 615.

In the display apparatus of this embodiment, the distance between the light-emitting elements can be short. Specifically, the distance between the light-emitting elements, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where the gap between two adjacent island-shaped EL layers is less than or equal to 1 μm, preferably less than or equal to 0.5 μm (500 nm), further preferably less than or equal to 100 nm. The distance between the light-emitting elements is shortened in this manner, whereby a display apparatus with high resolution and a high aperture ratio can be provided.

A protective layer 631 is provided over the light-emitting element 650. The protective layer 631 is a film functioning as a passivation film for protecting the light-emitting element 650. Provision of the protective layer 631 covering the light-emitting element can inhibit impurities such as water and oxygen from entering the light-emitting element, and increase the reliability of the light-emitting element 650. The protective layer 631 preferably has a single-layer structure or a stacked-layer structure including at least an inorganic insulating film. Examples of the inorganic insulating film include an oxide film and a nitride film such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as an indium gallium oxide or an indium gallium zinc oxide (IGZO) may be used for the protective layer 631. The protective layer 631 can be formed by an ALD method, a CVD method, a sputtering method, or the like. Although a structure in which the protective layer 631 includes an inorganic insulating film is described as an example, one embodiment of the present invention is not limited thereto. For example, the protective layer 631 may have a stacked-layer structure of an inorganic insulating film and an organic insulating film.

The protective layer 631 and a substrate 610 are bonded to each other with an adhesive layer 607. A solid sealing structure, a hollow sealing structure, or the like can be employed to seal the light-emitting elements. In FIG. 28, a solid sealing structure is employed in which a space between the substrate 410 and the substrate 610 is filled with the adhesive layer 607. Alternatively, a hollow sealing structure may be employed, in which the space is filled with an inert gas (e.g., nitrogen or argon). Here, the adhesive layer 607 may be provided not to overlap with the light-emitting element. The space may be filled with a resin other than the frame-shaped adhesive layer 607.

For the adhesive layer 607, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet may be used.

The display apparatus 600A has a top-emission structure. Light from the light-emitting element is emitted to the substrate 610 side. Thus, for the substrate 610, a material having a high visible-light-transmitting property is preferably used. For example, as the substrate 610, a substrate having a high visible-light-transmitting property is selected from substrates that can be used as the substrate 410. The pixel electrode contains a material that reflects visible light, and a counter electrode (the common electrode 615) contains a material that transmits visible light.

Note that the display apparatus of one embodiment of the present invention may be not a top-emission display apparatus but a bottom-emission display apparatus where light from the light-emitting element is emitted to the substrate 410 side. In that case, a substrate having a high visible-light-transmitting property is selected as the substrate 410.

### Structure Example 2 of Display Apparatus

FIG. 36 illustrates a cross-sectional view of the display apparatus 600B. The element layer 660 of the display apparatus 600B is different from the element layer 660 of the display apparatus 600A in that the layer 613a, the layer 613b, and the layer 613c have the same structure and that a coloring layer 628R, a coloring layer 628G, and a coloring layer 628B are provided. Furthermore, the display apparatus 600B is different from the display apparatus 600A in not including the element layer 620 but including an element layer 635. The element layer 635 illustrated in FIG. 36 has a structure similar to that of the element layer 630.

As a variation example of FIG. 36, FIG. 29 illustrates an example in which the transistor MTCK included in the element layer 635 is an OS transistor and has a structure different from that of the transistor MTCK included in the element layer 630 in FIG. 28 and the element layer 635 in FIG. 36.

The element layer 635 illustrated in FIG. 29 includes an insulating layer IS1_2, the transistor MTCK and an insulating layer IS2_2 over the insulating layer IS1_2, and an insulating layer IS3_2 over the transistor MTCK. An oxide semiconductor layer 230k of the transistor MTCK, an insulating layer 250k functioning as a gate insulating layer, and a conductive layer 260k functioning as a gate electrode are provided in an opening of the insulating layer IS2_2. A conductive layer 220k functioning as one of a source electrode and a drain electrode of the transistor MTCK is positioned over the insulating layer IS1_2, and a conductive layer 240k functioning as the other is positioned over the insulating layer IS2_2.

In the element layer 635 illustrated in FIG. 29, the conductive layer 260k of the transistor MTCK includes a region positioned in a first opening provided in the insulating layer IS2_2 and a region positioned in a second opening provided in the insulating layer IS3_2, and the second opening includes a region overlapping with the first opening.

The display apparatus 600B can be a display apparatus having flexibility (also referred to as a flexible display apparatus) when a flexible substrate is used as each of a substrate 541 and the substrate 610. The substrate 541 is bonded to an insulating layer 545 with an adhesive layer 543. The substrate 610 is bonded to the protective layer 631 with the adhesive layer 607.

In the element layer 660 of the display apparatus 600B, the layer 613a, the layer 613b, and the layer 613c have the same structure and the coloring layer 628R, the coloring layer 628G, and the coloring layer 628B are included.

The layer 613a, the layer 613b, and the layer 613c are formed using the same material in the same step. The layer 613a, the layer 613b, and the layer 613c are separated from one another. When the EL layer is provided in an island shape for each light-emitting element, leakage current between adjacent light-emitting elements (sometimes referred to as horizontal-direction leakage current, horizontal leakage current, or lateral leakage current) can be inhibited. Accordingly, unintentional light emission due to crosstalk can be prevented, and color mixture between adjacent light-emitting elements can be inhibited, so that a display apparatus with extremely high contrast can be obtained.

The light-emitting elements 650R, 650G, and 650B illustrated in FIG. 29 and FIG. 36 emit white light, for example. White light emitted from the light-emitting elements 650R, 650G, and 650B passes through the coloring layer 628R, the coloring layer 628G, and the coloring layer 628B, whereby light of a desired color can be obtained.

In the case where the light-emitting element configured to emit white light has a microcavity structure, light with a specific wavelength such as red, green, or blue is sometimes intensified and emitted.

Light emitted from the light-emitting element 650R is extracted as red light to the outside of the display apparatus 600B through the coloring layer 628R. Similarly, light emitted from the light-emitting element 650G is extracted as green light to the outside of the display apparatus 600B through the coloring layer 628G. Light emitted from the light-emitting element 650B is extracted as blue light to the outside of the display apparatus 600B through the coloring layer 628B.

A light-emitting element that emits white light preferably has a tandem structure.

Alternatively, the light-emitting elements 650R, 650G, and 650B illustrated in FIG. 29 and FIG. 36 emit blue light, for example. In that case, the layer 613a, the layer 613b, and the layer 613c each include one or more light-emitting layers that emit blue light. In a subpixel that emits blue light, blue light emitted from the light-emitting element 650B can be extracted. In a subpixel that emits red light and a subpixel that emits green light, a color conversion layer is provided between the light-emitting element 650R and the coloring layer 628R and between the light-emitting element 650G and the coloring layer 628G, so that blue light emitted from the light-emitting element 650R or the light-emitting element 650G is converted into light with a longer wavelength and red light or green light can be extracted. When light transmitted through the color conversion layer is extracted through the coloring layer, light other than light of the desired color can be absorbed by the coloring layer, and color purity of light emitted by a subpixel can be improved.

The coloring layer is a colored layer that selectively transmits light in a specific wavelength range and absorbs light in the other wavelength ranges. For example, a red (R) color filter transmitting light in the red wavelength range, a green (G) color filter transmitting light in the green wavelength range, a blue (B) color filter transmitting light in the blue wavelength range, or the like can be used. For each coloring layer, one or more of a metal material, a resin material, a pigment, and a dye can be used. Each coloring layer is formed in a desired position by a printing method, an inkjet method, an etching method using a photolithography method, or the like.

The element layer 630 of the display apparatus 600B has a structure similar to that of the element layer 630 of the display apparatus 600A; thus, the detailed description thereof is omitted.

The display apparatus 600B includes the element layer 635 and the element layer 630 over the element layer 635. The element layer 635 has a structure similar to that of the element layer 630.

At least part of the transistor included in the element layer 635 is electrically connected to a conductive layer or a transistor included in the element layer 630 through a plug, a wiring, and the like. The wiring layer 670 may be provided between the element layer 630 and the element layer 635.

One or both of a pixel circuit and a driver circuit of the display apparatus are preferably provided in the element layer 635.

Although FIG. 29 and FIG. 36 each illustrate an example in which two element layers including OS transistors are stacked (the element layer 630 and the element layer 635), the number of stacked element layers is not limited thereto, and may be three or more. In the case where three or more element layers including OS transistors are stacked, for example, it is preferable that the lowermost layer be used for the driver circuit (one or both of a gate driver and a source driver) of the display apparatus, the uppermost layer be used for the pixel circuit of the display apparatus, and one or more layers between them be used for the pixel circuit or the driver circuit.

A Si transistor is typically formed on a single crystal Si wafer, and thus is difficult to have flexibility. Meanwhile, as illustrated in FIG. 29 and FIG. 36, in the case where the display apparatus is formed using only OS transistors without using a Si transistor, the display apparatus can have flexibility through a relatively simple manufacturing process.

### Structure Example of Light-Emitting Element

Next, light-emitting elements that can be used in the display apparatus of one embodiment of the present invention are described. Structure examples of light-emitting elements, which are different from the structures illustrated in FIG. 28, FIG. 29, and FIG. 36, are mainly described below.

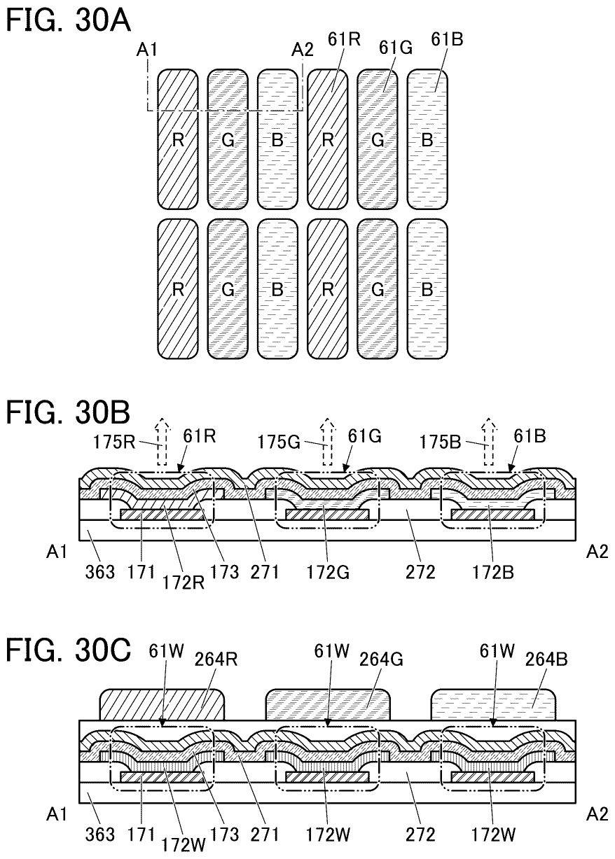

FIG. 30A illustrates a schematic top view of part of a display portion including a plurality of light-emitting elements. The display portion includes a plurality of light-emitting elements 61R emitting red light, a plurality of light-emitting elements 61G emitting green light, and a plurality of light-emitting elements 61B emitting blue light. In FIG. 30A, light-emitting regions of the light-emitting elements are denoted by R, G, and B to easily differentiate the light-emitting elements. Although FIG. 30A illustrates the structure having three emission colors of red (R), green (G), and blue (B) as an example, one embodiment of the present invention is not limited thereto. For example, the structure may have four or more colors.

FIG. 30B is a cross-sectional view taken along dashed-dotted line A1-A2 in FIG. 30A. The light-emitting element 61R, the light-emitting element 61G, and the light-emitting element 61B illustrated in FIG. 30B are each provided over an insulating layer 363 and include a conductive layer 171 functioning as a pixel electrode and a conductive layer 173 functioning as a common electrode. For the insulating layer 363, one or both of an inorganic insulating film and an organic insulating film can be used.

The light-emitting element 61R includes an EL layer 172R between the conductive layer 171 functioning as a pixel electrode and the conductive layer 173 functioning as a common electrode. The EL layer 172R includes at least a light-emitting compound that emits light with a peak in a red wavelength range. An EL layer 172G included in the light-emitting element 61G includes at least a light-emitting compound that emits light with a peak in a green wavelength range. An EL layer 172B included in the light-emitting element 61B includes at least a light-emitting organic compound that emits light with a peak in a blue wavelength range.

The conductive layer 171 functioning as a pixel electrode is provided in each of the light-emitting elements. The conductive layer 173 functioning as a common electrode is provided as a continuous layer shared by the light-emitting elements. A conductive film that has a property of transmitting visible light is used for one of the conductive layer 171 functioning as a pixel electrode and the conductive layer 173 functioning as a common electrode, and a reflective conductive film is used for the other.

In the case where the light-emitting element 61R has a top-emission structure, for example, light 175R from the light-emitting element 61R is emitted to the conductive layer 173 side. In the case where the light-emitting element 61R has a top-emission structure, light 175G from the light-emitting element 61G is emitted to the conductive layer 173 side. In the case where the light-emitting element 61B has a top-emission structure, light 175B from the light-emitting element 61B is emitted to the conductive layer 173 side.

An insulating layer 272 is provided to cover end portions of the conductive layer 171 functioning as a pixel electrode. An end portion of the insulating layer 272 preferably has a tapered shape. For the insulating layer 272, one or both of an inorganic insulating film and an organic insulating film can be used.

The insulating layer 272 is provided to prevent an unintentional electric short-circuit between adjacent light-emitting elements and unintended light emission therefrom. The insulating layer 272 also has a function of preventing the contact of a metal mask with the conductive layer 171 in the case where the metal mask is used to form the EL layer.

The EL layer 172R, the EL layer 172G, and the EL layer 172B each include a region in contact with the top surface of the conductive layer 171 functioning as a pixel electrode and a region in contact with a surface of the insulating layer 272. End portions of the EL layer 172R, the EL layer 172G, and the EL layer 172B are positioned over the insulating layer 272.

As illustrated in FIG. 30B, a gap is provided between two EL layers of light-emitting elements of different emission colors. In this manner, the EL layer 172R, the EL layer 172G, and the EL layer 172B are preferably provided so as not to be in contact with one another. This can favorably prevent unintentional light emission (also referred to as crosstalk) from being caused by current flowing through two adjacent EL layers. As a result, the contrast can be increased to achieve a display apparatus with high display quality.

The EL layer 172R, the EL layer 172G, and the EL layer 172B can be formed separately by a vacuum evaporation method using a shadow mask such as a metal mask, for example. Alternatively, these layers may be formed separately by a photolithography method. The use of a photolithography method enables a display apparatus to have high resolution, which is difficult to obtain in the case of using a metal mask.

A protective layer 271 is provided over the conductive layer 173 functioning as a common electrode so as to cover the light-emitting element 61R, the light-emitting element 61G, and the light-emitting element 61B. The protective layer 271 has a function of preventing diffusion of impurities such as water into the light-emitting elements from above. For the material for the protective layer 271, the above-described material for the protective layer 631 can be referred to.

FIG. 30C illustrates a light-emitting element 61W emitting white light. The light-emitting element 61W includes an EL layer 172W that emits white light between the conductive layer 171 functioning as a pixel electrode and the conductive layer 173 functioning as a common electrode.

The EL layer 172W can have, for example, a structure in which two or more light-emitting layers that are selected such that their emission colors have a relationship of complementary colors are stacked. It is also possible to use a tandem EL layer in which a charge-generation layer is provided between light-emitting layers.

FIG. 30C illustrates three light-emitting elements 61W side by side. A coloring layer 264R is provided above the light-emitting element 61W on the left. The coloring layer 264R functions as a band-pass filter that transmits red light. Similarly, a coloring layer 264G that transmits green light is provided above the light-emitting element 61W in the middle, and a coloring layer 264B that transmits blue light is provided above the light-emitting element 61W on the right. Accordingly, the display apparatus can display an image with colors.

Here, the EL layer 172W is separated between two adjacent light-emitting elements 61W. This can prevent unintentional light emission from being caused by current flowing through the EL layers 172W of the two adjacent light-emitting elements 61W. Particularly when a stacked EL layer in which a charge-generation layer is provided between two light-emitting layers is used as the EL layer 172W, the effect of crosstalk becomes more significant as the resolution increases, i.e., as the distance between adjacent pixels decreases, leading to a problem of lower contrast. Thus, employing the above structure enables a display apparatus to have both high resolution and high contrast.

A photolithography method is preferably used for the separation of the EL layer 172W. This can reduce a gap between light-emitting elements, enabling a display apparatus to have a higher aperture ratio than that formed using, for example, a shadow mask such as a metal mask.

This embodiment can be combined with the other embodiments as appropriate.

### Embodiment 6

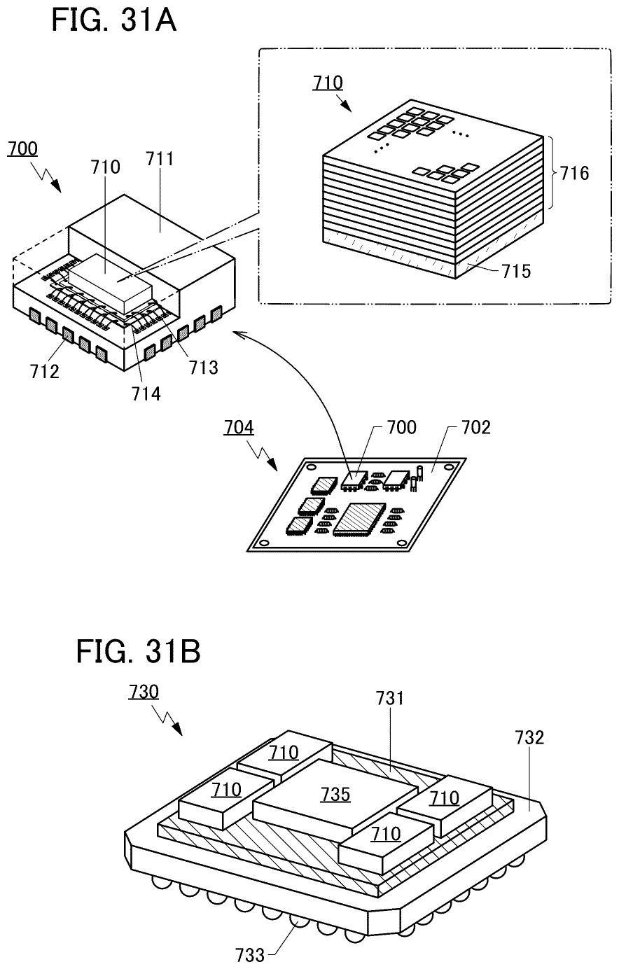

In this embodiment, application examples of the semiconductor device of one embodiment of the present invention are described with reference to FIG. 31 to FIG. 35.

The semiconductor device of one embodiment of the present invention can be used for an electronic component, a large computer, space equipment, a data center (also referred to as DC), and a variety of electronic appliances, for example. With the use of the semiconductor device of one embodiment of the present invention, an electronic component, a large computer, space equipment, a data center, and a variety of electronic appliances can have lower power consumption and higher performance.

A display apparatus including the semiconductor device of one embodiment of the present invention can be used for a display portion of a variety of electronic appliances. The display apparatus including the semiconductor device of one embodiment of the present invention can be easily increased in resolution and definition.

Examples of the electronic appliances include a digital camera, a digital video camera, a digital photo frame, a mobile phone, a portable game console, a portable information terminal, and an audio reproducing device, in addition to electronic appliances with relatively large screens, such as a television device, a desktop or notebook personal computer, a monitor of a computer or the like, digital signage, and a large game machine such as a pachinko machine.

In particular, the display apparatus of one embodiment of the present invention can have a high resolution, and thus can be suitably used for an electronic appliance having a relatively small display portion. Examples of such an electronic appliance include watch-type and bracelet-type information terminal devices (wearable devices) and wearable devices capable of being worn on a head, such as a VR device like a head-mounted display, a glasses-type AR device, and an MR device.

The display apparatus of one embodiment of the present invention preferably has an extremely high definition such as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display apparatus of one embodiment of the present invention is preferably 100 ppi or higher, 300 ppi or higher, 500 ppi or higher, 1000 ppi or higher, 2000 ppi or higher, 3000 ppi or higher, 5000 ppi or higher, or 7000 ppi or higher. The use of a display apparatus having one or both of such high definition and high resolution can further increase realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (square), 4:3, 16:9, and 16:10.

The electronic appliance in this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, odor, or infrared rays).

The electronic appliance in this embodiment can have a variety of functions. For example, the electronic appliance in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### [Electronic Component]

FIG. 31A illustrates a perspective view of a substrate (a mounting board 704) on which an electronic component 700 is mounted. The electronic component 700 illustrated in FIG. 31A includes a semiconductor device 710 in a mold 711. Some components are omitted in FIG. 31A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected on the printed circuit board 702, whereby the mounting board 704 is completed.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as TSV (Through Silicon Via) and a bonding technique such as Cu—Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be made smaller than those when the technique using a through electrode such as TSV is employed; thus, the number of connection pins can be increased. The increase in the number of connection pins enables parallel operation, which can improve the bandwidth of the memory (also referred to as a memory bandwidth).

It is preferable that the plurality of memory cell arrays included in the memory layer 716 be formed using OS transistors and the plurality of memory cell arrays be monolithically stacked. The monolithic stacked-layer structure of the plurality of memory cell arrays can improve one or both of the bandwidth of the memory and the access latency of the memory. Note that the bandwidth refers to the data transfer amount per unit time, and the access latency refers to time between data access and start of data transmission. In the case where Si transistors are used for the memory layer 716, the monolithic stacked-layer structure is difficult to form as compared with the case where OS transistors are used. Therefore, the OS transistors are superior to the Si transistors in the monolithic stacked-layer structure.

The semiconductor device 710 may be called a die. In this specification and the like, a die refers to a chip piece obtained by, for example, forming a circuit pattern on a disc-like substrate (also referred to as a wafer) or the like and cutting the substrate into dies in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 31B illustrates a perspective view of an electronic component 730. The electronic component 730 is an example of a SiP (System in Package) or an MCM (Multi Chip Module). In the electronic component 730, an interposer 731 is provided on a package substrate 732 (printed circuit board), and a semiconductor device 735 and a plurality of the semiconductor devices 710 are provided on the interposer 731.

The electronic component 730 using the semiconductor devices 710 as high bandwidth memories (HBM) is illustrated as an example. The semiconductor device 735 can be used for an integrated circuit such as a CPU, a GPU, or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. The interposer 731 also has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In a silicon interposer, TSV can also be used as the through electrode.

In an HBM, many wirings need to be connected to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like each using a silicon interposer, a decrease in reliability due to a difference in expansion coefficient between the integrated circuit and the interposer is less likely to occur. Furthermore, since a surface of a silicon interposer has high planarity, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, TSV, and the like, a space for the width of the terminal pitches and the like is needed. Accordingly, in the case where the size of the electronic component 730 is to be reduced, the width of the terminal pitches becomes an issue, which sometimes makes it difficult to provide a large number of wirings for achieving a wide memory bandwidth. For this reason, the monolithic stacked-layer structure using the OS transistors is suitable, as described above. A composite structure in which memory cell arrays stacked using TSV and monolithically stacked memory cell arrays are combined may be employed.

A heat sink (radiator plate) may be provided to overlap with the electronic component 730. In the case where a heat sink is provided, the levels of integrated circuits provided on the interposer 731 are preferably equal to each other. For example, in the electronic component 730 described in this embodiment, the levels of the semiconductor devices 710 and the semiconductor device 735 are preferably equal to one another.

Electrodes 733 may be provided on a bottom portion of the package substrate 732 to mount the electronic component 730 on another substrate. FIG. 31B illustrates an example in which the electrodes 733 are formed of solder balls. When the solder balls are provided in a matrix on the bottom portion of the package substrate 732, BGA (Ball Grid Array) mounting can be achieved. Alternatively, the electrodes 733 may be formed of conductive pins. When the conductive pins are provided in a matrix on the bottom portion of the package substrate 732, PGA (Pin Grid Array) mounting can be achieved.

The electronic component 730 can be mounted on another substrate by any of a variety of mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### [Large Computer]

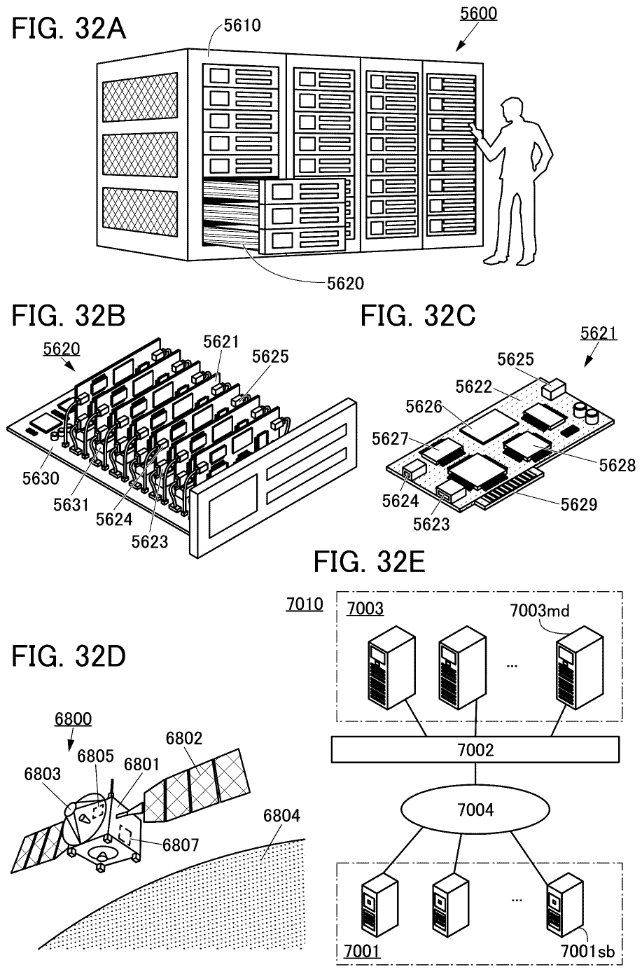

Next, FIG. 32A illustrates a perspective view of a large computer 5600. In the large computer 5600 illustrated in FIG. 32A, a plurality of rack mount computers 5620 are stored in a rack 5610. Note that the large computer 5600 may also be referred to as a supercomputer.

Each of the computers 5620 can have a structure in the perspective view illustrated in FIG. 32B, for example. In FIG. 32B, the computer 5620 includes a motherboard 5630, and the motherboard 5630 includes a plurality of slots 5631 and a plurality of connection terminals. A PC card 5621 is inserted in each of the slots 5631. In addition, the PC card 5621 includes a connection terminal 5623, a connection terminal 5624, and a connection terminal 5625, each of which is connected to the motherboard 5630.

The PC card 5621 illustrated in FIG. 32C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. FIG. 32C also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and functions as an interface for connecting the PC card 5621 and the motherboard 5630. Examples of the standard for the connection terminal 5629 include PCIe.

The connection terminal 5623, the connection terminal 5624, and the connection terminal 5625 can each serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, examples of the standard therefor include HDMI (registered trademark).

The semiconductor device 5626 includes a terminal (not illustrated) for inputting and outputting signals, and when the terminal is inserted into a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. Examples of the semiconductor device 5628 include a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used for space equipment.

The semiconductor device of one embodiment of the present invention includes an OS transistor. A change in electrical characteristics of an OS transistor due to exposure to radiation is small. That is, an OS transistor is highly resistant to radiation and thus can be suitably used in an environment where radiation can enter. For example, an OS transistor can be suitably used in the case of being used in outer space. Specifically, an OS transistor can be used as a transistor included in a semiconductor device provided in a space shuttle, an artificial satellite, or a space probe. Examples of radiation include X-rays and a neutron beam. Note that outer space refers to, for example, space at an altitude greater than or equal to 100 km, and outer space described in this specification may include one or more of the thermosphere, the mesosphere, and the stratosphere.

FIG. 32D illustrates an artificial satellite 6800 as an example of space equipment. The artificial satellite 6800 includes a body 6801, a solar panel 6802, an antenna 6803, a secondary battery 6805, and a control device 6807. FIG. 32D illustrates a planet 6804 in outer space, for example.

Although not illustrated in FIG. 32D, a battery management system (also referred to as BMS) or a battery control circuit may be provided in the secondary battery 6805. An OS transistor is suitably used in the battery management system or the battery control circuit because low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, meson beams, and the like.

When the solar panel 6802 is irradiated with sunlight, electric power required for the operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, electric power required for the operation of the artificial satellite 6800 might not be generated. In order to operate the artificial satellite 6800 even in the situation where the amount of generated electric power is small, the artificial satellite 6800 may be provided with the secondary battery 6805. Note that the solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed using one or more selected from a CPU, a GPU, and a memory device, for example. Note that semiconductor device including an OS transistor, which is one embodiment of the present invention, is suitably used for the control device 6807. A change in electrical characteristics due to exposure to radiation is smaller in an OS transistor than in a Si transistor. That is, an OS transistor has high reliability and thus can be suitably used even in an environment where radiation can enter.

The artificial satellite 6800 can have a structure including a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can have a function of an earth observing satellite, for example.

Although the artificial satellite is described as an example of space equipment in this embodiment, the present invention is not limited thereto. The semiconductor device of one embodiment of the present invention can be suitably used for space equipment such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for, for example, a storage system used in a data center or the like. Long-term data management, such as a guarantee for data immutability, is required for the data center. The long-term data management needs increasing the scale of the data center for installation of a storage and a server for storing an enormous amount of data, a stable power source for data retention, ensuring cooling equipment required for data retention, or the like.

With the use of the semiconductor device of one embodiment of the present invention for the storage system used in the data center, electric power required for data retention can be reduced and a semiconductor device that retains data can be downsized. Accordingly, downsizing of the storage system, downsizing of a power source for data retention, downscaling of cooling equipment, and the like can be achieved. Therefore, space saving of the data center can be achieved.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention can achieve a data center that stably operates even in a high-temperature environment. Thus, the reliability of the data center can be increased.

FIG. 32E illustrates a storage system that can be used in a data center. A storage system 7010 illustrated in FIG. 32E includes a plurality of servers 7001sb as a host 7001 (indicated as “Host Computer” in the diagram). The storage system 7010 includes a plurality of memory devices 7003md as a storage 7003 (indicated as “Storage” in the diagram). In the illustrated example, the host 7001 and the storage 7003 are connected through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but the time is considerably longer than the time required for a DRAM that can be used as a cache memory in the storage. In the storage system, in order to solve the problem of low access speed of the storage 7003, a cache memory is normally provided in the storage to shorten the time taken for data storage and output.

The above-described cache memory is used in the storage control circuit 7002 and the storage 7003. Data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on the data can reduce the frequency of refreshing, so that power consumption can be reduced. Furthermore, downsizing is possible by stacking memory cell arrays.

### [Electronic Appliance]

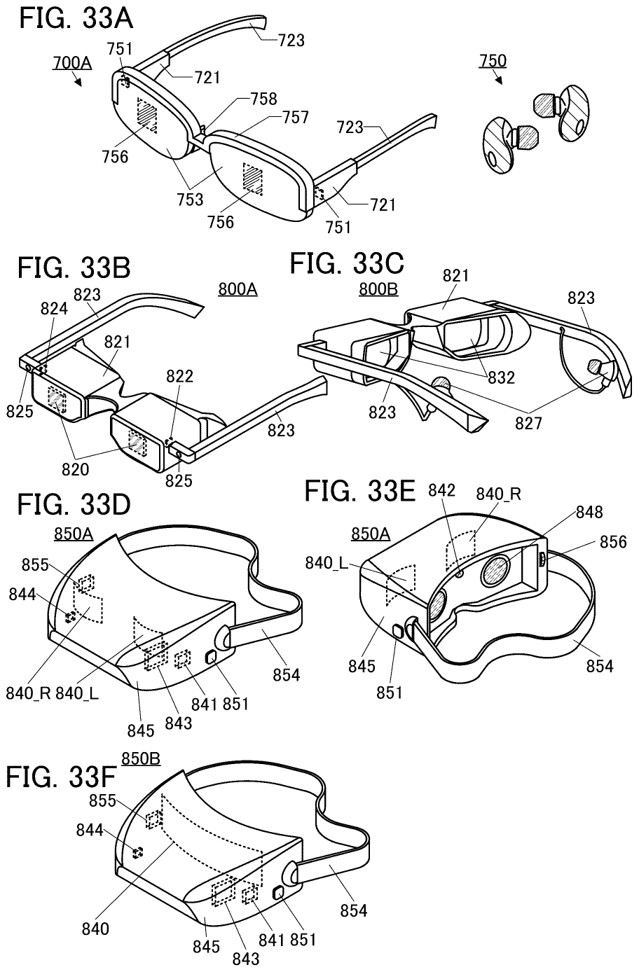

Examples of wearable devices that can be worn on a head are described with reference to FIG. 33A to FIG. 33F. The wearable devices have at least one of a function of displaying AR contents, a function of displaying VR contents, a function of displaying SR contents, and a function of displaying MR contents. An electronic appliance having a function of displaying contents of at least one of AR, VR, SR, MR, and the like enables the user to feel a higher level of immersion.

An electronic appliance 700A illustrated in FIG. 33A includes a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. In that case, the electronic appliance is capable of ultrahigh-resolution display. The semiconductor device of one embodiment of the present invention can be used for the control portion (not illustrated). In that case, the power consumption of the electronic appliance can be reduced.

The electronic appliance 700A can project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic appliance 700A is an electronic appliance capable of AR display.

In the electronic appliance 700A, a camera capable of capturing images of the front side may be provided as the image capturing portion. Furthermore, when the electronic appliance 700A is provided with an acceleration sensor such as a gyroscope sensor, the orientation of the user's head can be sensed and images corresponding to the orientation can be displayed on the display regions 756.

The communication portion includes a wireless communication device, and a video signal and the like can be supplied by the wireless communication device. Instead of the wireless communication device or in addition to the wireless communication device, a connector to which a cable supplied with a video signal and a power potential can be connected may be provided.

In addition, the electronic appliance 700A is provided with a battery so that charging can be performed wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, processing such as a pause or a restart of a moving image can be executed by a tap operation, and processing such as fast forward and fast rewind can be executed by a slide operation. When the touch sensor module is provided in each of the two housings 721, the range of the operation can be increased.

An electronic appliance 800A illustrated in FIG. 33B and an electronic appliance 800B illustrated in FIG. 33C each include a pair of display portions 820, a housing 821, a communication portion 822, a pair of wearing portions 823, a control portion 824, a pair of capturing portions 825, and a pair of lenses 832.

The display apparatus of one embodiment of the present invention can be used for the display portions 820. In that case, the electronic appliance is capable of ultrahigh-resolution display. Such an electronic appliance can provide a high level of immersion to the user. The semiconductor device of one embodiment of the present invention can be used for the control portion 824. In that case, the power consumption of the electronic appliance can be reduced.

The display portions 820 are provided at positions inside the housing 821 so as to be seen through the lenses 832. When the pair of display portions 820 display different images, three-dimensional display using parallax can be performed.

Each of the electronic appliance 800A and the electronic appliance 800B can be regarded as an electronic appliance for VR. The user who wears the electronic appliance 800A or the electronic appliance 800B can see images displayed on the display portions 820 through the lenses 832.

The electronic appliance 800A and the electronic appliance 800B each preferably include a mechanism capable of adjusting the lateral positions of the lenses 832 and the display portions 820 so that the lenses 832 and the display portions 820 are positioned optimally in accordance with the positions of the user's eyes. In addition, a mechanism for adjusting focus by changing the distance between the lenses 832 and the display portions 820 is preferably included.

The electronic appliance 800A or the electronic appliance 800B can be mounted on the user's head with the wearing portions 823. Although FIG. 33B and the like illustrate examples in which each of the wearing portions 823 has a shape like an ear piece of glasses (also referred to as a temple or the like), one embodiment of the present invention is not limited thereto. The wearing portion 823 may have any shape with which the user can wear the electronic appliance, such as a shape of a helmet or a band.

The image capturing portions 825 have a function of obtaining information on the external environment. Data obtained by the image capturing portions 825 can be output to the display portions 820. Image sensors can be used for the image capturing portions 825. Moreover, a plurality of cameras may be provided so as to cover a plurality of fields of view, such as a telescope field of view and a wide field of view.

Although examples in which the image capturing portions 825 are included are described here, a range sensor (hereinafter, also referred to as a sensing portion) that is capable of measuring the distance to an object just needs to be provided. In other words, the image capturing portions 825 are each one embodiment of the sensing portion. For the sensing portion, an image sensor or a distance image sensor such as LIDAR (Light Detection and Ranging) can be used, for example. By using images obtained by a camera and images obtained by the distance image sensor, more pieces of information can be obtained and a gesture operation with higher accuracy is possible.

The electronic appliance 800A may include a vibration mechanism functioning as a bone-conduction earphone. For example, a structure including the vibration mechanism can be employed for any one or more of the display portions 820, the housing 821, and the wearing portions 823. Thus, without additionally requiring an audio device such as headphones, earphones, or a speaker, the user can enjoy images and sound only by wearing the electronic appliance 800A. The electronic appliance 800A and the electronic appliance 800B may each include an input terminal. To the input terminal, a cable for supplying a video signal from a video output device or the like, electric power for charging a battery provided in the electronic appliance, and the like can be connected.

The electronic appliance of one embodiment of the present invention may have a function of performing wireless communication with earphones 750. The earphones 750 include a communication portion (not illustrated) and have a wireless communication function. The earphones 750 can receive information (e.g., audio data) from the electronic appliance with the wireless communication function. For example, the electronic appliance 700A illustrated in FIG. 33A has a function of transmitting information to the earphones 750 with the wireless communication function.

The electronic appliance may include an earphone portion. The electronic appliance 800B illustrated in FIG. 33C includes earphone portions 827. The earphone portions 827 can be connected to the control portion 824 by wire, for example. Part of a wiring that connects the earphone portions 827 and the control portion 824 may be placed inside the housing 821 or the wearing portions 823. The earphone portions 827 and the wearing portions 823 may include magnets. This is preferable because the earphone portions 827 can be fixed to the wearing portions 823 with magnetic force and thus can be easily housed.

The electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of what is called a headset by including the audio input mechanism.

FIG. 33D and FIG. 33E illustrate perspective views of a goggles-type electronic appliance 850A for VR. FIG. 33D and FIG. 33E illustrate an example in which a pair of curved display apparatuses 840 (a display apparatus 840_R and a display apparatus 840_L) is included in a housing 845. The electronic appliance 850A includes a motion detection portion 841, an eye-gaze detection portion 842, an arithmetic portion 843, a communication portion 844, lenses 848, an operation button 851, a wearing tool 854, a sensor 855, a dial 856, and the like.

Since the two display apparatuses 840 are included, the user's eyes can see their respective display apparatuses. This allows a high-definition video to be displayed even when three-dimensional display using parallax is performed. The display apparatuses 840 are each curved around an arc with the user's eye as an approximate center. This allows a uniform distance between the user's eye and the display surface of the display apparatus 840; thus, the user can see a more natural image. Even when having what is called viewing angle dependence where the luminance or chromaticity of light changes depending on a viewing angle, the display apparatus 840 can have a structure in which the user's eye is positioned in the normal direction of the display surface of the display apparatus 840; accordingly, the influence of the viewing angle dependence particularly in the horizontal direction can be practically ignored, enabling display of a more realistic video.

As illustrated in FIG. 33E, the lenses 848 are positioned between the display apparatuses 840 and the user's eyes. FIG. 33E illustrates an example in which the dial 856 for changing the positions of the lenses for visibility adjustment is provided. In the case where the electronic appliance 850A has an autofocus function, the dial 856 for visibility adjustment is not necessarily provided.

FIG. 33F illustrates a goggles-type electronic appliance 850B including one display apparatus 840. Such a structure can reduce the number of components.

The display apparatus 840 can display an image for the right eye and an image for the left eye side by side on a right region and a left region, respectively. Thus, a three-dimensional image using binocular disparity can be displayed. The display apparatus 840 may display two different images side by side using parallax, or may display two same images side by side without using parallax.

One image that can be seen by both eyes may be displayed on the entire display apparatus 840. A panorama image can thus be displayed from end to end of the field of view, which can provide a stronger sense of reality.

The display apparatus of one embodiment of the present invention can be used for the display apparatus 840. Since the display apparatus of one embodiment of the present invention has an extremely high resolution, even when an image is magnified using the lens 848, the pixels are not perceived by the user, and thus a more realistic image can be displayed.

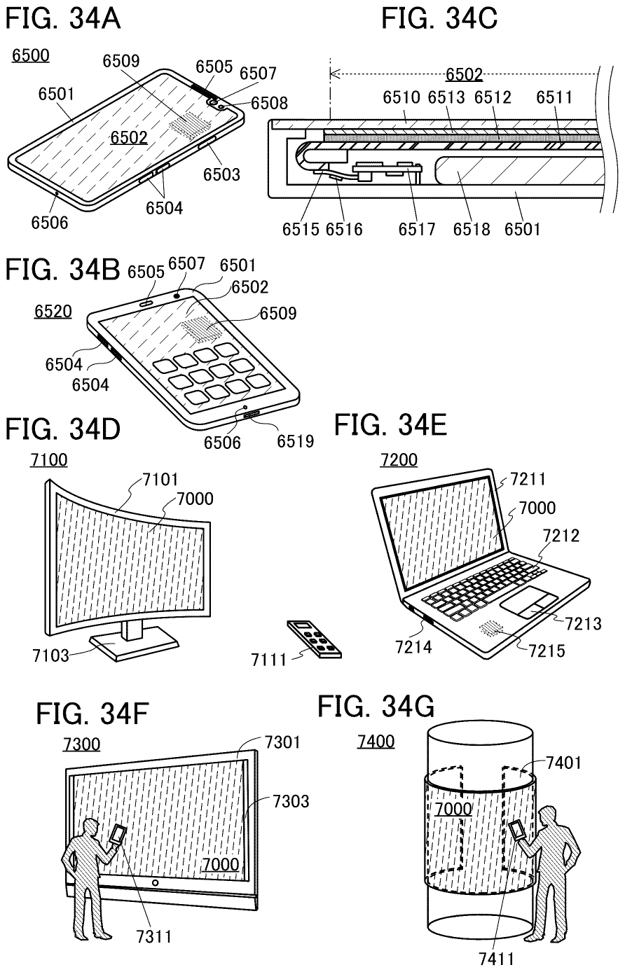

An electronic appliance 6500 illustrated in FIG. 34A is a portable information terminal device that can be used as a smartphone.

The electronic appliance 6500 includes a housing 6501, a display portion 6502, a power button 6503, buttons 6504, a speaker 6505, a microphone 6506, a camera 6507, a light source 6508, a control device 6509, and the like.

An electronic appliance 6520 illustrated in FIG. 34B is a portable information terminal device that can be used as a tablet terminal.

The electronic appliance 6520 includes the housing 6501, the display portion 6502, the buttons 6504, the speaker 6505, the microphone 6506, the camera 6507, the control device 6509, a connection terminal 6519, and the like.

In each of the electronic appliance 6500 and the electronic appliance 6520, the display portion 6502 has a touch panel function. In addition, one or more selected from a CPU, a GPU, and a memory device are included in the control device 6509, for example. The semiconductor device of one embodiment of the present invention can be used for one or both of the display portion 6502 and the control device 6509.

FIG. 34C is a schematic cross-sectional view including an end portion of the housing 6501 included in the electronic appliance 6500 or the electronic appliance 6520 on the microphone 6506 side.

A protection member 6510 having a light-transmitting property is provided on the display surface side of the housing 6501; a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus of one embodiment of the present invention can be used as the display panel 6511. In that case, an extremely lightweight electronic appliance can be obtained. Since the display panel 6511 is extremely thin, the battery 6518 with high capacity can be mounted without an increase in the thickness of the electronic appliance. Moreover, part of the display panel 6511 is folded back so that a connection portion with the FPC 6515 is provided on the back side of the pixel portion, whereby an electronic appliance with a narrow bezel can be obtained.

FIG. 34D illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

Operations of the television device 7100 illustrated in FIG. 34D can be performed with an operation switch included in the housing 7101 and a separate remote controller 7111. Alternatively, the display portion 7000 may include a touch sensor, and the television device 7100 may be operated by touch on the display portion 7000 with a finger or the like. The remote controller 7111 may include a display portion for displaying information output from the remote controller 7111. With operation keys or a touch panel provided in the remote controller 7111, channels and volume can be controlled and videos displayed on the display portion 7000 can be controlled.

The television device 7100 has a structure including a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 34E illustrates an example of a notebook personal computer. A notebook personal computer 7200 includes a housing 7211, a keyboard 7212, a pointing device 7213, an external connection port 7214, a control device 7215, and the like. The display portion 7000 is incorporated in the housing 7211. One or more selected from a CPU, a GPU, and a memory device are included in the control device 7215, for example. The semiconductor device of one embodiment of the present invention can be used for one or both of the display portion 7000 and the control device 7215.

FIG. 34F and FIG. 34G illustrate examples of digital signage.

Digital signage 7300 illustrated in FIG. 34F includes a housing 7301, the display portion 7000, a speaker 7303, and the like. Furthermore, an LED lamp, an operation key (including a power switch or an operation switch), a connection terminal, a variety of sensors, a microphone, and the like can be included.

FIG. 34G is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in FIG. 34F and FIG. 34G.

A larger area of the display portion 7000 can increase the amount of information that can be provided at a time. The larger display portion 7000 attracts more attention, so that the effectiveness of the advertisement can be increased, for example.

A touch panel is preferably used for the display portion 7000, in which case intuitive operation by the user is possible in addition to display of an image or a moving image on the display portion 7000. Moreover, for an application for providing information such as route information or traffic information, usability can be enhanced by intuitive operation.

As illustrated in FIG. 34F and FIG. 34G, it is preferable that the digital signage 7300 or the digital signage 7400 can work with an information terminal device 7311 or an information terminal device 7411 such as the user's smartphone through wireless communication. For example, information of an advertisement displayed on the display portion 7000 can be displayed on a screen of the information terminal device 7311 or the information terminal device 7411. By operation of the information terminal device 7311 or the information terminal device 7411, display on the display portion 7000 can be switched.

It is also possible to make the digital signage 7300 or the digital signage 7400 execute a game with the use of the screen of the information terminal device 7311 or the information terminal device 7411 as an operation means (controller). In that case, an unspecified number of users can join in and enjoy the game concurrently.

The semiconductor device and the display apparatus of one embodiment of the present invention can also be used around a driver's seat in a car, which is a vehicle.

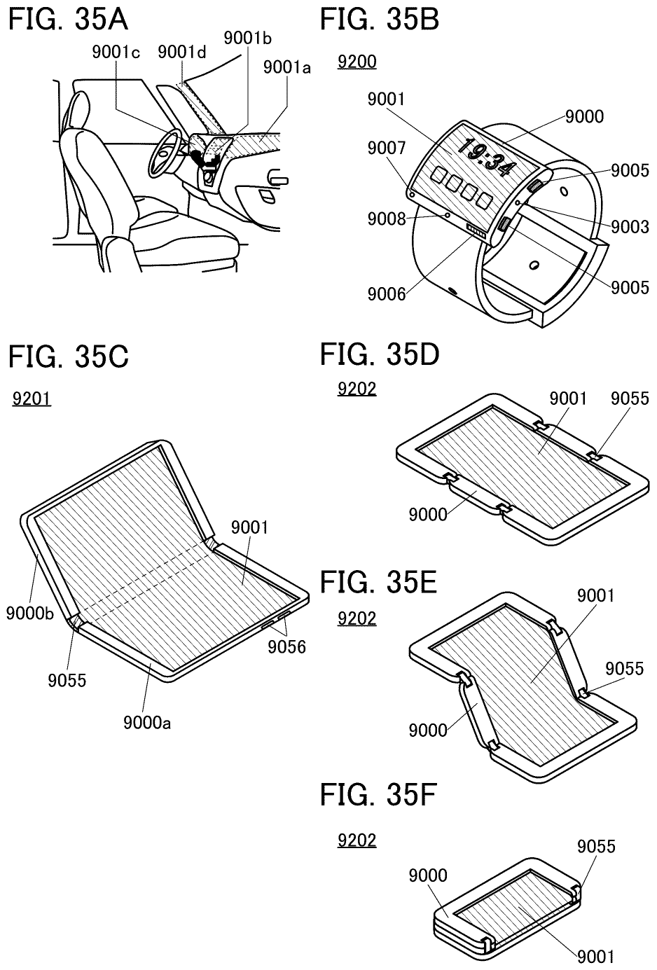

FIG. 35A is a diagram illustrating an area around a windshield inside an automobile. FIG. 35A illustrates a display panel 9001a, a display panel 9001b, and a display panel 9001c attached to a dashboard and a display panel 9001d attached to a pillar.

The display panel 9001a to the display panel 9001c can provide a variety of kinds of information by displaying navigation information, a speedometer, a tachometer, a mileage, a fuel meter, a gearshift indicator, air-condition settings, and the like. The content, layout, and the like of the display on the display panels can be changed as appropriate to suit the user's preference, so that the design can be improved. The display panel 9001a to the display panel 9001c can also be used as lighting devices.

The display panel 9001d can compensate for the view obstructed by the pillar (blind areas) by displaying a video taken by an imaging unit provided for the car body. That is, displaying an image taken by the imaging unit provided on the outside of the car body leads to elimination of blind areas and enhancement of safety. In addition, displaying an image to complement a portion that cannot be seen makes it possible to confirm the safety more naturally and comfortably. The display panel 9001d can also be used as a lighting device.

FIG. 35B is a perspective view illustrating a wristwatch-type portable information terminal 9200. The portable information terminal 9200 can be used as a Smartwatch (registered trademark), for example. The display surface of a display portion 9001 is curved, and an image can be displayed on the curved display surface. Furthermore, for example, mutual communication between the portable information terminal 9200 and a headset capable of wireless communication can be performed, and thus hands-free calling is possible. With a connection terminal 9006, the portable information terminal 9200 can perform mutual data transmission with another information terminal and charging. The charging operation may be performed by wireless power feeding.

The portable information terminal 9200 illustrated in FIG. 35B includes a housing 9000, the display portion 9001, a speaker 9003, an operation key 9005 (including a power switch or an operation switch), the connection terminal 9006, a sensor 9007 (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, odor, or infrared rays), a microphone 9008, and the like.

FIG. 35C is a perspective view illustrating a foldable portable information terminal 9201. The portable information terminal 9201 includes a housing 9000a, a housing 9000b, the display portion 9001, and operation buttons 9056.

The housing 9000a and the housing 9000b are connected to each other with a hinge 9055, and the hinge 9055 allows a bi-fold.

The display portion 9001 included in the portable information terminal 9201 is supported by two housings (the housing 9000a and the housing 9000b) joined together by the hinge 9055.

FIG. 35D to FIG. 35F are perspective views illustrating a foldable portable information terminal 9202. FIG. 35D is a perspective view of an opened state of the portable information terminal 9202, FIG. 35F is a perspective view of a folded state thereof, and FIG. 35E is a perspective view of a state in the middle of change from one of FIG. 35D and FIG. 35F to the other. In this manner, the portable information terminal 9202 can be folded in three.

The display portion 9001 included in the portable information terminal 9202 is supported by three housings 9000 joined together by the hinge 9055.

The display apparatus of one embodiment of the present invention can be used for the display portion 9001 in FIG. 35C to FIG. 35F. The display portion 9001 can be folded with a radius of curvature greater than or equal to 0.1 mm and less than or equal to 150 mm, for example.

The portable information terminal 9201 and the portable information terminal 9202 are each highly portable in the folded state and are each highly browsable in the opened state owing to a seamless large display region.

The use of the semiconductor device of one embodiment of the present invention for one or more selected from an electronic component, a large computer, space equipment, a data center, and an electronic appliance can reduce power consumption. While the demand for energy is expected to increase with higher performance or higher integration of semiconductor devices, the emission amount of greenhouse effect gases typified by carbon dioxide (CO₂) can be reduced with the use of the semiconductor device of one embodiment of the present invention. Furthermore, the semiconductor device of one embodiment of the present invention has low power consumption and thus is effective as a global warming countermeasure.

This embodiment can be combined with the other embodiments as appropriate.

### REFERENCE NUMERALS

ADDR: signal, BIL: wiring, BILB: wiring, BRL: wiring, BW: signal, CA: capacitor, CAL: wiring, CB: capacitor, CC: capacitor, CE: signal, CLK: signal, D: width, GNDL: wiring, GW: signal, M10: transistor, MPG: conductive layer, MTCK: transistor, RBL: wiring, RDA: signal, RWL: wiring, SL: wiring, VDL: wiring, WAKE: signal, WBL: wiring, WDA: signal, WOL: wiring, 61B: light-emitting element, 61G: light-emitting element, 61R: light-emitting element, 61W: light-emitting element, 100a: capacitor, 100b: capacitor, 100: capacitor, 110: conductive layer, 115: conductive layer, 120: conductive layer, 130B: subpixel, 130G: subpixel, 130R: subpixel, 130: insulating layer, 140: insulating layer, 150a: memory cell, 150b: memory cell, 150c: memory cell, 150d: memory cell, 150: memory cell, 160: memory layer, 170: display module, 171: conductive layer, 172B: EL layer, 172G: EL layer, 172R: EL layer, 172W: EL layer, 173: conductive layer, 175B: light, 175G: light, 175R: light, 180: insulating layer, 190: opening, 200: transistor, 200a: transistor, 200b: transistor, 210: insulating layer, 220k: conductive layer, 220: conductive layer, 222: insulating layer, 230a: oxide layer, 230b: oxide layer, 230c: oxide layer, 230k: oxide semiconductor layer, 230: oxide semiconductor layer, 240k: conductive layer, 240: conductive layer, 245: conductive layer, 246: conductive layer, 247: conductive layer, 248: conductive layer, 250a: insulating layer, 250b: insulating layer, 250c: insulating layer, 250d: insulating layer, 250k: insulating layer, 250: insulating layer, 260a: conductive layer, 260af: conductive layer, 260b: conductive layer, 260bf: conductive layer, 260k: conductive layer, 260: conductive layer, 264B: coloring layer, 264G: coloring layer, 264R: coloring layer, 271: protective layer, 272: insulating layer, 278: mask, 280a: insulating layer, 280b: insulating layer, 280c: insulating layer, 280: insulating layer, 283: insulating layer, 285: insulating layer, 290a: opening, 290b: opening, 290: opening, 291: substrate, 292: circuit portion, 293a: pixel circuit, 293: pixel circuit portion, 294a: pixel, 294: pixel portion, 295: terminal portion, 296: wiring portion, 297: display portion, 298: FPC, 299: substrate, 300: transistor, 311: substrate, 313: semiconductor region, 314a: low-resistance region, 314b: low-resistance region, 315: insulating layer, 316: conductive layer, 320: insulating layer, 322: insulating layer, 324: insulating layer, 326: insulating layer, 328: conductive layer, 330: conductive layer, 350: insulating layer, 352: insulating layer, 354: insulating layer, 356: conductive layer, 363: insulating layer, 400d: transistor, 410: substrate, 412: element isolation layer, 413: semiconductor region, 414a: low-resistance region, 414b: low-resistance region, 415: insulating layer, 416: conductive layer, 417: insulating layer, 420: insulating layer, 422: insulating layer, 424: insulating layer, 426: insulating layer, 428: conductive layer, 430: conductive layer, 450: insulating layer, 452: insulating layer, 454: insulating layer, 456: conductive layer, 513: insulating layer, 514: conductive layer, 541: substrate, 543: adhesive layer, 545: insulating layer, 574: insulating layer, 581: insulating layer, 592: insulating layer, 594: insulating layer, 596: conductive layer, 598: insulating layer, 599: insulating layer, 600A: display apparatus, 600B: display apparatus, 607: adhesive layer, 610: substrate, 611a: conductive layer, 611b: conductive layer, 611c: conductive layer, 613a: layer, 613b: layer, 613c: layer, 614: common layer, 615: common electrode, 618a: sacrificial layer, 620: element layer, 625: insulating layer, 627: insulating layer, 628B: coloring layer, 628G: coloring layer, 628R: coloring layer, 630: element layer, 631: protective layer, 635: element layer, 640: connection portion, 641: insulating layer, 642: conductive layer, 643: conductive layer, 644: conductive layer, 645: conductive layer, 646: conductive layer, 647: insulating layer, 648: insulating layer, 650B: light-emitting element, 650G: light-emitting element, 650R: light-emitting element, 650: light-emitting element, 660: element layer, 661: conductive layer, 662: conductive layer, 670: wiring layer, 700A: electronic appliance, 700: electronic component, 702: printed circuit board, 704: mounting board, 710: semiconductor device, 711: mold, 712: land, 713: electrode pad, 714: wire, 715: driver circuit layer, 716: memory layer, 721: housing, 723: wearing portion, 730: electronic component, 731: interposer, 732: package substrate, 733: electrode, 735: semiconductor device, 750: earphone, 751: display panel, 753: optical member, 756: display region, 757: frame, 758: nose pad, 800A: electronic appliance, 800B: electronic appliance, 820: display portion, 821: housing, 822: communication portion, 823: wearing portion, 824: control portion, 825: image capturing portion, 827: earphone portion, 832: lens, 840_L: display apparatus, 840_R: display apparatus, 840: display apparatus, 841: motion detection portion, 842: eye-gaze detection portion, 843: arithmetic portion, 844: communication portion, 845: housing, 848: lens, 850A: electronic appliance, 850B: electronic appliance, 851: operation button, 854: wearing tool, 855: sensor, 856: dial, 900: semiconductor device, 910: driver circuit, 911: peripheral circuit, 912: control circuit, 915: peripheral circuit, 920: memory array, 923: row driver, 924: column driver, 925: input circuit, 926: output circuit, 927: sense amplifier, 928: voltage generation circuit, 930: layer, 931: PSW, 932: PSW, 941: row decoder, 942: column decoder, 950: memory cell, 951: memory cell, 952: memory cell, 953: memory cell, 954: memory cell, 955: memory cell, 956: memory cell, 957: memory cell, 958: memory cell, 960: arithmetic unit, 970A: semiconductor device, 970B: semiconductor device, 970C: semiconductor device, 989: cache interface, 990: substrate, 991: ALU, 992: ALU controller, 993: instruction decoder, 994: interrupt controller, 995: timing controller, 996: register, 997: register controller, 998: bus interface, 999: cache, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic appliance, 6501: housing, 6502: display portion, 6503: power supply button, 6504: button, 6505: speaker, 6506: microphone, 6507: camera, 6508: light source, 6509: control device, 6510: protection member, 6511: display panel, 6512: optical member, 6513: touch sensor panel, 6515: FPC, 6516: IC, 6517: printed circuit board, 6518: battery, 6519: connection terminal, 6520: electronic appliance, 6800: artificial satellite, 6801: body, 6802: solar panel, 6803: antenna, 6804: planet, 6805: secondary battery, 6807: control device, 7000: display portion, 7001sb: server, 7001: host, 7002: storage control circuit, 7003md: memory device, 7003: storage, 7010: storage system, 7100: television device, 7101: housing, 7103: stand, 7111: remote controller, 7200: notebook personal computer, 7211: housing, 7212: keyboard, 7213: pointing device, 7214: external connection port, 7215: control device, 7300: digital signage, 7301: housing, 7303: speaker, 7311: information terminal device, 7400: digital signage, 7401: pillar, 7411: information terminal device, 9000a: housing, 9000b: housing, 9000: housing, 9001a: display panel, 9001b: display panel, 9001c: display panel, 9001d: display panel, 9001: display portion, 9003: speaker, 9005: operation key, 9006: connection terminal, 9007: sensor, 9008: microphone, 9055: hinge, 9056: operation button, 9200: portable information terminal, 9201: portable information terminal, 9202: portable information terminal

1. A semiconductor device comprising:
a first transistor and a first insulating layer,
wherein the first transistor comprises a first conductive layer, a second conductive layer, a semiconductor layer, a gate insulating layer, and a gate electrode,
wherein the first conductive layer is one of a source electrode and a drain electrode of the first transistor, and the second conductive layer is the other of the source electrode and the drain electrode of the first transistor,
wherein the first conductive layer and the second conductive layer are positioned at different levels,
wherein the first insulating layer is provided between the first conductive layer and the second conductive layer and provided with a first opening reaching the first conductive layer,
wherein the second conductive layer is provided over the first insulating layer,
wherein the gate electrode overlaps with the semiconductor layer with the gate insulating layer therebetween,
wherein the semiconductor layer comprises a first region covering a top surface of the first conductive layer in the first opening, a second region covering a side surface of the first insulating layer in the first opening, and a third region covering a top surface of the second conductive layer and overlapping with the gate electrode,
wherein the gate insulating layer comprises a fourth region provided to face a sidewall of the first opening provided in the first insulating layer with the second region therebetween, a fifth region covering a top surface of the third region, and a sixth region covering the top surface of the second conductive layer and being positioned outward from an end portion of the gate electrode in a top view,
wherein a thickness of the fifth region is larger than a thickness of the fourth region, and
wherein the thickness of the fifth region is larger than a thickness of the sixth region.

2. The semiconductor device according to claim 1,
wherein the thickness of the fifth region is larger than the thickness of the sixth region by 2 nm or more.

3. The semiconductor device according to claim 1,
wherein the thickness of the sixth region is greater than or equal to 1.0 nm and less than or equal to 100 nm.

4. The semiconductor device according to claim 1,
wherein the thickness of the fourth region is greater than or equal to 0.1 nm and less than or equal to 7.0 nm.

5. The semiconductor device according to claim 1,
wherein the semiconductor layer comprises a region covering the top surface of the second conductive layer and being covered with the sixth region.

6. The semiconductor device according to claim 1,
wherein the second conductive layer is provided with a second opening overlapping with the first opening,
wherein the semiconductor layer comprises a region covering a side surface of the second conductive layer in the second opening, and
wherein the first insulating layer comprises a region covering the second opening with the semiconductor layer therebetween.

7. A method for manufacturing a semiconductor device, comprising:
forming a first insulating layer over a first conductive layer;
forming a second conductive layer over the first insulating layer;
removing part of the second conductive layer and part of the first insulating layer to form a first opening reaching the first conductive layer and to expose a top surface of the first conductive layer;
forming a first semiconductor layer in contact with the top surface of the first conductive layer, a side surface of the first insulating layer in the first opening, a side surface of the second conductive layer in the first opening, and a top surface of the second conductive layer;
forming a second insulating layer in contact with a top surface of the first semiconductor layer and a top surface of the first insulating layer;
forming a third conductive layer over the second insulating layer;
forming a first mask by a photolithography method;
performing dry etching using the first mask; and
removing part of the third conductive layer by the dry etching to form a fourth conductive layer,
wherein the second insulating layer is formed by a method with deposition rate anisotropy,
wherein, in the second insulating layer, a thickness of the second insulating layer in a region covering a side surface of the first opening with the first semiconductor layer therebetween is smaller than a thickness of the second insulating layer in a region covering a top surface of the first conductive layer, and
wherein, in the region covering the top surface of the first conductive layer in the second insulating layer, a thickness of a part not covered with the first mask is reduced by the dry etching.

8. The method for manufacturing a semiconductor device, according to claim 7,
wherein the second insulating layer is formed by an ionization sputtering method.

9. The method for manufacturing a semiconductor device, according to claim 7,
wherein the second insulating layer is formed by a long throw sputtering method.

10. The method for manufacturing a semiconductor device, according to claim 7,
wherein the second insulating layer is formed by a plasma-enhanced chemical vapor deposition method.
